(19) United States
(12) Patent Application Publication
(10) Pub. No.: US 2021/0396905 A1
(43) Pub. Date: Dec. 23, 2021

(54) Multi-Sensor Analysis for Autonomous Systems and Devices

(71) Applicant: RN Technologies, LLC, Garden City, NY (US)

(72) Inventor: Richard Neill, Garrison, NY (US)

(21) Appl. No.: 17/354,761

(22) Filed: Jun. 22, 2021

Related U.S. Application Data
(60) Provisional application No. 63/042,392, filed on Jun. 22, 2020.

(51) Int. Cl. G01V 3/32; G05D 1/00; B64C 39/02

(52) U.S. Cl. CPC G01V 3/32; B64C 2201/123; B64C 39/024; G05D 1/0094

(57) ABSTRACT

A portable nuclear magnetic resonance (NMR) system configured for semi-autonomous or autonomous operation, including a portable NMR device configured to obtain NMR or other sensor data from an environment; a wireless communications device configured to communicate with a remote computing device; and at least one local computing device in communication with the wireless communications device and the NMR/Multisensor device, the at least one local computing device configured to perform operations comprising: receiving the NMR and sensor data that is obtained from the environment by the NMR system; sending, by the wireless communications device, the NMR or sensor data to the remote computing device; receiving, through the wireless communications device, at least one control signal for operating the NMR system in the environment, and the control signal being based on processing by the remote computing device; and causing, based on the control signal, the NMR system to adjust a data collection parameter for obtaining additional NMR and sensor data.

### CLAIM OF PRIORITY

This application claims priority under 35 U.S.C. § 119(e) to U.S. Patent Application Ser. No. 63/042,392, filed on Jun. 22, 2020, the entire contents of which are hereby incorporated by reference.

### TECHNICAL FIELD

The present disclosure relates to semi-autonomous and autonomous devices and systems configured for data collection and analysis by various sensors. More specifically, the present disclosure describes examples of performing Nuclear Magnetic Resonance analysis and sensor measurement in conjunction with semi-autonomous and autonomous systems and devices.

### BACKGROUND

There is a rapid increase in the utilization of autonomous and semi-autonomous systems, devices, and networks of such devices, coordinated collectively or managed individually, in advancing numerous fields. Once such example includes self-driving vehicles whereby networks of sensors are utilized to predict operational parameters and behavior to autonomously control a self-driving vehicle. Aquatic devices enable the exploration and manipulation within immersive or submersible domains such as oceans or other liquid filled regions for analysis of environment. Similarly, a mobile robotic system can autonomously or semi-autonomously carry out a task or function based on analysis of sensor inputs and data within the robotic systems environment. Unmanned Aerial Vehicles (UAVs), commonly referred to as drones can operate individually or in collective networks in accordance with a geospatial and operational goal. UAV systems may collect data from one or more sensors whereby computational processing and analysis of collected data may modify operational state and actions for one or more device or systems, based on said processed data. Similarly collected data may be utilized to provide real-time detection, measurement, monitoring, and situational awareness of environmental, biological, structural, and other conditions or events of interest.

Nuclear Magnetic Resonance (NMR) technology and methods such as NMR time-domain relaxometry and spectroscopy has proven to be a useful method for detecting and enabling the analysis of numerous chemical studies, biological, and material analysis. Such analysis may be performed on any sample of atomic, molecular, inorganic, and organic including biochemical structures and materials meaningful within the realm of NMR technologies. Data collected from NMR devices derived from processing samples provides utility in sensing, evaluating, screening, or measuring the presence of, and analysis of, materials, liquids, as well as identification of bacterial and viral organisms, oils, water-quality, agricultural/dairy/food, etc. NMR when combined with other multi-sensor devices (Multi-sensors) enables enhanced detection, monitoring, and analysis of complex chemistries, biological, and environmental properties beyond independent utilization of NMR or Multi-sensor devices and systems.

### SUMMARY

Methods and systems are described for a modular system, that integrates one or more combinations of portable NMR sensors and other sensors (portable NMR/Multisensor device) in conjunction with one or more autonomous or semi-autonomous systems, devices, networks of devices, including unmanned aerial vehicles, self-driving vehicles or intelligent robots, aquatic, and other forms of robotic systems.

The modular portable NMR/Multisensor device may include a portable NMR device module (for performing time-domain relaxometry, arbitrary pulse sequences, and spectroscopy methods). The portable NMR/Multisensor device can include, in addition to the NMR device, one or more additional sensor modules for environment sensing capabilities (such as temperature or other environmental or chemical measurement and detection functions across gas, liquids or solids). Each portable NMR/Multisensor device (also called NMR/Multisensor device instances or a portable NMR/Multisensor apparatus) are fully configurable in behavior actuated through dynamic command/control mechanisms managed by a NMR/Multisensor device software application. The command mechanisms occur through one or more communications methods, subsequently described. The portable NMR/Multisensor device performs data-acquisition local to the semi-autonomous or autonomous systems. Data-acquisition is associated in accordance to a given NMR or multi-sensor apparatus set of processing cycles, generating NMR and sensor telemetry for distribution to a remote computer host (NMR application apparatus) for additional processing for analysis and visualization.

A remote NMR/Sensor application is configured to execute on a NMR/Multisensor application host and performs both command/control functions as well as execution of processing and analysis algorithms relevant to the portable NMR device. The semi-autonomous or autonomous system and remote NMR/Multisensor application is connected over a network or communications link, in which the link is a wireless, wired, radio, microwave, or Bluetooth, USB, Ethernet, optical, or other communications technology, with apparatus, semi-autonomous or autonomous system or device, and remote application communicating in real-time. In some implementations, the application executes locally within the portable NMR/Multisensor device. Local processing and corresponding resulting data are utilized by both remote systems and devices, and/or additionally an associated semi-autonomous or autonomous system or device for adapting or modifying the behavior of the autonomous device or system. Generally, the portable NMR/Multisensor device and/or the application can execute in an autonomously or semi-autonomous manner.

The implementations described herein can provide various technical benefits.

The portable NMR/Multisensor devices and associated semi-autonomous or autonomous devices described in the present disclosure have utility in the detection, screening, testing, monitoring, analysis, and diagnosis of organic and inorganic materials, biological, pharmacological, environmental and/or chemical conditions, and combinations and utilization thereof based on NMR techniques and multi-sensor measurements within the field of geo-spatial use supported by semi-autonomous or autonomous systems and devices. NMR methods are performed by a semi-autonomous or autonomous system or device to detect or measure specified chemical elements and/or molecular structures where some action must be taken or reported. For example, NMR sample data analysis results are used to modify the operating behavior of the semi-autonomous or autonomous system or device such as changing its position or altitude. Modifying the portable NMR/Multisensor device behavior includes changing the configuration of the portable NMR/Multisensor device to modify which nuclei to evaluate or result in additional resampling and analysis of the sample or environment to acquire a new sample. Other examples are possible. A semi-autonomous or autonomous portable NMR/Multisensor device or system can move in accordance with a geographic route, taking samples and analyzing the chemistry of a water system in order to provide insight into the quality of the water at any given location. In another example, semi-autonomous or autonomous portable NMR/Multisensor device or system can be utilized to monitor and analyze pharmaceutical quality and detection of counterfeit substances in a fully automated (not requiring a human to manage samples), portable, and distributed manner. As another example, semi-autonomous or autonomous portable NMR/Multisensor device or system with multiple sensors can be located in regions with constrained medical facilities or access, whereas the semi-autonomous or autonomous portable NMR/Multisensor device or system in conjunction with a multi-sensor (measuring metabolic or other medical sensor devices) can provide diagnostic capabilities without the requirement of a skilled individual to operate or be present. These examples are illustrative and non-exhaustive.

Various combinations of the embodiments described herein are possible. For example, the devices and systems described herein may be semi-autonomous or autonomous and can include portable NMR-only devices, portable NMR/Multisensor devices, or multisensor-only devices that are integrated with the semi-autonomous or autonomous device or system in any combination. As subsequently described, the autonomous or semiautonomous devices or systems can be deployed in a single environment or in multiple, different environments (e.g., remote from one another) in any number per environment and in any combination of the described embodiments of the devices or systems.

In this application and with no loss of generality for application of the presently disclosed technology, methods and system design for the implementation of unmanned aerial vehicles with integral NMR and multi-sensors for analysis of a plurality of atomic, molecular, inorganic, and organic materials including biochemical structures and materials. The sensors include environmental sensors. The NMR/Multisensor device includes a representative autonomous system for performing analysis within a mobile, geospatial, potentially inaccessible or constrained, and potentially hazardous environment. Other autonomous systems and devices can similarly utilize the portable NMR/Multisensor device and methods of the system design with no loss of generality. Therefore, the illustration of a UAV is not limiting to the scope and flexibility of utilizing the presently disclosed technology for other autonomous system or device scenarios or applications.

In a general aspect, a portable nuclear magnetic resonance (NMR) system configured for semi-autonomous or autonomous operation. The NMR system includes a portable NMR device configured to obtain NMR data from an environment, a wireless communications device configured to communicate with a remote computing device; and at least one local computing device in communication with the wireless communications device and the NMR device. The at least one local computing device configured to perform operations comprising: receiving the NMR data that is obtained from the environment by the NMR device; processing, by the local device, the NMR data, or sending, by the wireless communications device, the NMR data to the remote computing device; generating, at the local processing device, or causing the remote computing device to generate, at least one control signal for operating the NMR device or at least one other device in the environment or another environment, the control signal being based on processing the NMR data by the remote computing device; and causing, based on the at least one control signal, the NMR device, the at least one other device, or both to perform an action in the environment or another environment.

In some implementations, the NMR system further comprises a navigation assembly that is coupled to the NMR device, the navigation assembly configured to autonomously or semi-autonomously navigate the NMR device in the environment, wherein the navigation assembly comprises at least one propulsion mechanism configured to move the navigation assembly in the environment based on the environment data and based on the at least one control signal. In some implementations, the at least one control signal comprises a navigation command for moving the navigational assembly in the environment to obtain additional NMR data.

In some implementations, the navigation assembly further comprises one or more sensors configured to obtain environment data for autonomous navigation in the environment by the navigation assembly.

In some implementations, the navigation assembly comprises an unmanned vehicle (UV). In some implementations, the unmanned vehicle comprises one of an unmanned aerial vehicle (UAV), an unmanned ground vehicle (UGV), an unmanned underwater vehicle, or an unmanned spacecraft. In some implementations, the remote computing device is configured to analyze of the NMR data is performed in real-time or near real-time for generating the at least one control signal, and wherein the at least one control signal is part of a stream of data that continuously or nearly continuously controls the at least one other device.

In some implementations, the at least one other device in the environment comprises one of a medical device, a user interface, a mechanical actuator, a data logging system, or an inspection system configured for quality control.

In some implementations, the NMR device is configured to operate using at least one radio frequency (RF), and wherein the NMR device comprises one or more sensors that are configured to obtain data for a plurality of different types of data acquisition and/or analysis.

In some implementations, the NMR device includes a sample system including a sample reservoir, the sample system configured to autonomously or semi-autonomously obtain a material sample from the environment; and a sensor configured to obtain the NMR data from the material sample in the sample reservoir.

In some implementations, the sample system and the sensor are configured for obtaining one or more of a liquid sample through an inlet, a solid sample by a retaining mechanism, or a gaseous sample through an inlet.

In some implementations, the NMR device comprises a plurality of sample modules, wherein each sample module is configured to be removable and replaceable with one or more other sample modules.

In some implementations, the remote computing device comprises a first remote computing device. In some implementations, the operations further comprise: sending, by the at least one local computing device through the wireless communications device, the NMR data to a second remote computing device, wherein the first remote computing device and the second remote computing device are configured to analyze the NMR data together to generate the control signal.

In some implementations, the operations further include causing the remote computing device to coordinate, using the control signal, operation of the NMR device and operation of one or more other NMR devices of one or more other respective NMR systems in response to sending NMR data to the remote computing device.

In some implementations, the control signal comprises a data vector including results of a data analysis, and wherein the action comprises performance of additional processing of the data vector.

In some implementations, the operations further include registering, by the at least one local computing device, the NMR device with the remote computing device, wherein registering comprises associating the NMR data with the NMR device; and receiving, from the remote computing device, remote computing device configuration data responsive to registering the NMR device and representing a configuration of the remote computing device for processing the NMR data of the NMR device.

In some implementations, the remote computing device configuration data specify a machine learning configuration of the remote computing device. In some implementations, the operations further include transforming the NMR data into feature data representing one or more features of the NMR data, wherein transforming the NMR data is based on the machine learning configuration of the remote computing device.

In some implementations, registering the NMR device with the remote computing device comprises: sending NMR configuration data representing a hardware configuration of the NMR device to the remote computing device, wherein the control signal is configured to control the NMR device based on the hardware configuration of the NMR device.

In some implementations, the hardware configuration specifies a plurality of types of material that the NMR device is configured to analyze.

In some implementations, the hardware configuration specifies a plurality of radio frequencies that the NMR device is configured to use, and wherein the control signal specifies a particular frequency of the plurality of frequencies for use in obtaining the NMR data.

In some implementations, the control signal is configured to control the NMR device based on different NMR data received by the remote computing device from a different NMR device.

In some implementations, the NMR device comprises a fluid reservoir, and wherein the control signal is configured to reposition the fluid reservoir to improve NMR processing by the NMR device, wherein repositioning is based on a feedback from a multi-axis gimbal.

In some implementations, the NMR device comprises a rotating reservoir configured for receiving solid matter, and wherein the control signal is configured to position an axis of the rotating reservoir to a particular angle relative to a magnetic field of the environment.

In some implementations, the NMR system further includes one or more biometric sensors comprising a temperature sensor, a pressure sensor, an electrocardiogram (EKG) sensor, or an SPO₂ sensor.

In some implementations, the NMR device is coupled to a stationary autonomous or semi-autonomous device.

In some implementations, the local computing device is configured to cause transmission of a data broadcast comprising the NMR data, wherein the NMR device is configured to repeatedly obtain updated instances of NMR data from the environment for transmitting in the data broadcast.

In some implementations, the control signal is configured to cause the NMR device or the other device to adjust a data collection parameter for obtaining additional NMR data or other sensor data, respectively.

In some implementations, the local computing device is configured to perform a preprocessing workflow on the NMR data to transform the NMR data for processing by the remote computing system.

In some implementations, the preprocessing workflow is based on a trained machine learning model or sensor calibration data that is received from the remote computing system.

In some implementations, the operations further include, based on the NMR data, sending one or more control signals to one or more other NMR devices of one or more other respective NMR systems in the environment to control operation of the one or more other respective NMR systems in the environment.

In a general aspect, a system includes at least one sensor device configured to acquire sensor data in an environment, the at least one sensor device including a nuclear magnetic resonance (NMR) device, a multisensor device configured to support one or more modular sensors, or a combination of the NMR device and the multisensor device; at least one local computing device configured to perform operations including: processing the sensor data to update a local model representing a processing workflow for generating a control instruction for a device or to perform data analytics on the sensor data; sending, over a communication network, the sensor data from the at least one sensor device in the environment to a remote computing device; causing, based on the sensor data, the remote computing device to update a global model representing a processing workflow to control at least one additional device or perform data analytics for the at least one additional device, the global model being based on additional sensor data received from the least one additional device; and causing, based on the processing workflow of the updated global model, an autonomous or semi-autonomous platform coupled to the at least one additional device to perform an action in the environment.

The details of one or more embodiments are set forth in the accompanying drawings and the description below. Other features and advantages will be apparent from the description and drawings, and from the claims.

### BRIEF DESCRIPTION OF THE DRAWINGS

FIGS. 1A-1C each show a block diagram of a system including an example of a portable NMR/Multisensor device and a semi-autonomous or autonomous device.

FIGS. 2A-2C each show a block diagram of an example of a portable NMR/Multisensor device controlled by a base controller device.

FIG. 3 shows a block diagram that illustrates an example of a NMR/Multisensor application hosted on a UAV base controller device.

FIG. 4 shows a block diagram that illustrates an example of a connection and utilization of the NMR/Multisensor application with a management and analysis system.

FIGS. 5A-5B each show a block diagram of an example of a single portable NMR/Multisensor device communication based on Wi-Fi and/or cellular communications network independent of a semi-autonomous or autonomous device.

FIG. 6 illustrates a block diagram of an example of a single portable NMR/Multisensor device integrated to an UAV semi-autonomous device.

FIG. 7 illustrates a block diagram of an example of two portable NMR/Multisensor devices and UAV devices, each with a dedicated base controller.

FIG. 8 illustrates a block diagram of an example of a UAV semi-autonomous device with two portable NMR/Multisensor device devices communicating to a single base controller hosting an instance of a NMR/Multisensor application.

FIG. 9 illustrates a block diagram of an example of a UAV semi-autonomous device with two portable NMR/Multisensor device devices communicating to a single base controller and an external instance of the NMR/Multisensor application.

FIG. 10 illustrates a block diagram of an example of two or more portable NMR/Multisensor devices integrated with two or more UAV devices, each with a dedicated base controller.

FIG. 11 illustrates a block diagram of an example of two or more portable NMR/Multisensor devices integrated with two or more UAV devices operating within a collective or swarm-based control plane.

FIG. 12 illustrates a block diagram of an example of a network of FIG. 4.

FIG. 13A illustrates a block diagram of an example of multiple portable NMR/Multisensor devices communicating and utilizing a management and analysis system.

FIG. 13B illustrates a block diagram of an example of multiple portable NMR/Multisensor devices communicating and utilizing a management and analysis system that deploys machine learning logic onto each of the portable NMR/Multisensor devices.

FIG. 14 illustrates a block diagram of an example of a hardware design for a portable NMR/Multisensor device including multiple RF coils.

FIG. 15A illustrates a block diagram of an example of a hardware design of the portable NMR/Multisensor device including a single RF coil.

FIG. 15B illustrates a block diagram of an example of a hardware design of the portable Multisensor-only device.

FIG. 16A illustrates a block diagram of an example of a portable NMR/Multisensor device software design and architecture for basic NMR and sensor operation.

FIG. 16B illustrates a block diagram of an example of the portable NMR/Multisensor device software design and architecture for enhanced NMR and sensor operation.

FIG. 17A-B illustrate block diagrams of examples of the NMR/Multisensor Application apparatus hardware design and software architecture.

FIG. 18 illustrates a perspective view of an example of a design of portable NMR/Multisensor device suitable for mobile autonomous or semi-autonomous device or system attachment.

FIG. 19 illustrates an exploded assembly view and example design of portable NMR/Multisensor device 102 with multiple components of assembly.

FIG. 20 illustrates an example design of the NMR/Multisensor apparatus processor and RF/coil electronics assembly component.

FIG. 21 illustrates an example design of the NMR/Multisensor apparatus magnetic component assembly.

FIG. 22 illustrates an example design of the NMR/Multisensor apparatus base unit for semi-autonomous or autonomous systems or device mounting option component assembly.

FIG. 23 illustrates an example design of the NMR/Multisensor apparatus NMR Sample Module component assembly.

FIG. 24 illustrates an example design of portable NMR/Multisensor device with semi-autonomous or autonomous system or device mounting option and four sensor modules inserted into assembly.

FIG. 25 illustrates an exploded assembly view and example design of portable NMR/Multisensor device 102 including four sensor modules representing multiple components of assembly and with semi-autonomous or autonomous system or device mounting option.

FIG. 26 illustrates a perspective view of the portable NMR/Multisensor device design without mounting option or use in desktop scenario.

FIG. 27 illustrates a side view of an example portable NMR/Multisensor device design for table-top use.

FIG. 28 illustrates an exploded assembly view and example design of portable NMR/Multisensor representing multiple components of assembly in desktop utilization scenario.

FIG. 29 illustrates a side view of an example portable NMR/Multisensor device design with four sensors inserted for table-top use.

FIG. 30 illustrates a perspective view of an example portable NMR/Multisensor device.

FIG. 31 illustrates an exploded assembly view and example design of portable NMR/Multisensor device.

FIG. 32 illustrates an example of a semi-autonomous or autonomous system embodiment for automated lab assay experimentation.

FIG. 33A illustrates an example of a semi-autonomous or autonomous system embodiment for a portable medical kiosk.

FIG. 33B illustrates an example of a semi-autonomous or autonomous system embodiment for multisensor use.

FIG. 33C illustrates an example of a semi-autonomous or autonomous system embodiment for NMR/Multisensor use in a single environment.

FIG. 33D illustrates an example of a semi-autonomous or autonomous system embodiment for single sensor use.

FIG. 33E illustrates an example of a semi-autonomous or autonomous system embodiment for multiple instances of autonomous or semi-autonomous devices including multisensor use in a single environment.

FIG. 33F illustrates an example of a semi-autonomous or autonomous system embodiment for instances of autonomous or semi-autonomous devices including multisensor use in more than one environment.

FIG. 33G illustrates an example of a semi-autonomous or autonomous system embodiment for multiple instances of devices or systems including lower explosive limit (LEL) sensor use in a single environment.

FIG. 33H illustrates an example of instances of NMR/Multisensor use in multiple regions of an environment.

FIG. 34 illustrates perspective views of a portable NMR/Multisensor device design for UAVs including example configurations of one or more NMR/Multisensors on each UAV.

FIGS. 35-36 show example coupling mechanisms for coupling sensor modules or NMR subassemblies to an NMR/Multisensor device.

### DETAILED DESCRIPTION

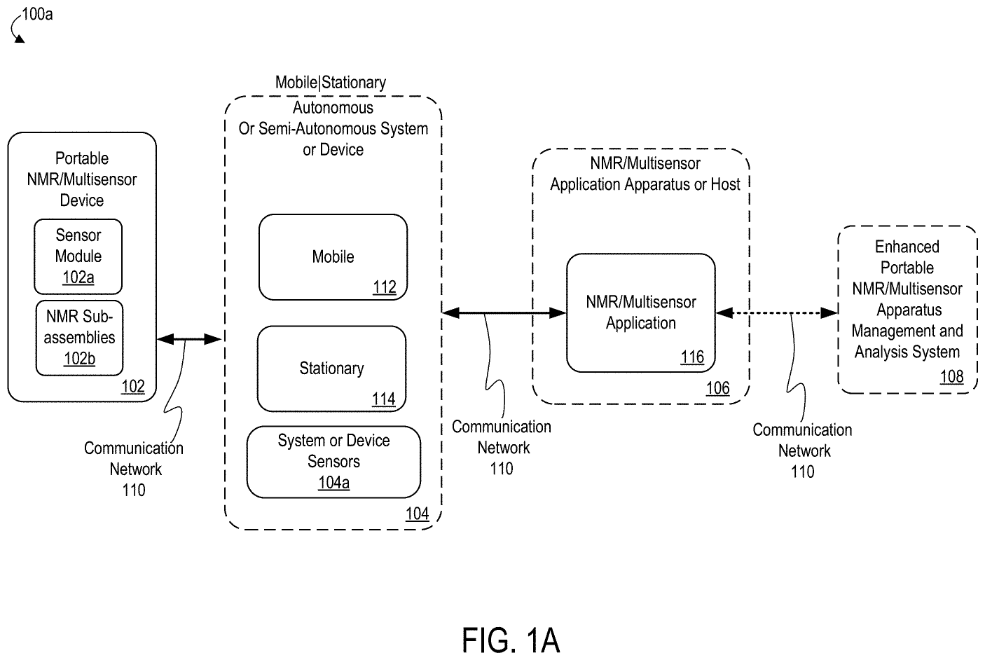

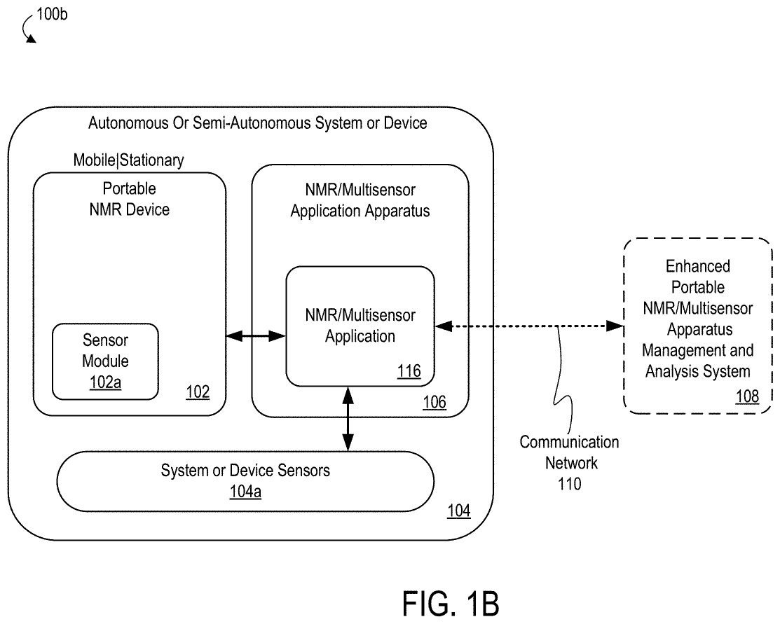

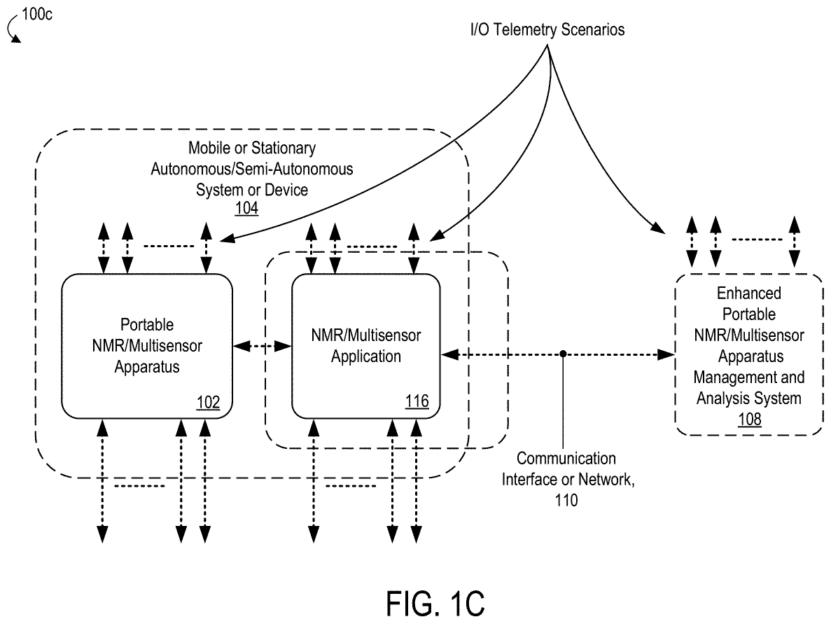

FIG. 1A shows an example of a system 100a for portable Nuclear Magnetic Resonance (NMR) and multi-sensor analysis. System 100a includes a portable device 102 configured to perform NMR operations and/or multi-sensor measurements (e.g., the portable device 102 or portable NMR/Multisensor device 102). The portable device 102 is in communication with an autonomous or semi-autonomous system or device 104 (e.g., the autonomous device 104), such as using a communications network 110, subsequently described in greater detail. The autonomous device 104 includes one or more of unmanned aerial vehicles, self-driving vehicles or intelligent robots, aquatic vehicles, and similar forms of autonomous or semi-autonomous systems. In some implementations, the portable device 102 is included in the semi-autonomous or autonomous device 104, as shown below in relation to system 100b of FIG. 1B. In some implementations the portable NMR/Multisensor device included in 104 can be stationary while still performing its functions and operations in a semi-autonomous or autonomous manner.

Throughout this document, the portable NMR/Multisensor device is shown having various particular embodiments and configurations. Generally, the portable NMR/Multisensor device includes one of the following configurations: NMR sensors only; NMR sensors and a multisensor device including a suite of one or more other sensors, operating either individually or in combination with one another or the portable NMR device; or the multisensor device only that includes the suite of one or more non-NMR sensors. Each of these sensor configurations can be combined with a semiautonomous or autonomous device (such as a UAV or other vehicle) for transporting the sensor configuration through an environment for data collection.

In some implementations, the NMR/Multisensor device 102 includes other sensors for measuring data in addition to the NMR data obtained by the NMR module. Though the NMR device 102 is referred to as being an NMR device in particular, the NMR device includes functionality for these other sensors as well, and the other sensors obtained data for independent operations for the portable device 102 and/or data for using in conjunction with the NMR data obtained by the NMR module.

Generally, the portable NMR/Multisensor device 102 includes an NMR module configured to perform time-domain relaxometry, to perform arbitrary pulse sequences, and/or to perform spectroscopy methods. The portable NMR/Multisensor device 102 is configured to perform NMR operations in addition to one or more other operations that are performed based on additional sensors of the semi-autonomous or autonomous device 104. The NMR operations include obtaining data for analysis of an atomic or molecular structure of a material by measuring an interaction of nuclear spins (one or more atoms constituting the sample material) of the material when the material is subjected to a magnetic field. Generally, the NMR operations include an alignment (polarization) of magnetic nuclear spins in an applied, constant magnetic field B₀. The portable device 102 causes a perturbation of the alignment of the nuclear spins by applying a weak oscillating magnetic field, such as a radio-frequency (RF) pulse. An oscillation frequency required for significant perturbation is dependent upon the static magnetic field (B0) and the nuclei of observation. A detection of the NMR signal during or after the RF pulse, due to the voltage induced in a detection coil by precession of the nuclear spins around B0. After the RF pulse, precession usually occurs with the nuclei's intrinsic Larmor frequency.

The NMR/Multisensor device 102 is configured to adjust operations of the NMR sensor and/or Multisensor to improve or optimize portability of the sensors. For example, for energy management, the NMR/Multisensor is activated for sample collection and deactivated for transport. Power levels for one or more of the NMR coils is adjustable. The coils can be tuned dynamically (e.g., by controls from the management and analysis system 108) for different NMR studies. The management and analysis system 108 can be configured to adjust a number of NMR sequences generated for a particular study or iteration of data acquisition. The NMR/Multisensor device 102 is remotely configurable by the base controller, as subsequently described. For example, the NMR sensor is controlled to generate multiple pulse sequence patterns by remote command/control on the NMR/Multisensor application host 218. Additionally, results of the NMR/Multisensors data acquisition are used for controlling the NMR/Multisensor device 102, such as to actuate the autonomous device or system 104. For example, if a particular value is acquired in the data, the autonomous device or system 104 is controlled to move to a new location, generate an alarm or notification, update a user interface, and so forth.

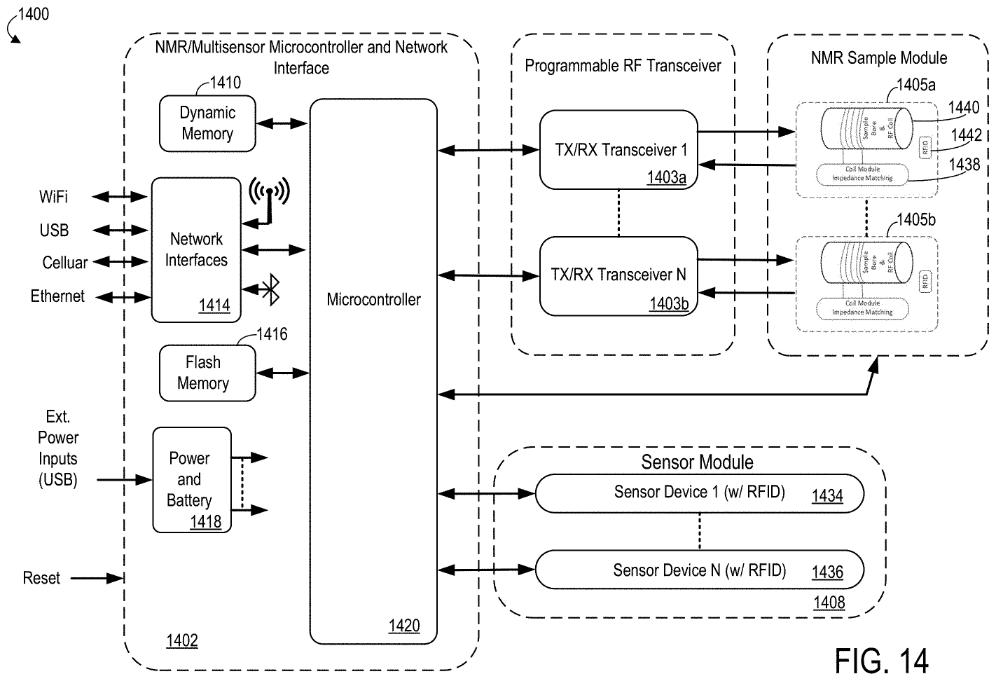

Other forms of NMR operations are possible by the portable device 102, as subsequently described in relation to FIGS. 14-16B.

Generally, the NMR RF coil is separated from the other electronics of the NMR/Multisensor device 102, such as an RF transmitter/receiver being separated from signal processing, analysis, and visualization electronics. FIGS. 14-16B, subsequently described, show examples of hardware modules of the NMR/Multisensor device 102. In some embodiments, the hardware positioned on the semi-autonomous or autonomous device (e.g., a UAV) is at minimum, and processing hardware is located at a remote location (e.g., cloud computing). For example, data acquisition are performed at a UAV, and the acquired data are transmitted to remote computer resources available to process the data (e.g. DSP signal processing, Fourier transforms, data-analytics to categorize the process data into chemical signatures, visualization and prediction of chemistries, etc.). In addition, as subsequently described, cloud computing resources enable coordination and aggregation of data from multiple instances of the NMR/Multisensor device 102 for collective intelligence and orchestration.

The portable NMR/Multisensor device 102 can include one or more additional sensors in a sensor module 102a for sensing capabilities, such as temperature or other environmental or chemical measurement and detection functions across gas, liquids or solids. In some implementations, the sensors of the sensor module 102a are modular, and most any suite of associated sensors are included as needed on the portable NMR/Multisensor device 102 by being interfaced in one or more ports of the portable NMR/Multisensor device 102. In some implementations, the semi-autonomous or autonomous device 104 is configured to perform various other operations based on data from these additional sensors of the sensor module 102a of the portable NMR/Multisensor device 102.

The portable NMR/Multisensor device 102 is configured to analyze multiple types of materials using specialized modules. For example, the portable NMR/Multisensor device 102 includes a plurality of NMR/Multisensor device modules and associated NMR sample module reservoirs. The portable NMR/Multisensor device 102 includes zero, one, or a plurality of sensor modules associated with the NMR/Multisensor device modules. The NMR/Multisensor device modules, NMR sample module reservoirs, and sensor modules can together form a set of sub-assemblies 102b. Each of these sub-assemblies is modular, such that it is inserted and removed from the portable NMR/Multisensor device 102. In some implementations, each NMR/Multisensor device module or sub-assembly associated with the NMR/Multisensor device module can have an identifier, such as a unique RFID tag. The identifier distinguishes the sub-assembly to a processing device of the portable NMR/Multisensor device 102, semi-autonomous or autonomous device 104, or application host 106, as subsequently described.

The portable NMR/Multisensor device 102 facilitates the measurement and evaluation of different sample characteristics for materials in an environment. For example, the application 116 is configured to recognize a module configuration of the portable NMR/Multisensor device 102. In response to detecting the configuration, the application 116 automatically generates a corresponding appropriate command and control message.

The portable NMR/Multisensor device 102 can include multiple NMR sample modules, each having a design that is suited for the sample collection task. In an example, a first sample module is configured to collect fluids (gases or liquids). The design of the NMR sample module is optimized to move fluids to the outer surface of the sample module in proximity to the coil and associated magnetic fields (e.g., static fields, dynamic fields, and fields during RF signal reception).

A second NMR sample module is optimized for fluid sample retention in conjunction with dynamic repositioning of the portable NMR/Multisensor device 102. For example, command and control of a multi-axis gimbal or positioning system (e.g., for a semi-autonomous or autonomous device 104 including an aerial vehicle) is coordinated to optimize the fluid reservoir for NMR processing. This includes keeping the sample module stable when needed, to moving the sample module if desired.

A third NMR sample module of the portable NMR/Multisensor device 102 may be optimized for solid samples, such as collection of soil samples or other solid matter enabling solid-state NMR testing. An exemplary embodiment is a NMR sample module comprising a rotating solid matter reservoirs having an axis position is precisely oriented to 54.7 degrees relative to the static magnetic field. The axis position of the reservoirs is useful for implementing the magnetic angle spinning condition for improved signal response, further optimizing the performance of the portable NMR/Multisensor device 102 operating with the semi-autonomous or autonomous device 104.

The sub-assemblies 102b of the portable NMR device 102 can each include a reusable or disposable NMR sample module. The reusable module is fully separable from the portable NMR/Multisensor device 102. The NMR sample module is highly cost-efficient and is easily reconfigured for any targeted environment.

The portable NMR/Multisensor device 102 and semi-autonomous or autonomous device 104 generally communicate telemetry data over the communication network 110 to a second computing device (e.g., the application host 106) hosting the application 116 that can configure and control the portable NMR/Multisensor device 102. In one embodiment, the application 116 is hosted and executed on an alternative computer hardware platform (e.g., remote computing device, cloud computing device) with no loss of generality.

The semi-autonomous or autonomous device 104 includes a mobile platform that is configured to move the portable NMR/Multisensor device 102 in an environment. The portable NMR/Multisensor device 102 is integrated with the semi-autonomous or autonomous device 104 such that the portable NMR/Sensor device is part of the hardware of the semi-autonomous or autonomous device. In some implementations the NMR/Multisensor device 102 is portable, yet stationary while operating in a semi-autonomous or autonomous manner. For example, the NMR/Multisensor device 102 is moveable to a particular environment in which it operates autonomously or semi-autonomously. In some implementations, the portable NMR/Multisensor device 102 is modular and is detached from the semi-autonomous or autonomous device 104. In another example, the semi-autonomous or autonomous device 104 is a platform for the portable NMR/Multisensor device 102 to move the device around the environment. In an example, the semi-autonomous or autonomous device 104 includes an unmanned aerial vehicle (UAV). The UAV supports the portable NMR/Multisensor device 102 on board. In some implementations, the UAV includes additional multi-sensors for analysis of materials including atomic, molecular, inorganic, and organic (including biochemical structures and materials) and environmental sensors as previously described.

Generally, a UAV is used for various examples throughout this disclosure to represent the semi-autonomous or autonomous device 104 for performing analysis within a mobile, geospatial, potentially inaccessible, or constrained, and potentially hazardous environment. However, as previously described, other semi-autonomous or autonomous systems and devices can similarly utilize the portable NMR/Multisensor device 102 and perform the processes described herein with no loss of generality. Therefore, the subsequent illustration of a UAV as the semi-autonomous or autonomous device 104 is not limiting to the scope and flexibility of utilizing the technology of the present disclosure for other autonomous or semi-autonomous systems or device scenarios or applications.

There may also be one or more additional sensors 104a on the semi-autonomous or autonomous device 104. Data from the (semi-autonomous or autonomous) system or device sensors 104a is used individually, or in combination with data from the portable NMR/Multisensor device 102, for operation of the semi-autonomous or autonomous device. For example, the semi-autonomous or autonomous device 104 can perform navigation operations based on data from the portable NMR/Multisensor device 102 and one or more other sensors hosted on the semi-autonomous or autonomous device. In some embodiments, the additional sensors 102a that communicate with the portable NMR/Multisensor device 102 are included in another autonomous or semi-autonomous device that is different than the semi-autonomous or autonomous device 104 hosting the portable NMR/Multisensor device. In some implementations, the system or device sensors 104a are both on the semi-autonomous or autonomous device 104 and one or more remote devices (not shown), such as additional semi-autonomous or autonomous devices.

The portable NMR/Multisensor device 102 is configured to communicate with one or more remote devices over communication network 110. The one or more remote devices are configured to perform data processing operations on data acquired by the portable NMR/Multisensor device 102 or data acquired by the other sensors associated with portable NMR/Multisensor device and semi-autonomous or autonomous device 104. Generally, the portable NMR/Multisensor device 102 and the additional sensors are configured to communicate data among one another.

The portable NMR/Multisensor device 102 generally performs data-acquisition local to the semi-autonomous or autonomous device 104. The acquired data with a particular set of processing cycles of a portable NMR/Multisensor device 102. The portable NMR/Multisensor device 102 generates NMR and sensor data (e.g., telemetry) that can be distributed to a plurality of destinations including an application host 106 (e.g., a NMR/Multisensor application apparatus) that hosts an application 116 (e.g., NMR/Multisensor application 116).

The application host 106 includes a software service, referred as the NMR/Multisensor application 116 (e.g., the application 116). The application host 106 is generally an optimized computational networked host that performs processing of the NMR data, sensor data, including combinations of both and generates control instructions for the semi-autonomous or autonomous device 104 and portable NMR/Multisensor device 102. The application host 106 also processes sensor-acquired sample data for sensors associated with the portable NMR/Multisensor device 102. In an example, the application host 106 retrieves one or more environmental or chemical measurements from the sensor module 102a including any sensors that may exist on the portable NMR/Multisensor device 102. The application host 106 executes one or more analysis algorithms that are dynamically loaded and updated as part of application 116. The analysis includes classification of the environmental or chemical measurements as part of the analysis. This application host 106 is a server or cloud-based software platform, and is subsequently described in further detail. As previously described, the NMR and sensor data are distributed for utilization by the portable NMR/Multisensor device 102, such as for additional processing, for system or device actuation, additional processing, analysis and/or visualization, and so forth.

The application 116 (e.g., a remote NMR/Multisensor application executing on the application host 106) performs both command/control operations and execution of data processing and analysis relevant to the portable NMR/Multisensor device 102 or semi-autonomous or autonomous device 104. Generally, the portable NMR/Multisensor device 102 is fully configurable in its behavior and is actuated through the command instructions that are managed by the remote application 116 executed by the application host 106. The application 116 is configured to receive, in real-time or near real time, data from the portable NMR/Multisensor device 102 and/or other sensors of the semi-autonomous or autonomous device 104. The application 116, in real time or near-real time, sends response commands to the portable NMR/Multisensor device 102 and/or a semi-autonomous or autonomous device 104 based on the received data. Real-time or near real-time processing refers to a scenario in which received data are processed as made available to systems and devices requesting those data as soon as possible (e.g. within milliseconds, tens of milliseconds, or hundreds of milliseconds) after the processing of those data are completed. The processing delay between when data are received and when data are available is generally on the order of seconds. While there is no guarantee of when output data will be available, real-time data output from the data processing system generally represents the latest data received from one or more data sources, with a processing delay of up to several seconds. For each module in a pipelined workflow, the module is configured to approximately match the rate of data being output with the rate that data are received. In an embodiment, each module in a workflow of modules operates in parallel and at a synchronous or nearly-synchronous rate. When a downstream module is ready to process additional data, the downstream module accesses the most recent data from a buffer or other in-memory storage that is provided from an upstream module. When the module is finished processing the additional data, the additional data is stored in an in-memory storage for access by one or more downstream modules or systems

In some implementations, the application host 106 includes a high-resolution display for enabling visualization and interactivity between users and the portable NMR/Multisensor device 102. Users can control the portable NMR/Multisensor device 102 and/or semi-autonomous or autonomous device 104, including configuring and reconfiguring of all operational parameters. Users can control dynamic execution of analysis, including machine learning based software to aide in the analysis of all acquired NMR data and sensor data.

The semi-autonomous or autonomous device 104 and application host 106 are generally connected to one another over a communication network 110. The communication network includes a communications link. The communications link is wireless or wired. The communications network 110 is based on technologies that are serial or parallel, including Ethernet or USB; optical communications; WiFi, Bluetooth, or RF/broadband/microwave; or if collocated on the same physical hardware, as software processes utilizing standard methods for software inter-process communication, or other communications technology, with each apparatus, autonomous system or device, and remote application communicating in real-time. These communication approaches may be used in combination.

The portable NMR/Multisensor device 102 is configured for geo-spatial analysis that includes performing NMR/Multisensor operations at different locations in an environment. In an example, the portable NMR/Multisensor device 102 is configured for detection, screening, testing, analysis, and diagnosis of organic and inorganic materials, environmental/chemical conditions, and combinations thereof based on NMR techniques and measurements of the one or more other sensors associated with the portable NMR/Multisensor device 102 and/or semi-autonomous or autonomous device 104. The analysis by the portable NMR/Multisensor device 102 detects or measures specified chemical elements and/or molecular structures. Based on the analysis of the NMR data, the portable NMR/Multisensor device 102 (or related application host 106) determines that an action should be taken by the semi-autonomous or autonomous device 104 and sends a corresponding instruction to the semi-autonomous or autonomous device 104. For example, based on the NMR sample data analysis results, the application host 106 or portable NMR/Multisensor device 102 may modify the navigation behavior of the semi-autonomous or autonomous device 104, including a position, altitude, trajectory, path planning, GPS waypoint list, geo-fence, velocity, orientation, and so forth. In a second example, based on the NMR sample data analysis results, the application host 106 or portable NMR/Multisensor device 102 may modify the behavior of one or more sensors residing within the portable NMR/Multisensor modules 102a, 102b and/or the semi-autonomous or autonomous device or system 104.

The application host 106 is configured to change a configuration of the portable NMR/Multisensor device 102 in response to receiving NMR or sensor data. For example, the application host 106 can generate an instruction indicating that the portable NMR/Multisensor device 102 modify which nuclei to evaluate (e.g., through adaptive control of the NMR RF coil(s) residing within the portable NMR/Multisensor device) in response to analysis of NMR data received from the portable NMR/Multisensor device 102. In another example, the application host 106 can instruct the portable NMR/Multisensor device 102 to perform resampling and analysis of a previous material, environment, or change a position in the environment to acquire a new sample.

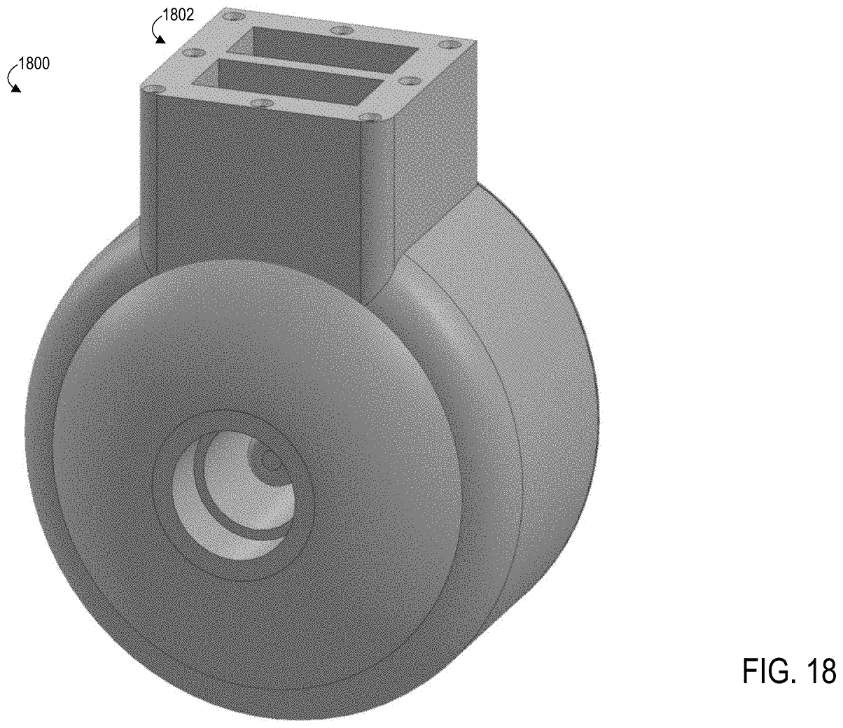

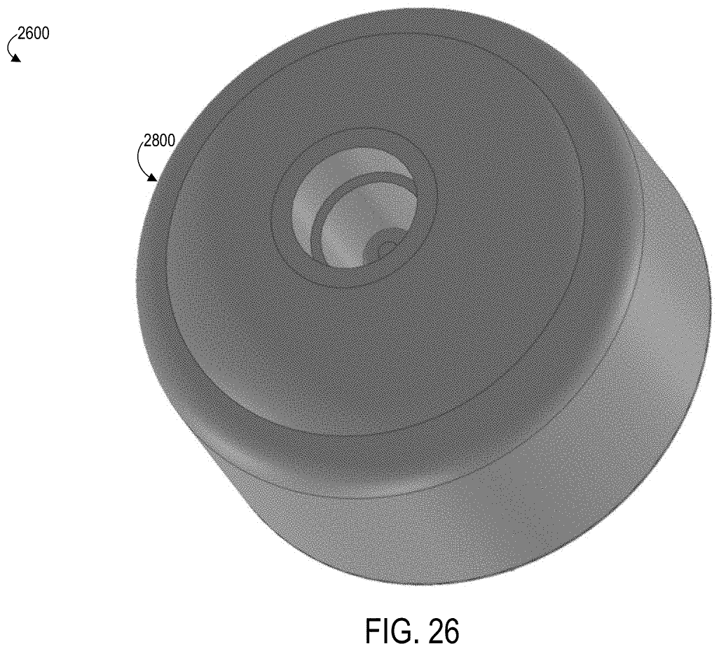

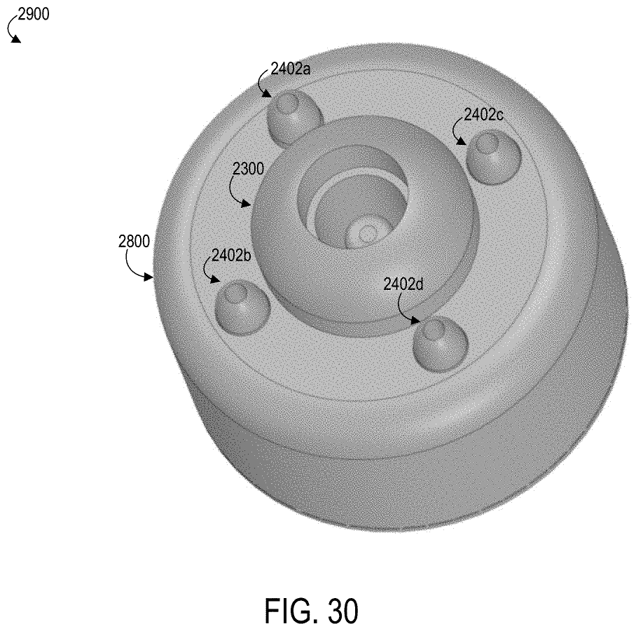

To enable attachment of the portable NMR/Multisensor device 102 to different types of semi-autonomous or autonomous devices 104, the portable NMR/Multisensor device 102 includes an attachment interface module (e.g., described further in relation to FIGS. 18, 19, 22, 24, 25, etc.). The attachment interface module is a structure that enables modular attachment of the portable NMR/Multisensor device to the other portions of the semi-autonomous or autonomous device (such as a UAV or an autonomous vehicle frame). The attachment module is reconfigured for different types of semi-autonomous or autonomous systems and device configurations, shape, and geometry and mode of operation. In another example, the attachment interface module is completely removed, which allows a standalone operation of the portable NMR/Multisensor device 102 for stationary use. For example, the portable NMR/Multisensor device 102 is deposited by or decoupled from the semi-autonomous or autonomous device 104 for use on a desktop or table, as would be found in a scientific lab, medical facility, hospital, or other facility; within a kiosk, or fixed object or structure such as one found within a building, bridge, or other super-structure; or within a spatially constant, yet moving from of reference as occurring for example within a moving train, boat or aquatic vehicle, aircraft, or some similar vehicle. The semi-autonomous or autonomous device 104 is configured to move the portable NMR/Multisensor device 102 to other environments as well, such as in or around pipelines, industrial machinery, dams, energy, and industrial systems (e.g., oil wells or rigs), chemical factories, refineries, and agricultural infrastructure including farms, dairy, and food processing facilities. Many other similar examples are possible, and this list is non-exhaustive. Examples of standalone use of the portable NMR/Multisensor device 102 are described below in relation to FIGS. 26-30.

Turning to FIG. 1B, in an exemplary embodiment of the system 100b is shown in which the portable NMR/Multisensor device 102 is combined with the semi-autonomous or autonomous device 104. In this example, the portable NMR/Multisensor device 102 and sensor operations are fully autonomous. Data processing of the NMR data and sensor data are sent to the application host 106 as part of the data telemetry for remote processing. In another embodiment, the portable NMR/Multisensor device 102 and semi-autonomous or autonomous device 104 use the NMR data and the sensor data from the modules/sensors 102a, 104a locally for internal processing. For example, the application 116, executed either on the semi-autonomous or autonomous device 104 and portable NMR/Multisensor device 102 or as a remote system, can control the position of the portable NMR/Multisensor device 102. Control of the position of the portable NMR/Multisensor device 102 includes angle, tilt, and yaw or multiple axis of movement of the portable NMR/Multisensor device. Additionally, the NMR sensor module supports both stationary and actuated movement using a multi-axis gimbal to achieve specified NMR sensor geometric relationship to a given sample environment. The application 116 can control positioning or repositioning of the portable NMR/Multisensor device 102 one or more times for collecting samples or measurements of interest in an environment at different times under user-control or dynamically by utilizing the analysis of NMR/Multisensor data to drive command and control instructions to the host semi-autonomous or autonomous device 104. The application 116 can control all aspects of timing (based on user-control, a configured schedule, or dynamically driven by NMR and multisensory data analysis in real-time) and frequency of obtaining measurements. The application 116 can control how much of a sample is obtained, and control the configuration of the portable NMR/Multisensor device 102 to achieve different sample acquisition patterns. For example, the application 116 can select one set of sensors of sensor module 102a for data acquisition in a first location, and a second set of sensors of sensor module 102a for data acquisition in a second location. The application 116 can create one or more sensor acquisition patterns across one or more multiple locations. The application 116 can control in real-time the configuration of the NMR sensor module 102b includes dynamic generation of required pulse-sequence type, duration, frequency, pulse amplitude and phase. The application 116 can instruct the NMR sensor to auto-calibrate for optimal operation associated to a given type of sample. This would include selection of RF coil and tuning of the coil based on reconfigurable impedance network. The application 116 can optimize the power output of the NMR RF transmitter and receive sensitivity, as well as provide for temperature compensation.

While FIGS. 1A-1B each show a single portable NMR/Multisensor device 102 integrated to one semi-autonomous or autonomous device 104, and the portable NMR/Multisensor device 102 communicating to a single application 116 executing on a single application host 106 or equivalent alternative computer system host, other configurations are possible. For example, multiple portable NMR/Multisensor devices are networked together in various configurations on one or more semi-autonomous or autonomous devices. The systems 100a-b are scaled up by including a second data processing system (similar to application host 106) to manage multiple portable NMR/Multisensor device 102 instances. Similar to the application host 106, the second computer system, which operates as a management and analysis system 108, may be located within a private or public infrastructure, and be implemented as any of server, cluster, datacenter, or a cloud-based system.

The management and analysis system 108 (e.g., an enhanced portable NMR/Sensor apparatus management and analysis system 108) enhances the operation of the portable NMR/Multisensor device 102 and application 116 by providing additional operations including enhanced analysis, device management, and processing capabilities that span across one or more portable NMR/Multisensor device 102 instances and semi-autonomous or autonomous device 104 instances. For example, the management and analysis system 108 can dynamically manage all software images on each of the portable NMR/Multisensor device 102 instances and application host 106 instances or equivalent computer system hosts. The dynamic management of software images by the management and analysis system 108 includes, but is not limited to, management of operating systems, libraries, and application software for execution across any of the software components of systems 100a-b.

The management and analysis system 108 is generally implemented on a remote computing system (implemented as an individual server, cluster of servers, private or public cloud) that is available to both the portable NMR/Multisensor device 102 and application host 106 through an optional communications network (shown as dotted lines in FIGS. 1A-1B).

The systems 100a-b include mobile or stationary, autonomous, and semi-autonomous systems and devices including one or more portable NMR/Multisensor devices 102, the semi-autonomous or autonomous device 104, and the application host 106, independent of a secondary computing host in order to realize the end-to-end system functionality. Each component of the complete system 100a-b may generate output telemetry, or consume input telemetry (where telemetry may comprise data, command and control messages, result data-sets from measurements, data acquisition, processing or computation, analysis), as well as communicate in the form of messages with one another.

FIG. 1C illustrates the various telemetry scenarios 100c for this embodiment as bi-directional input/output arrows among the various component modules. The scenarios 100c include direct or indirect communication of telemetry to and from each of the portable NMR/Multisensor device 102, the NMR/Multisensor device application 116, and the portable NMR/Multisensor device management system 108 in any combination. As representative and non-limiting examples, portable NMR/Multisensor device 102 contains one or more sensors such as NMR, temperature, humidity, chemical (organic, hydrocarbon, inorganic, gas or fluid measurement devices, biological, biologics, agricultural, RF, microwave, thermal, camera, and other spectral monitoring, measurement and detection sensors; each of which can generate a stream of telemetry data associated with the given sensor device. The telemetry data of the portable NMR/Multisensor device 102 can be transferred, transmitted, delivered as individual or aggregated data messages to the semi-autonomous or autonomous system or device in 104 and/or to the NMR/Multisensor device Application in 116. Similarly, the portable NMR/Multisensor in 102 may receive data-streams (typically comprising command and control operation messages) from 116. In a similar manner, NMR/Multisensor device Application 116 may receive telemetry from the semi-autonomous or autonomous system or device 104 (such as operating state of 104 such as position, or other measurements or data collected by 104), telemetry received external to 104 (such as an external sensor that includes a direct communication link to 104) and transfer, transmit or otherwise deliver telemetry to 104 (comprising processed data by 116 such as analysis and other processing of data within 116 such as execution of machine learning algorithms and other computation of data received by 116 from any of the available sources). The portable NMR/Multisensor device management system 108 communicates bi-directionally to the portable NMR/Multisensor device application in 116. Typically, command, control and orchestration messaging is delivered to 116 from 108 to provision, control, and optimize the operational state and next-state behavior of 116 (and indirectly 102 and 104, or combinations of each) based on the telemetry streams generated and processed by 108 in response to messages originated by instances of 102, 104, and 116 throughout their operation.

The subject matter of the present disclosure may be utilized for numerous other mobile applications based on integration of the portable NMR/Multisensor device 102 with semi-autonomous or autonomous systems 104 other than UAV devices. For example, within a robotic land vehicle, such as a self-driving vehicle or robotic land or aquatic autonomous system, the portable NMR/Multisensor device 102 is attached to these systems enabling the collection, and real-time utilization of acquired and processed data based on the portable NMR/Multisensor device 102 generated telemetry.

A modularity of the portable NMR/Multisensor device 102 for a stationary, fixed autonomous system scenario is an embodiment in which a point-of-care or a point-of-use application may be implemented. In these applications, the portable NMR/Multisensor device 102 is utilized to implement medical diagnostics or a testing scenario with limited human intervention. For example, the portable NMR/Multisensor device 102 may be mounted within a smart kiosk, utilizing the plurality of known NMR technology capabilities of the sub-assemblies 102b for detection, testing, and analysis of a biologic sample. The associated sensors of the sensor module 102a can acquire biometrics of individuals. The biometrics include temperature, blood pressure, heart-rate, oxygen levels (e.g., SPO₂), and so forth.

The portable NMR/Multisensor device 102 is configured for different levels of functionality depending on the requirements of a given use case. For example, in a first scenario, the portable NMR/Multisensor device 102 is configured for NMR operation only. In this configuration both the cost and geometry of the unit are optimized with reduced component count. An embodiment of the portable NMR/Multisensor device 102 is that all NMR or sensor modules are added or removed with ease, leading to ease of assembly, disassembly during manufacturing or for field repairs if necessary. Modularity is achieved by either screw-in type interlocking methods in conjunction with pogo type connectors or magnetic locking mechanisms which provide retention forces to mating modules. Either of these methods implements an interconnect for sub-assembly modules comprising the NMR/Multisensor device 102, including; the modules implementing the NMR/Multisensor apparatus and sample module(s); zero, one or more sensor modules; and an NMR/Multisensor base assembly module. In the simplest embodiment, magnetic locking mechanisms provide retention forces to attach the NMR/Multisensor device to the semi-autonomous or autonomous device or system.

In another embodiment, the magnetic locking mechanism can include electrical connections, for a magnetic electro-mechanical connector attachment (such as described in U.S. Pat. No. 7,311,526, the entirety of which is incorporated by reference herein) whereby both locking, power and data signal interconnections are achieved in mating both mechanically and electrically the NMR/Multisensor device to the semi-autonomous or autonomous device or system. In another embodiment, the magnetic electro-mechanical connectors securely interconnect and mate the NMR/Multisensor subassembly modules comprising the portable NMR/Multisensor apparatus. In another embodiment, magnetic electro-mechanical attachment mechanisms implement the embedding of more complex electronic and hardware within the NMR sample module such as NMR electronics and coils. In another embodiment, magnetic electro-mechanical connectors enable mating of one or more sensor modules to the NMR/Multisensor apparatus. Incorporating the use of magnetic electro-mechanical locking and interconnection mechanism within the plurality of NMR/Multisensor subassemblies and modules provides for both rapid connection and disconnection of different, apparatus, sample, and sensor module configurations in the field. In another embodiment, a configurable NMR sample module include different coil and RF sub-assembly configurations in terms of coil sensitivity, resonant frequency, and number of coils. In another embodiment a first NMR sample module utilizes a magnetic electro-mechanical interconnection and is designed for fluids and liquids, while a second NMR sample module utilizes a magnetic electro-mechanical interconnection and is design for solid matter. Other combinations comprising NMR-only, NMR/Multisensor, and sensors-only module configuration are feasible based on the use of magnetically electro-mechanical connections. In this manner, different configurations and functionality can be interchanged quickly and easily across all NMR/Multisensor device modules and sub-assemblies comprising the targeted configuration for the NMR/Multisensor device.

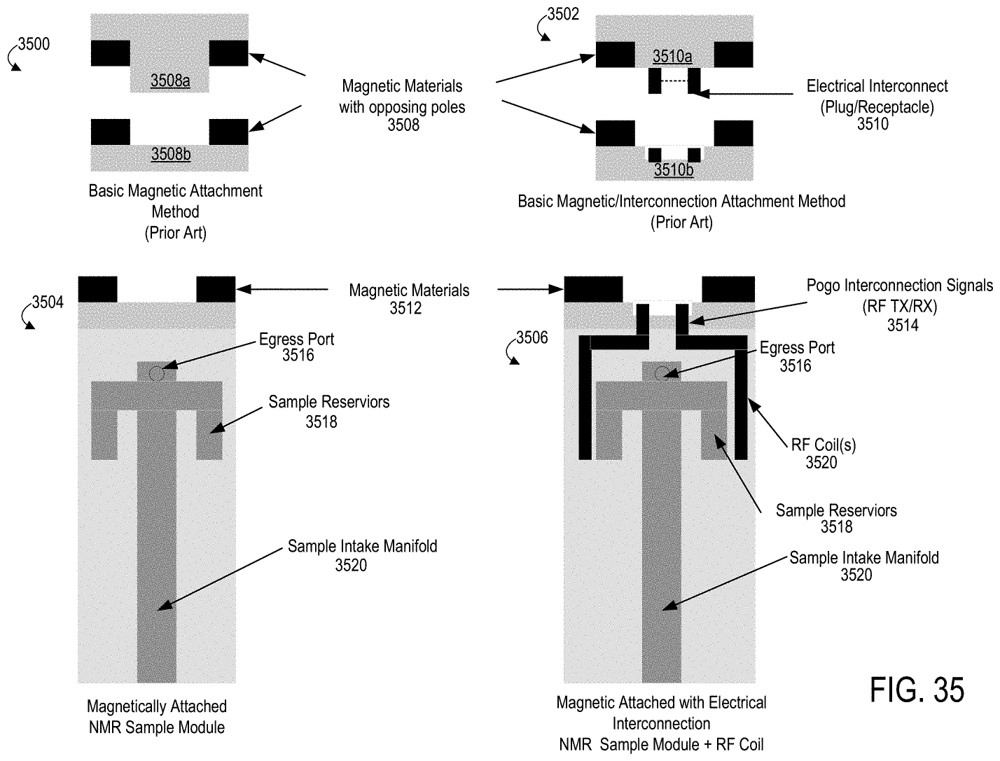

Turning briefly to FIG. 35, example embodiments of coupling mechanisms 3500, 3502, 3504, 3506 are shown based on the electro-mechanical interconnections previously described in relation to FIGS. 1A-1C. Coupling mechanism 3500 includes a magnetic attachment device having magnetic materials 3508 with opposing poles. As shown in coupling device 3500, the magnetic materials 3508 form a notch or slot 3508b for receiving a corresponding protrusion 3508a. As shown in coupling device 3502, which is similar to device 3500, an electrical plug 3510 or electrical connector can be integrated with the magnetic materials 3508. For example, a protrusion 3510a can include an electrical plug and the notch 3510b can include a receptacle for receiving the plug.

NMR sub-assembly 3504 (e.g., similar to sub-assemblies 102b) is configured to couple to the device 102 using magnetic materials 3512 in a manner similar to mechanisms 3500 and 3502. NMR sub-assembly 3504 includes additional hardware for sample storage, analysis, and removal. For example, the NMR sub-assembly 3504 includes an egress port 3516, sample reservoirs 3518, and a sample intake manifold 3520. The sample intake manifold 3520 enables the NMR sub-assembly 3504 to receive samples from an environment for data acquisition. In an example, the sub-assembly 3504 is lowered into liquid and fills the intake manifold 3520 with the liquid for storage in the sample reservoirs 3518. The egress port 3516 enables air or liquid to escape to empty the sub-assembly 3504.

In an example, the egress port 3516 and intake manifold 3520 enable flow and cleaning/emptying out of the sample reservoirs. In an example in which the NMR/Multisensor device 102 is coupled to a UAV or drone, the UAV is configured to lower down to a fluid or liquid level. The sub-assembly 3504 dips down so fluid collection occurs through intake manifold 3520. The liquid remains available in sample reservoirs 3518 so that the UAV can move away from the liquid in the environment, which can be turbulent or in general hazardous to the UAV. Additionally, requiring the UAV to hover above the liquid wastes power for drone flight time. In an embodiment, multiple NMR sub-assemblies 3504 (also called sample modules) are included for collecting multiple samples at different areas or environments. The NMR subassemblies 102b can be different lengths than one another and include differing reservoir set-points to facilitate multi-sample scenarios.

NMR subassembly 3514 of FIG. 35 is similar to sub-assembly 3504 and also includes RF coils 3520 that are interfaced with the coupling mechanism. The RF coils are positioned around the sample reservoirs 3518 and have leads extending up to the magnetic materials 3512 for the coupling mechanism of the sub-assembly 3514.

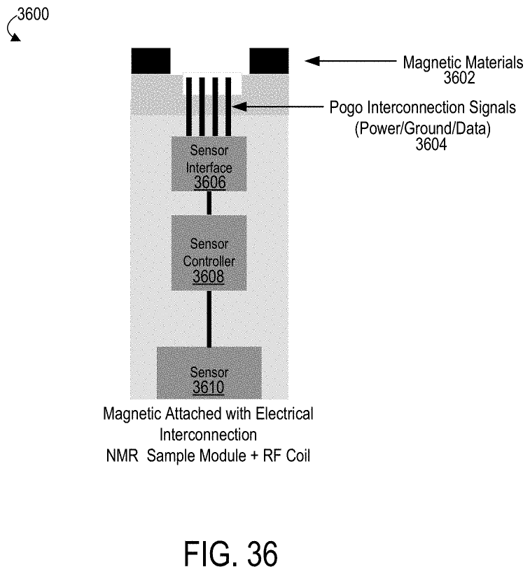

FIG. 36 shows an example of a sensor module 3600 (e.g., similar to sensor module 102a of FIGS. 1A-1C). The sensor module 3600 includes magnetic materials 3602 for a coupling mechanism (e.g., similar to mechanisms 3500, 3502 of FIG. 35). In this example, sensor data/power can be connected to the device 102 from the sub-assembly 3600 using a plug 3604. A sensor interface 3606 provides a connection from the sensor(s) of the module 3600 to the electronics of the NMR/Multisensor device 102, such as for transmission to a remote device for further processing. The interface 3606 can buffer the sensor data or otherwise prepare the sensor data for being accessed by the controller of the NMR/Multisensor device 102. A sensor controller 3608 is configured to control operation of the sensor(s) 3610 of the sensor module 3600, including activation/deactivation of the sensor 3610, calibration of the sensor, and so forth.

In a second scenario, the portable NMR/Multisensor device 102 has interfaces for both NMR and multi-sensor array modules 102a, 102b. The portable NMR/Multisensor device 102 includes a base module assembly and NMR coil module design that enable a fully additively manufactured apparatus. In some implementations, the portable NMR/Multisensor device 102 is produced as an integrated unit in which the integrated set of components include both structural components and required digital and analog electronics, system on a chip (SoC), circuits, discrete components, and magnetics. The portable NMR device 102 can also include additively manufactured coil assemblies. In this case, and similar to the first scenario, the independent modules include the NMR sample module; zero, one or more sensor modules; and the NMR/sensor base assembly module all mate relative to one another utilizing the magnetic locking mechanism previously described.

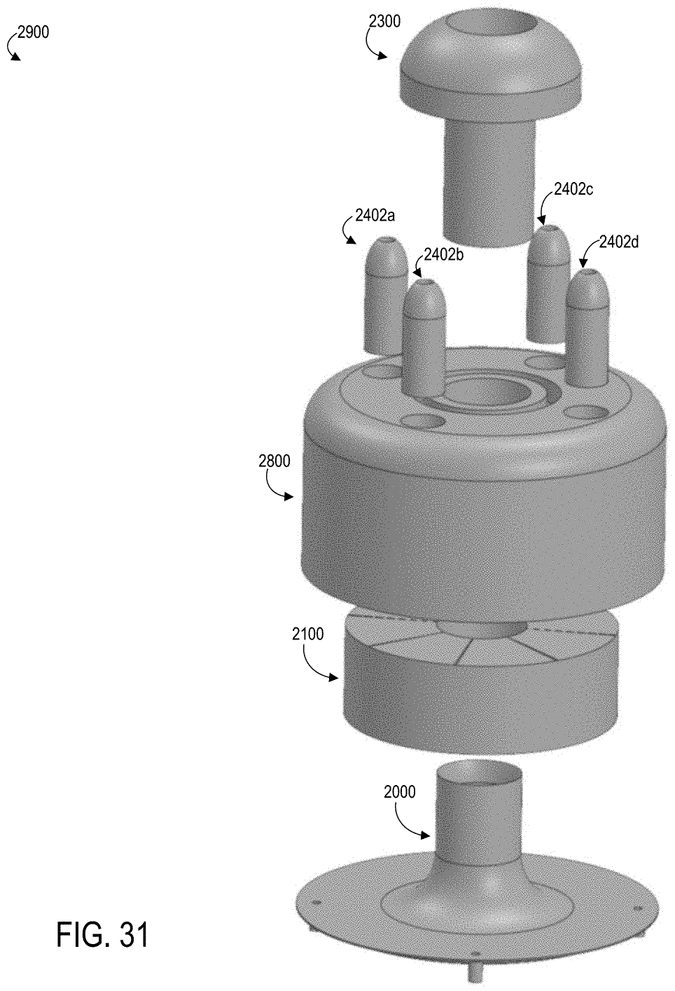

To produce the NMR and sensor subassemblies (such as those described in relation to FIGS. 35-36), a multi-material, multi-axis additive manufacturing system is configured to simultaneously print the NMR Apparatus and/or NMR Sample module at the same time. In an embodiment, the module 3506 including the shown sample module geometry, RF coil, passive components and magnetic electromechanical interconnect are a single, hermetically-sealed assembly. This process is described in application Ser. No. 17/155,976, filed Jan. 22, 2021, the contents of which are incorporated by reference in entirety. The above scenarios are subsequently described in detail in relation to FIGS. 18-31 and 34.

In some implementations, the fully additively manufactured portable NMR device 102 is a single manufactured assembly in which all modules are additively manufactured in one unified process such that the resulting assembly is hermetically sealed. For example, the NMR module, sensor modules, application host, and other components are included inside a single additively manufactured structure made of one or more materials that a multi-axis, multi-tool, multi-material additive manufactured system utilizes to fabricate the desired target geometry and functional characteristics. In one embodiment, the NMR/Multisensor apparatus, NMR sample module, and RF coil assembly, or collectively the portable NMR/Multisensor device, is fabricated by an additive manufacturing system process that consists of one tool deposing a structural material such as a thermoplastic across one or more axes of movement, whereas the additive manufacturing system with a second tool disposes across one or more axes of movement (which can be different from the first tool) conductive material in the fabrication of one or more NMR RF coils. The materials are additively manufactured in a single process workflow so that there are no seams or seals in the structure. The same processes steps previous described apply to the additive manufacturing of the one or more sensor devices in a similar method. The portable NMR/Multisensor device 102 is thus resistant to fluidic environments including liquids and gases, as well as environments experiencing variation or high levels of temperature or humidity. In this example, the portable NMR/Multisensor device 102 is fully enclosed with power supplied by rechargeable batteries (such as by near field charging) and communication is performed using wireless links. In one embodiment power and data can be supplied through magnetic and/or water-resistant interconnectors as described previously.

The portable NMR/Multisensor device 102 is coupled to the semi-autonomous or autonomous device 104. In either of the mobile 112 or stationary 114 scenarios described, the portable NMR/Multisensor device 102 communicates directly with the application host 106, generally in parallel with the autonomous device 104. The application 116 operates at the network layer and thus detects communications by the autonomous device 104 and the portable NMR/Multisensor device 102 in a transparent manner.

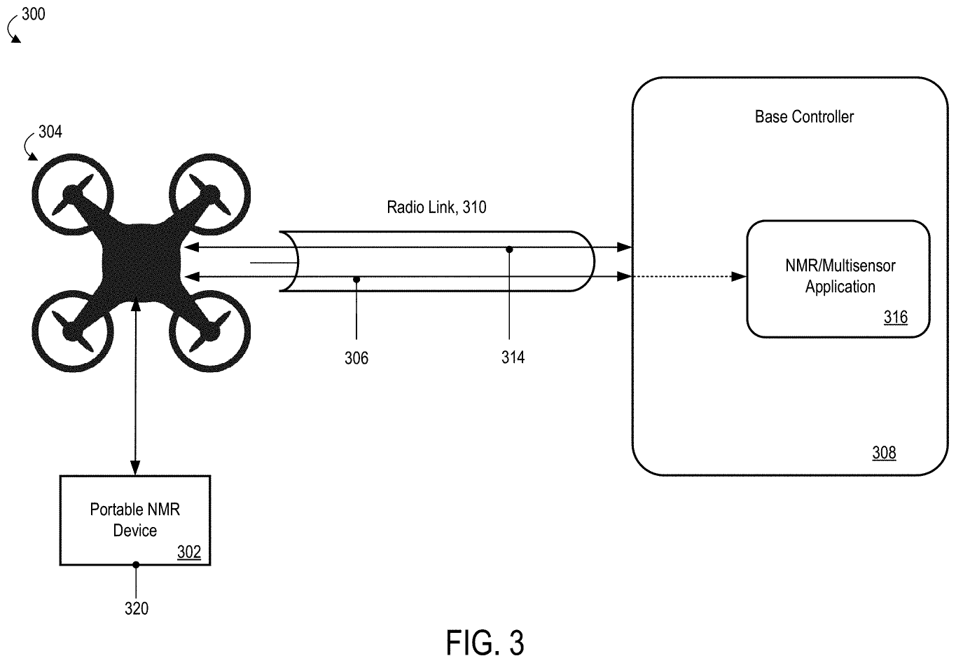

As subsequently described in relation to FIGS. 3-5B, there are generally two ways for device 102 to communicate with application apparatus or host 106. A first communication scenario includes communicating through the autonomous or semi-autonomous device 104 using that device 104 as a proxy for communications and networking. In this case, device 104 is configured to forward all messages from portable NMR/Multisensor device 102 to apparatus or host 106. The operations are at a network level that is transparent to the device 104.

A second communication scenario includes direct communication from NMR/Multisensor device 102 to apparatus or host 106 without providing the data to the autonomous or semiautonomous device 104.

While additive manufacturing is one potential process to produce the portable NMR/Multisensor device 102, the portable NMR/Multisensor device is manufactured in accordance to other methods not described in this application.

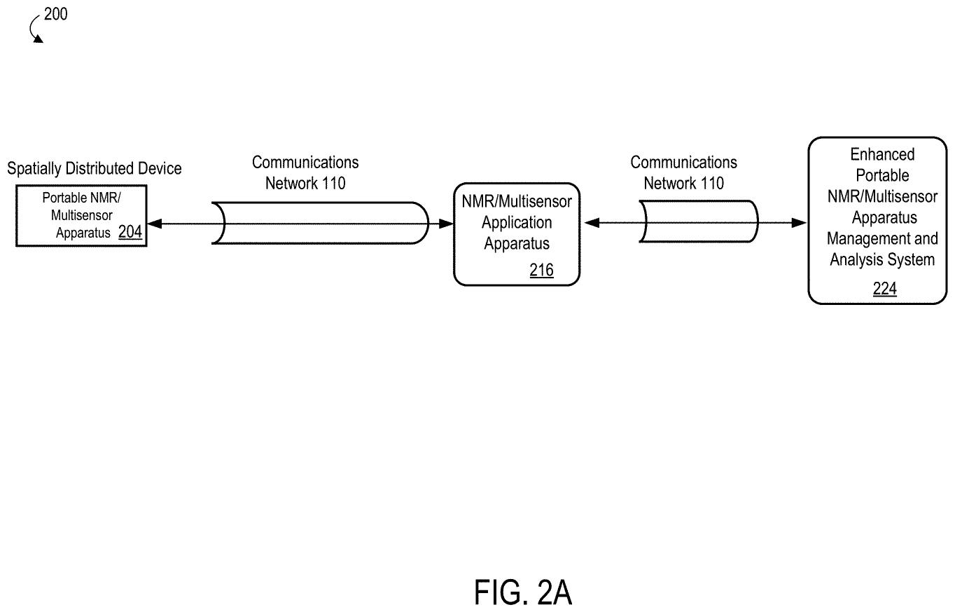

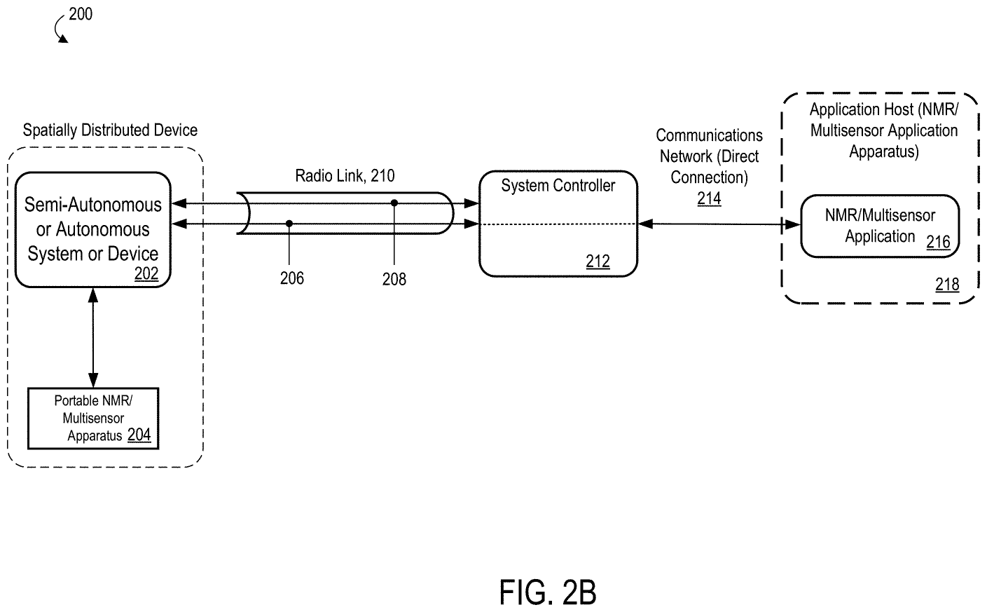

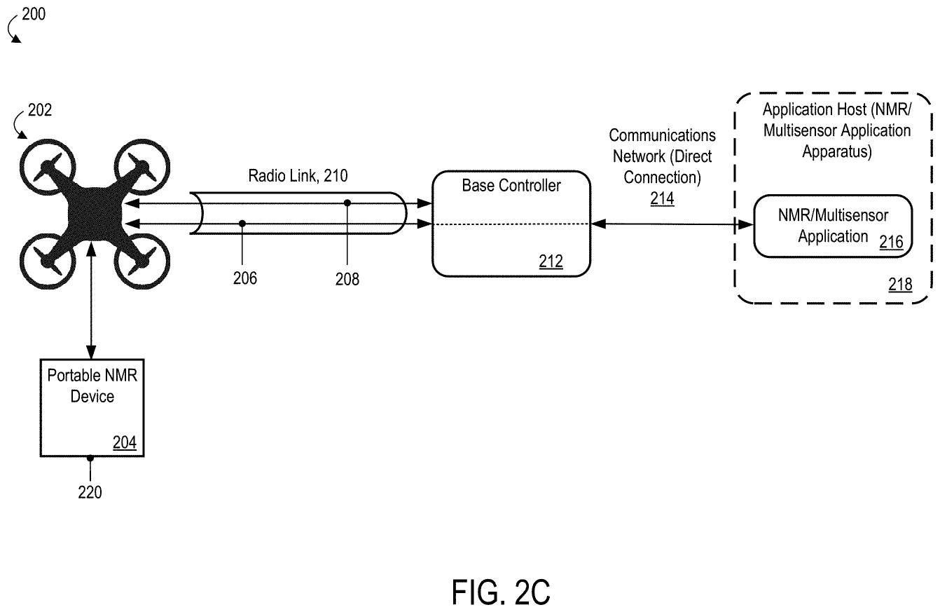

FIGS. 2A-2C illustrates an example embodiment 200 of the systems 100a-c of FIGS. 1A-1C. In FIG. 2A, the portable NMR/Multisensor device 204 (e.g., similar to device 102 of FIGS. 1A-1C) communicates over communications network 110 to an application apparatus 216. Application apparatus 216 communicates over network 110 to a remote processing system 224 configured to process the acquired data as described below.

In FIG. 2B, the portable NMR/Multisensor device 204 is configured to communicate with a system controller 212 through the autonomous or semiautonomous device 202. The device 202 communicates to the system controller using a radio link 210. The system controller 212 can control multiple, spatially distributed instances of the device 202 over the radio link 210. The system controller 212 receives acquired data from the device 204 and sends the acquired data over a communications network 214 to the application host 218 (e.g., similar to host 106 previously described).

In FIG. 2C, the semi-autonomous or autonomous device 104 includes an UAV 202 (e.g., a drone). The UAV 202 includes an instance of a portable NMR/Multisensor device 204 (e.g., similar to portable NMR/Multisensor device 102, described herein). The portable NMR/Multisensor device 204 is integrated to the UAV 202. The portable NMR/Multisensor device 102 is configured to use systems of the UAV 202 that support UAV operations. These systems include, for example, a power system and a communications systems present on the UAV 202 that are also used for UAV operations such as propulsion and navigation. The UAV includes power and communications network 214 (shown as an IP network traversing a radio link 210 and some communications network such as USB, Ethernet, or wireless) in order to communicate with the application 216 (e.g., the NMR/Multisensor Application software described previously) residing on an application host 218 (e.g., the NMR/Multisensor Application apparatus hardware 208 described previously). For example, the portable NMR/Multisensor device 204 is associated with a network address 220 (e.g., IPv4/IPv6 IP, NETMASK) to communicate at the network level. A UAV base controller 212 provides a communications path between each network end-point providing the function of a transparent network bridge to both the portable NMR/Multisensor device 204 and the application 216. For example, the communications paths include a NMR network multi-protocol transparent bridge 206 to link the portable NMR/Multisensor device 204 to the base controller 212 and a UAV radio link 208 to link the UAV to the base controller 212.

In another embodiment, the multi-protocol transparent bridge operation can be replaced by a layer-2 routing operation, provided the equivalent communications functionality is achieved. Additionally, it should be understood that multi-protocol communications includes IPv4/IPv6 delivery, as well as physical transports (MAC layer frames of the underlying delivery method) over any combination of unicast, multicast and broadcast distribution methods.

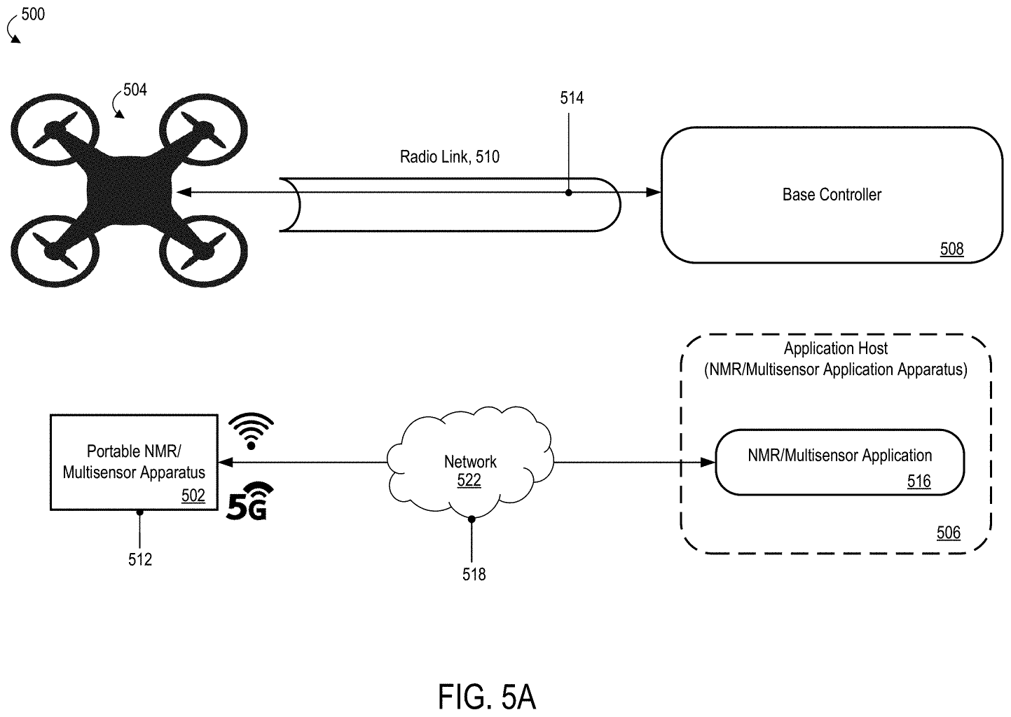

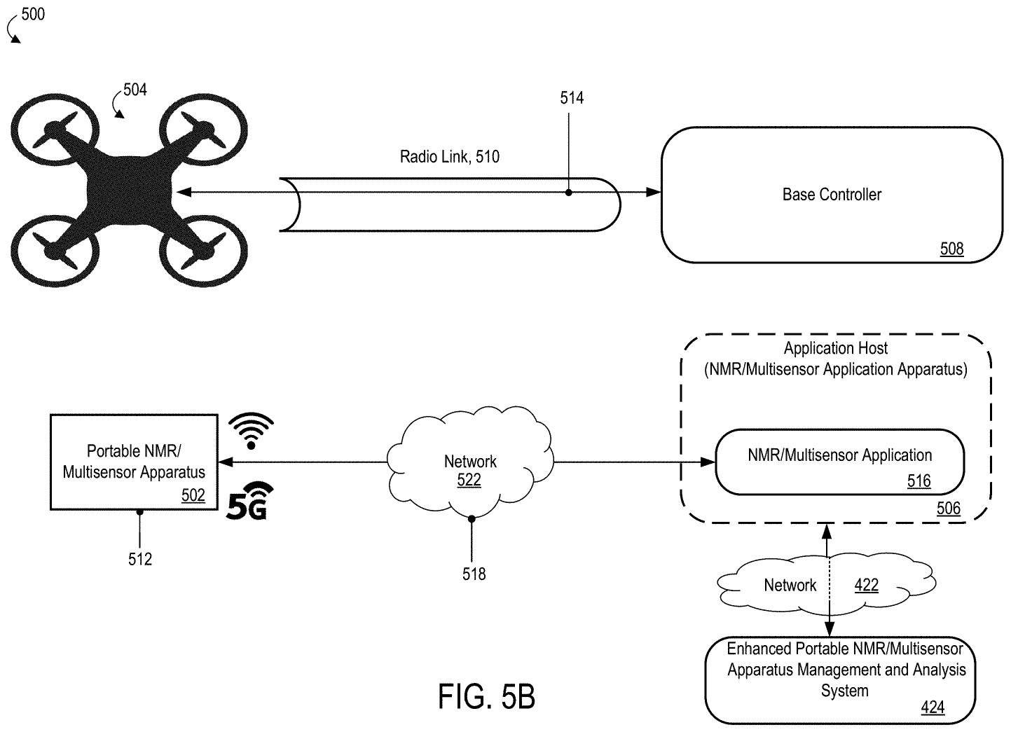

In one other embodiment, the portable NMR/Multisensor may communicate with the NMR/Multisensor Application apparatus independently of the semi-autonomous or autonomous device using a dedicated communications system such as wireless WiFi or cellular technologies. FIGS. 5A-5B illustrate this embodiment, as subsequently described. For any of the embodiments or configurations described throughout this document, either the first communication scenario including a transparent bridge (as described in relation to FIGS. 2B-4) or the second communications scenario including independent communication of the NMR/Multisensor device over a separate network (e.g., WiFi, cellular, etc.) can be used.

FIG. 3 illustrates an example embodiment 300 of the systems 100a-c of FIGS. 1A-1C. System 300 shows an example portable NMR/Multisensor device 302 (e.g., portable NMR/Multisensor apparatus) that is included in a semi-autonomous or autonomous device including a UAV 304 (similar to UAV 202 of FIG. 2). In system 300, an application 316 (e.g., similar to NMR/Multisensor application 116 of FIGS. 1A-1C) is included on the UAV base controller 308. There is independent NMR/Multisensor application apparatus hardware. Similar to the portable NMR/Multisensor device 204 of system 200 of FIG. 2, the portable NMR/Multisensor device 302 is associated with a network address 320 (e.g., IPv4/IPv6 IP, NETMASK) to communicate at the network level. The UAV base controller 308 provides a communications path between each network end-point providing the function of a transparent network bridge to both the portable NMR/Multisensor device 302 and the application 316. For example, the communications paths include a NMR/Multisensor network (capable of transporting both NMR and multisensor datasets) multi-protocol transparent bridge 306 to link the portable NMR/Multisensor device 302 to the base controller 308 and a UAV radio link 314 to link the UAV to the base controller 308. System 300 includes software processes associated with the portable NMR/Multisensor device 302 and the NMR/Multisensor application 316 may be located or reside among multiple scenarios including residing with the semi-autonomous or autonomous device 304.

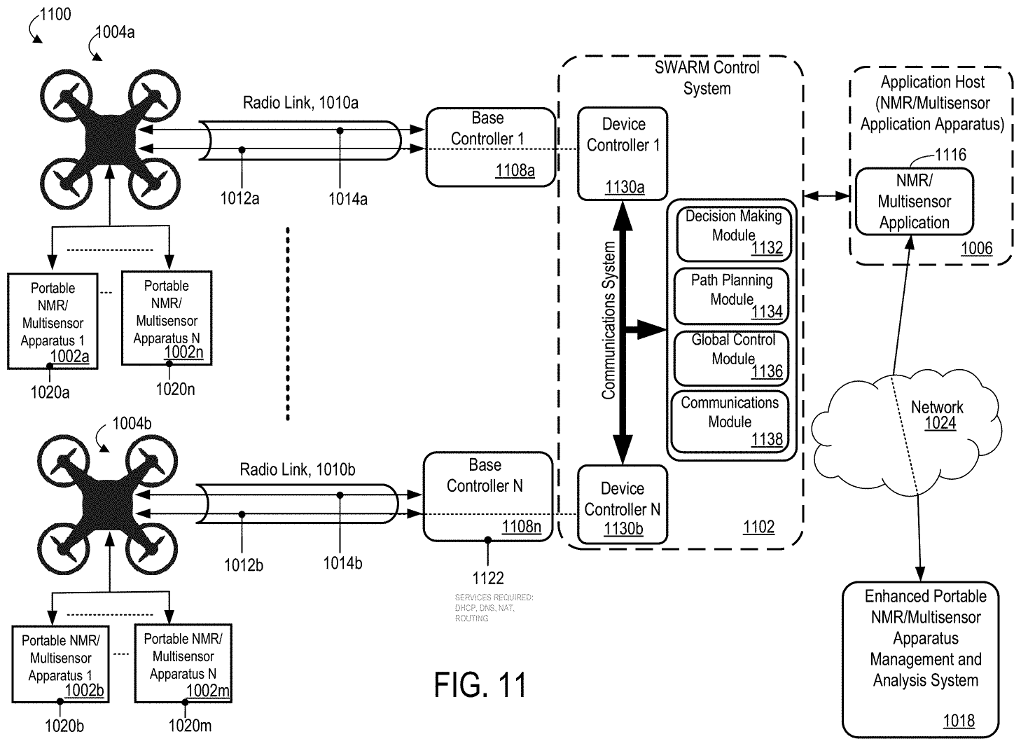

In some implementations, the systems 200, 300 include a collection of autonomous robotic systems or devices (for example in a manufacturing environment). The autonomous systems 202, 304 each includes a robotic actuator under programmatic control, a respective portable NMR/Multisensor device (e.g., device 204 or 302), and an application 216, 316, organized in an interconnected manner in a base controller. The interconnected systems achieve an enhanced functionality. For example, the commands for the semi-autonomous or autonomous devices 204, 302 (e.g., including a robotic actuator set of actions or behavior) adapt or change in response to telemetry provided by co-processing of the application 216, 316 instances. In some implementations, a network of autonomous robotic systems (e.g., including semi-autonomous or autonomous device 104 and/or UAVs 204 and 302) or devices perform a collective operation or behavior. The collective operation is controlled by the collective processing of telemetry received from one or more instances of the portable NMR/Multisensor devices 104 and respective application 116 instances executing on the base controller 308. This example is subsequently described in greater detail with respect to FIG. 11, which illustrates a swarm autonomous system or device control scenario.

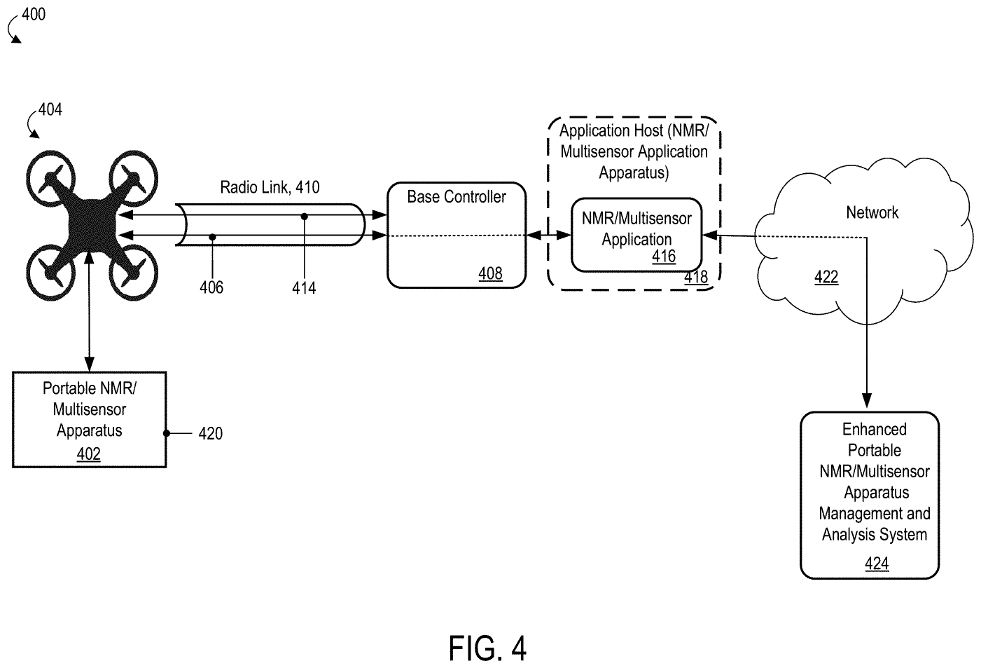

FIG. 4 illustrates an example system 400 (similar to systems 200, 300 of FIGS. 2-3) in which additional instances of the portable NMR/Multisensor device 402 or the semi-autonomous or autonomous device 404 is added for scalability. More specifically, additional autonomous or semi-autonomous operational and software functionality are included, additional computational power is available, and system services are realized by enabling the portable NMR/Multisensor device 402 and/or NMR/Multisensor application 416 to communicate with a remote computing system 424 (executing the enhanced portable NMR/Multisensor device management and analysis system, similar to system 108 of FIGS. 1A-1C). The management system 424 is accessible over a network 422, which is based on Internet standards based network technologies including transports such as; optical, broadband, wireless or cellular; or combinations thereof, and similar to communication networks illustrated in 110 of FIGS. 1A-1C. The UAV 404, similar to semi-autonomous or autonomous device 104 of FIGS. 1A-1C, is configured to communicate over radio link 410 at the network level, as previously described. The UAV base controller 408 provides a communications path between each network end-point providing the function of a transparent network bridge to both the portable NMR/Multisensor device 402 and the application 416 on application host 418. For example, the communications paths include a NMR/Multisensor network multi-protocol transparent bridge 406 to link the portable NMR/Multisensor device 402 to the base controller 408 and a UAV radio link 414 to link the UAV to the base controller 408.

FIG. 5A illustrates a system 500 in which a portable NMR/Multisensor device 502 (similar to portable NMR/Multisensor device 102) includes an integral communications capability. The capability includes WiFi, cellular, radio technology, USB, and so forth. The portable NMR/Multisensor device 502 is configured to independently communicate with any other component of the application host 506 (e.g., an NMR/Multisensor application apparatus), a NMR/Multisensor application 516, or an NMR/Multisensor remote computing software platform (not shown). The semi-autonomous or autonomous device 504 does not need to satisfy any no communications requirement in this example; rather the portable NMR/Multisensor device 502 communicates independently. This is in contrast to systems 100-400 previously described, in which the communications utilizes the communications and network capability of the autonomous device 104. In this example, the portable NMR/Multisensor device 502 includes network hardware/software 512 to support network level communication, such as IPv4/IPv6 IP, a Netmask, a gateway, a DNS resolver, and so forth. The network 522 is configured for services 518 including DHCP, DNS, NAT, and routing. The semi-autonomous or autonomous device 504 communicates over a separate link 510, such as a radio link 514, to the base controller 508, or otherwise device hosting the NMR/Multisensor application as depicted in the various scenarios described.

FIG. 5B shows a communication scenario similar to that described in relation to FIG. 5A, except that the enhanced portable NMR/Multisensor apparatus management and analysis system 424 is connected over a network 422 to the application host 506. In this example, the system 424 is configured to manage and control one or more instances of portable NMR/Multisensor apparatus 502 and semi-autonomous or autonomous device 504 coupled to the device 502. Network 422 can be a direct connection, as described in relation to FIGS. 2B, 2C, and 4.

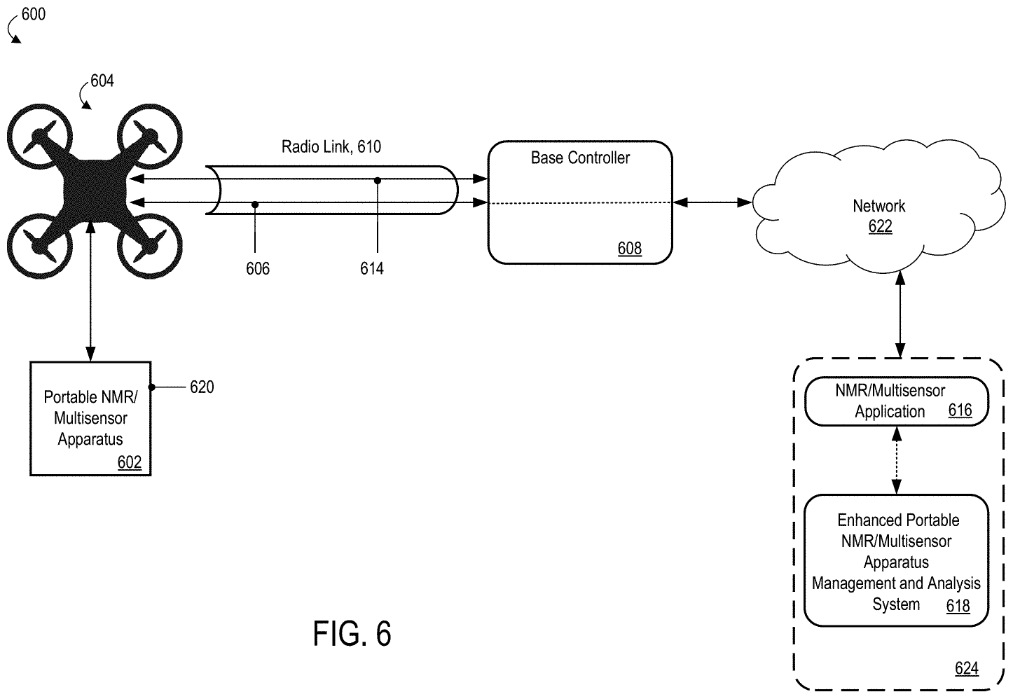

FIG. 6 illustrates a system 600 similar to systems previously described. In system 600, the NMR/Multisensor application 616 is located within the NMR/Multisensor remote computing software platform 618. In this scenario, the portable NMR/Multisensor device 602 communicates directly across a network 622 to the NMR/Multisensor remote computing software platform 618. As with systems previously described, the portable NMR/Multisensor device 602 is configured to communicate at the network level using protocols 620 such as IPv4/IPv6 IP and NETMASK. Communications links 606, 614 on the radio link 610 support NMR/Multisensor network multi-protocol transparent bridge UAV radio link, respectively, to the base controller 608. The application 616 and the management system 618 can each be executed on an application host 624, similar to application host 106.

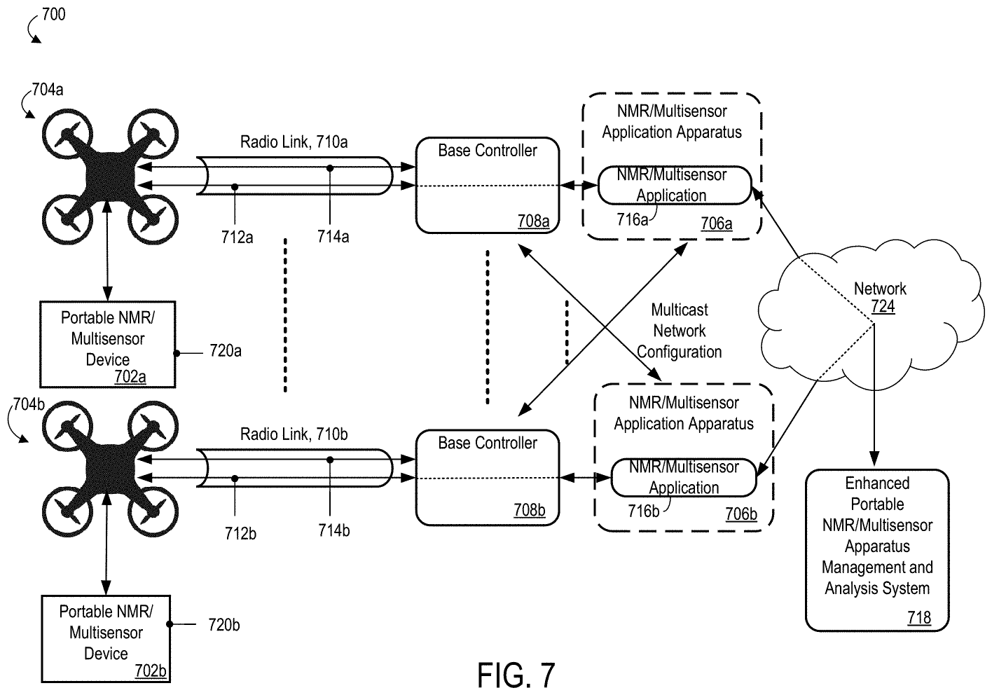

FIG. 7 illustrates a system 700 similar to previously described systems in which multiple semi-autonomous or autonomous devices 704a-b, each with at least one respective portable NMR/Multisensor device 702a-b and NMR/Multisensor application host 706a-b execute a respective NMR/Multisensor application 716a-b. The remote computing device 718 (similar to device 108) is configured for enhanced portable NMR/Multisensor device 102 management. Generally, the remote computing device 718 is configured to manage one or more portable NMR/Multisensor devices 702a-b, such as communications among the devices 702a-b, associated application hosts 704a-b, and associated NMR/Multisensor application 716a-b software processes. Management in this scenario includes determining which processes control which devices 704a-b. In an example, the devices 704a-b are coordinated to take samples in different areas in an environment to facilitate coverage of the environment.

In some implementations, the devices 704a-b can operate as a swarm. In some implementations, device 704a is instructed by the application 716a based on data received from device 704b at application 716b. Analytics and control are thus performed such that the entire swarm of portable NMR/Multisensor devices 702a-b and autonomous or semi-autonomous devices 704a-b are working together to accomplish an objective. For example, a swarm of UAV devices (e.g., devices 704a-b) can be utilized as part of an oil or chemical pollution response or water quality monitoring application. In this scenario the area of interest (e.g., geography containing the oil or chemical pollution, or a network of water supplies) is partitioned into a search space that the swarm of UAV devices 704a-b operate upon by applying collective intelligence methods to converge towards fully characterizing the oil, chemical, or water properties or pollution. Input into the swarm intelligence decision making is based on measurements or sampling of the underlying search space.

Current implementations rely on imaging data from a UAV to provide input measurement data to the decision-making and path-planning systems of the swarm control platform. The use of camera imaging data for the described example is outlined in Ball Z, Odonko P., “A SWARM-Intelligence approach to oil spill mapping using Unmanned Aerial Vehicles”, 2017, AIAA Information Systems, incorporated in entirety herein by reference. Camera-based imaging analysis is often noisy and can lead to inaccurate results due to incorrect classification of image samples as cited in Ball. A swarm-based system utilizing UAV devices (e.g., semi-autonomous or autonomous devices 704a-b) for oil or chemical pollution, or water quality monitoring can be improved by replacing the image sampling system with at least one of NMR/Multisensor devices 702a-b whose sample analysis can accurately predict chemical properties of each sample based on actual measurement of chemical properties.

The NMR chemical detection and analysis can be aggregated with additional multi-sensor data measured from additional chemical, gas, and environmental sensors to further improve the accuracy of the sample analysis process. In a similar manner, all NMR/Multisensor analyzed and classified samples are conveyed to neighboring swarm devices 704a-b and the application 716a-b and 718 as part of executing the given swarm intelligence platform.

In a second example, the swarm of portable NMR/Multisensor devices may comprise a portable desktop or lab based NMR/Multisensor, each geographically distributed and configured to detect and measure biological agents, events, and properties of respective samples provided to the system. In this scenario, the swarm network of portable NMR/Multisensor devices are semi-autonomously or autonomously generating a real-time map of biological events that can be utilized to predict spread of diseases or other bacterial or viral spread patterns by harvesting and processing in real-time all NMR/Multisensor detected, measured, and analyzed data that is shared across all devices and application 718.

Each of the devices 702a-b and 704a-b can operate in a separate respective radio link 710a, 710b, and use respective protocols such as NMR/Multisensor network multi-protocol transparent bridge 712a-b, UAV radio links 714a-b, and IPv4/IPv6, IP, and Netmask protocols 720a-b. The application hosts 706a-b and management system 718 can communicate over a wired or wireless network 724, which is similar to communications network 110. Each of the NMR/Multisensor devices 702a-b can also communicate with one another as part of the swarm network. For example, each portable NMR/Multisensor 702a-b includes an independent communications system enabling communications among devices for sharing of data as part of coordination and collective operation. In some embodiments, the base controllers 708a-b are configured to communicate with application hosts 706a-b over a multicast network, as previously described.

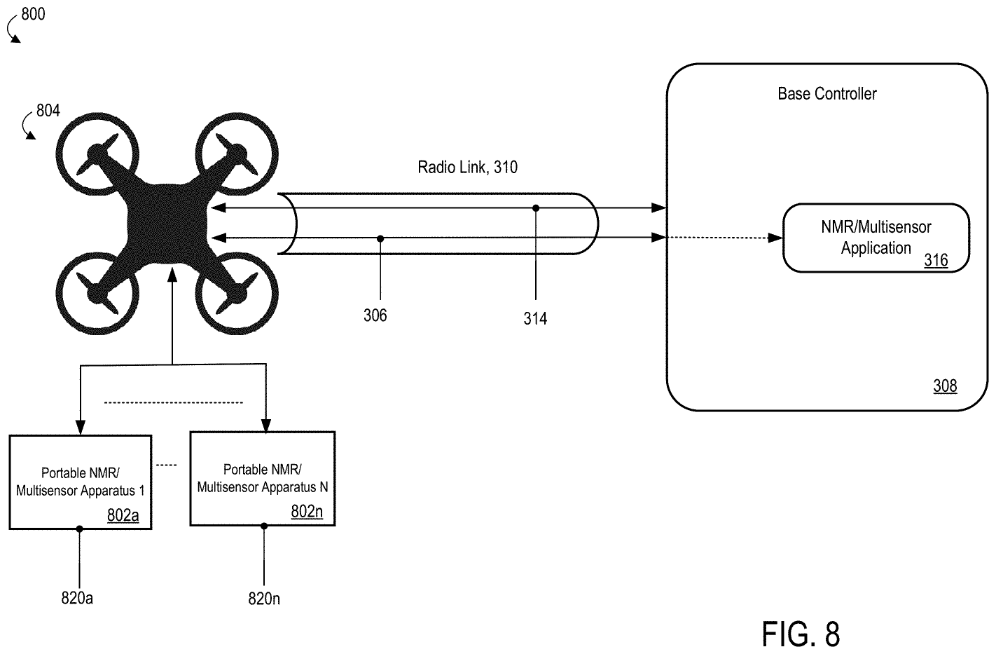

FIG. 8 is an illustration of a system 800 in which the UAV 804 is associated with multiple portable NMR/Multisensor devices 802a to 802n. Similar to semi-autonomous or autonomous device 304 of FIG. 3, the UAV 804 is configured to communicate over an IP network over a common radio link 310 provided by the UAV device 304, including a UAV radio link 314 and a NMR/Multisensor network. The UAV 804 is configured to utilize multiple portable NMR/Multisensor devices 802a-n each with independent configurations 820a-n and ability to perform different measurement or test operations for the generation of more complex, diverse, or accurate telemetry. In addition said multiple portable NMR/Multisensor devices 802a-n telemetry datasets are used by the semi-autonomous or autonomous device 804 or another semi-autonomous or autonomous device (not pictured) to control or modify behavior of each of the semi-autonomous or autonomous devices in coordination.

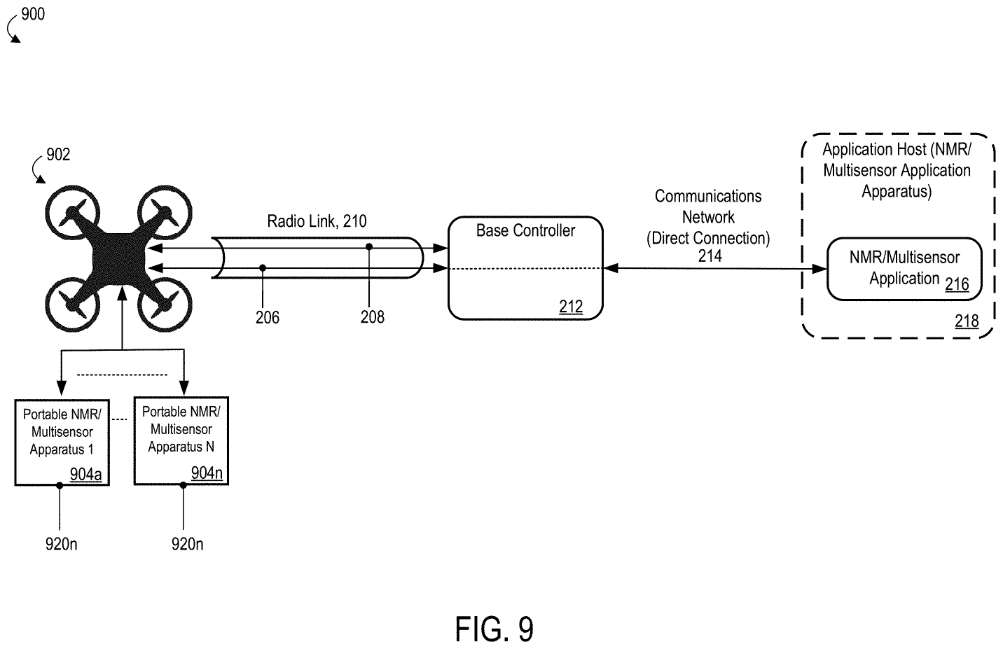

FIG. 9 is an illustration of a system 900 in which a UAV 902 (similar to UAV 204 of FIG. 2) is associated with multiple portable NMR/Multisensor devices 904a to 904n (each similar to portable NMR/Multisensor device 204 of FIG. 2). Similar to semi-autonomous or autonomous device 202 of FIG. 2, the UAV 902 is configured to communicate over an IP network over a common radio link 210 provided by the UAV device 202, including a UAV radio link 208 and a NMR/Multisensor network 206. The UAV 902 is configured to utilize multiple portable NMR/Multisensor devices 904a-n each with independent configurations 920a-n and ability to perform different measurement or test operations for the generation of more complex, diverse, or accurate telemetry. In addition the multiple portable NMR/Multisensor devices 902a-n telemetry datasets are used by the semi-autonomous or autonomous device 902 or another semi-autonomous or autonomous device (not pictured) to control or modify behavior of each of the autonomous devices in coordination.

In some implementations, a control plane (described further in relation to FIG. 11) is configured to independently manage multiple acquisition and analysis workflows (e.g., one associated to each NMR/Multisensor module 904a-n). A workflow includes an end-to-end process for configuration and calibration of the NMR/Multisensor; data detection, acquisition, transmission etc.; and one or more analysis cycles. The control plane detects functional capabilities of each attached NMR/Multisensor apparatus 904a-n and adjusts corresponding workflows automatically. For example, for different NMR/Multisensors including different hardware from one another, the workflow is configured automatically without user intervention or with minimal or non-technical intervention.

In an embodiment, each NMR sensor mounted on the NMR/Multisensor device or system 104 can include a magnetic and coil configuration that is different from at least one other NMR sensor on the autonomous device or system 104. Each NMR sensor can be configured to detect and analyze a particular (different) chemical shift from other NMR sensors. For example, different coils are included for respective different atomic spectra. Similarly, each NMR sensor module may include different gas or fluid or environment sensors. For example, NMR/Multisensor 904a can include configuration NMR/Coil 1 and a hydro-carbon gas sensor, and NMR/Multisensor 904b may include NMR/Coil 2 that has a different sensor designed to detect levels of some other chemical substance (e.g., dissolved in water-only). The NMR/Multisensor 904a is thus configured for liquids/gases, whereas the NMR/Multisensor 904b is thus configured for liquid/liquid environments.

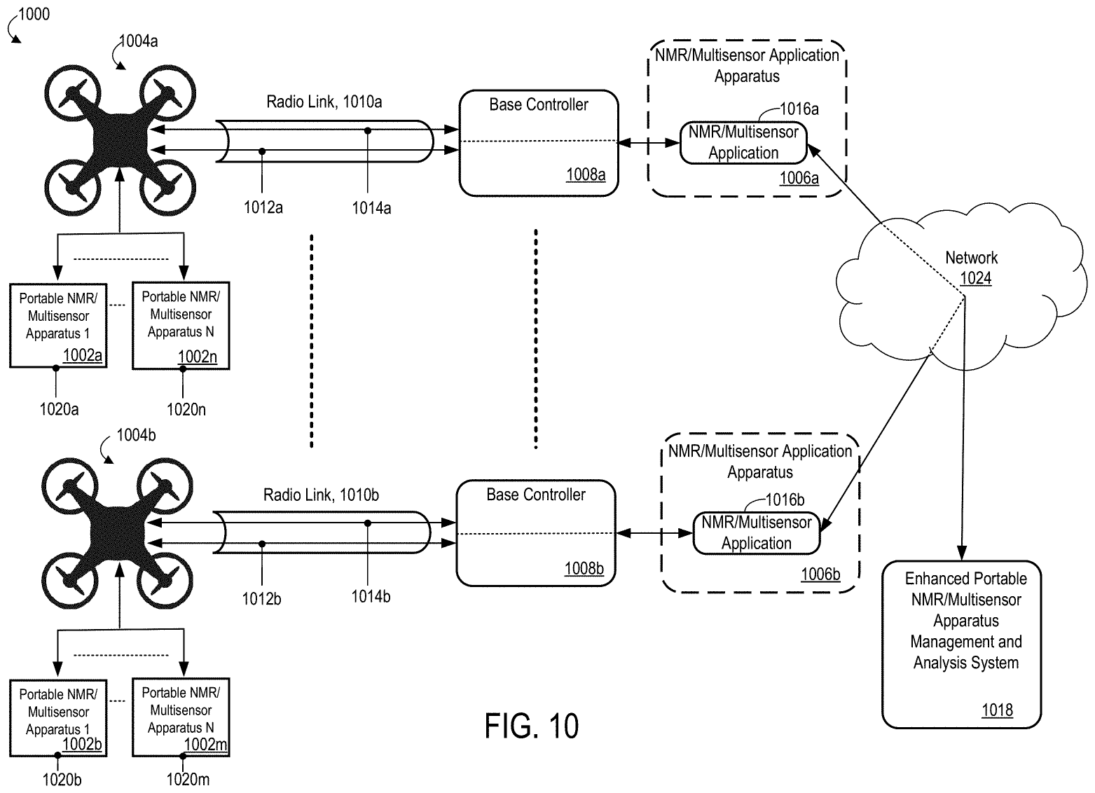

FIG. 10 illustrates a system 1000 similar to previously described systems in which multiple semi-autonomous or autonomous devices 1004a-b, each with multiple respective portable NMR/Multisensor devices 1002a-n and 1002b-m, respectively. Each semi-autonomous or autonomous device 1004a-b is associated with a respective NMR/Multisensor application host 1016a-b which is configured to execute a respective NMR/Multisensor application 1016a-b. The remote cloud computing device (also called an enhanced portable NMR/Multisensor apparatus management and analysis system) 1018 (similar to device 108) is configured for enhanced portable NMR/Multisensor device 102 management. Multiple NMR/Multisensor application apparatuses 1006a, 1006b and corresponding or resident NMR/Multisensor application software processes 1016a, 1016b utilize the remote cloud system 1018 for extended machine learning and analytics processing. The device 1018 can perform higher performance computing given greater hardware resources in comparison to portable computing systems. The cloud system 1018 is also configured to process global data-sets for analysis across all autonomous or semiautonomous devices 1004a-b. The device 1018 enables a global approach to data processing from the various NMR/Multisensor devices 1020a-n, as data from each of the devices 1020a-n can be processed in the context of data from other of the devices 1020a-n. In an example, each autonomous or semiautonomous device 1004a-b can be controlled to a particular location in an environment (described below in relation to FIG. 11) and gather data. The cloud device 1018 can receive all of these data and use it as inputs to a single processing model (e.g., a neural network, etc.).

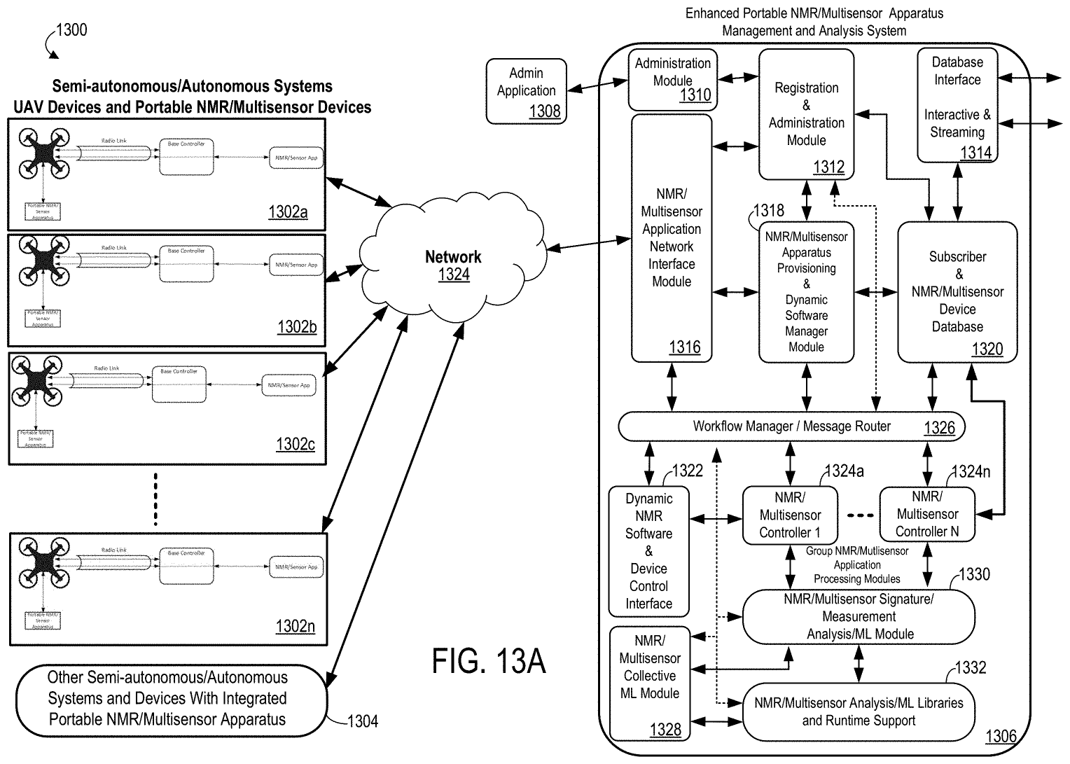

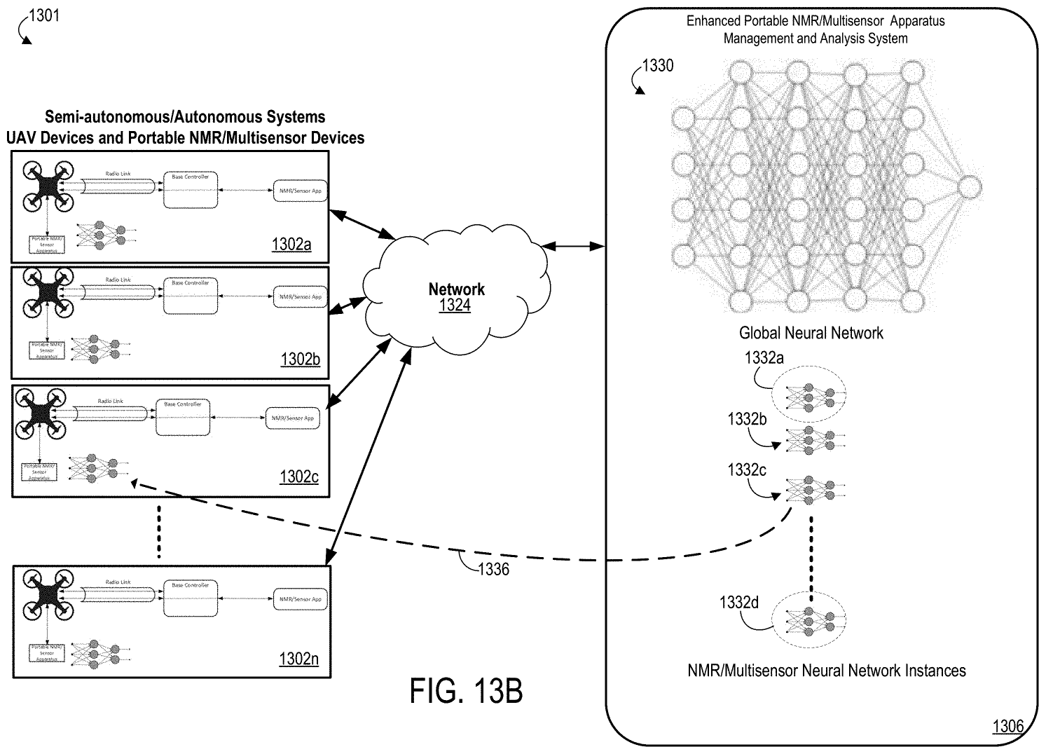

Generally, the remote computing device 1018 is configured to manage one or more portable NMR/Multisensor devices 1004a-b, such as communications among the devices 1004a-b, associated application hosts 1004a-b, and associated NMR/Multisensor application 1016a-b software processes. Management in this scenario can include1291 determining which processes control which devices 1004a-b. In an example, the devices 1004a-b are coordinated to take samples in different areas in an environment to facilitate coverage of the environment. In some implementations, the devices 1004a-b can operate as a swarm. In some implementations, device 1004a is instructed by the application 1016a based on data received from device 1004b at application 1016b. Analytics and control are thus performed such that the entire swarm of portable NMR/Multisensor devices 1004a-b are working together to accomplish an objective. Each of the devices 1002a-b and 1004a-b can operate in a separate respective radio link 1010a, 1010b, and use respective protocols such as NMR/Multisensor network 1012a-b. For example, the network can use UAV radio links 1014a-b, and IPv4/IPv6, IP, and Netmask protocols 1020a-n and 1020b-m, respectively, though the network can be a multiprotocol network configured for multicast, or broadcast oriented, etc. TCP/IP, or UDP/IP, or some other standard. The application hosts 7106a-b and management system 1018 can communicate over a wired or wireless network 1024, which is similar to communications network 110. Each of the multiple portable NMR/Multisensor devices 1004a-n and 1004b-m are associated with independent configurations and each have the ability to perform different measurement or test operations for the generation of more complex, diverse, or accurate telemetry. The cloud computing device 1018 provides enhancements over a single NMR/Multisensor application instance. In an example, the cloud device 1018 provides the platform for account/user-based software update and managements for all system components (e.g., except the devices 1004a-b). The cloud device 1018 performs data management and storage associated to one or more portable NMR/Multisensor devices 1002-an associated to an account. The cloud device 1018 provides a mechanism for scalable integrate global data from portable NMR/Multisensor devices 1002a-n to other systems. As subsequently described in relation to FIGS. 13A-13B, the cloud system 1018 is configured to perform analytics/machine learning on aggregated datasets for global intelligence. For example, the cloud system 1018 can perform global machine learning across full datasets from swarms/fleets of devices 1004a-b operating independently, collectively or combinations of both. The device 1018 can provide for reprocessing of ML algorithms for the individual portable NMR/Multisensor devices.

The cloud device 1018 provides global ML functionality and is additionally configured to preprocess/train ML algorithms that can then be sent to the individual portable NMR/Multisensor devices, described in relation to FIG. 13B. Effectively, the combination of the processing capability of the portable NMR/Multisensor in combination with the cloud backend (management and analysis) system comprises a distributed ML/learning architecture.

FIG. 11 shows a system 1100 that is similar to the system 1000 of FIG. 10. Here, a swarm control plane 1122 is included to further coordinate actions of the semi-autonomous or autonomous devices 1004a-b. In this example, rather than having independent base controllers controlled or managed by the remote management system 1018, the management system 1018 can send swarm commands to the swarm control plane 1102 which coordinates the base controllers 1108a-n. This can optimize the operation such as trajectory of the semi-autonomous or autonomous devices 1004a-b for collective or swarm based goal objectives. The collective or swarm control plane 1122 manages the multiple semi-autonomous or autonomous devices 1004a-b to a common operation or task or distributes tasks among the devices based on which devices are best for performing each task. For example, each semi-autonomous or autonomous device 1004a-b is configured to specialize in a particular kind of data acquisition, and data describing this functionality are stored at the application host 1006 along with an identifier of the associated semi-autonomous or autonomous device. When a particular task is to be performed, the associated device 1004a-b that is optimized to handle the task is selected to perform it.

The portable NMR/Multisensor devices 1002a-n and 1002b-m provide telemetry to the semi-autonomous or autonomous devices 1004a-b, which forward the data to the control plane 1122. In some implementations, the portable NMR/Multisensor devices 1002a-n and 1002b-m directly provide the telemetry to the collective or swarm control plane 1122. The control plane 1122 which receives the input telemetry and assigns portions of the data as state variables for use within the collective or swam processing framework. Additionally, the collective or swarm control plane 1102 may actuate, through command-and-control operations, one or more of the portable NMR/Multisensor devices 1004a-b in order to manipulate or modify the respective portable NMR/Multisensor device configuration, behavior or operation. As previously stated, the control plane 1122 can communicate (e.g., over network 1024) with the NMR/Multisensor application host 1006, the application 1016, the enhanced portable NMR/Multisensor device management and analysis system 1018 software platform to facilitate collective or swarm control plane processing, coordination, and orchestration functionality.

The control system 1102 can control multiple NMR/Multisensor devices 1002a-n residing across a population of semi-autonomous or autonomous devices or systems 1004a-b can form clusters implementing a swarm-based intelligence approach in solving a plurality of problem and applications. Generally, swarm intelligence includes a form of artificial intelligence methods wherein global optimization of an objective is achieved based on collective behavior or decentralized agents that self-organize in finding an optimal solution to a given problem or task. Swarm intelligence implementations derives from a number of algorithmic approaches to orchestration and coordination of semi-autonomous or autonomous agents, including Particle-Swarm Optimization (PSO) and biological inspired methods such as Ant Colony Optimization (ACO), described in Kennedy, J.; Eberhart, R. C. (2001). Swarm Intelligence. Morgan Kaufmann. ISBN 978-1-55860-595-4, the contents of which are incorporated herein in entirety. In terms of swarm-based implementation architectures, multiple approaches to swarm-based control systems are described in Jovan D. Boskovic, Ravil K. Prasanth, Raman K. Mehra: A Multi-Layer Autonomous Intelligent Control Architecture for Unmanned Aerial Vehicles. J. Aerosp. Comput. Inf. Commun. 1(12): 605-628 (2004), incorporated in entirety herein, as the basis for a multi-layer architecture for intelligent control of UAV device swarms. In this architectural approach, a swarm-based system is decomposed into five layers comprising; decision-making, path-planning, control, communications, and application layers. In a similar manner, the swarm control system is decomposed into five functional modules as illustrated in the NMR/Multisensor swarm control system 1102.

The swarm control system 1102 can include respective device controllers 1130a-b for sending/receiving commands or data to and from devices 1004a-b. The swarm controller 1102 includes a decision making module 1132, a path planning module 1134, a global control module 1136, and a communications module 1138.

The decision making module 1132 is configured to coordinate actions among the devices 1004a-b, such as executing the intelligence algorithms (e.g., PSO, ACO, etc.) previously described. The path planning module 1134 and global control modules 1136 are configured to control navigation of autonomous or semi-devices 1004a-b and data acquisition for the respective NMR/Multisensor devices 1002a-n by generating respective commands based on the results of intelligence algorithms of the decision making module 1132. These commands are sent to respective base controllers 1108a-n.

As shown in FIG. 11, multiple portable NMR/Multisensor devices 1002a-n and 1002b-m telemetry datasets are used by the semi-autonomous or autonomous devices 1004a-b or other semi-autonomous or autonomous devices (not pictured) to control or modify behavior of each of the semi-autonomous or autonomous devices in coordination. In an example, the communications module 1138 manages communications to each portable NMR/Multisensor device 1004a-n and 1004b-m, respectively. The controller can add local network addresses to each of the portable NMR/Multisensor devices (e.g., associated with respective configurations 1020a-n and 1020b-m). Different portable NMR/Multisensor devices 1002a-n and 1002b-m can be assigned different priorities for communication to application hosts 1006a-b. The management system 1102 can resolve priority conflicts between and among different application hosts 1006a-b. In some implementations, the resources of a first application host (e.g., host 1006a) is used by the second application instance (e.g., application 1016b). This can occur if, for example, portable NMR/Multisensor devices 1002b-m associated with UAV 1004b require more computing resources (e.g., for a period) than those portable NMR/Multisensor devices 1002a-n associated with UAV 1004a. For example, the portable NMR/Multisensor devices 1002b-m associated with UAV 1004b could obtain more data than can be processed locally on the UAV 1004b hardware, and so part of this processing is outsourced to a remote device, such as the other UAV 1004a or a remote computing system. The management system 1018 can schedule these changes so that control of the UAVs 1004a-b is real-time or near real-time. The flexibility of assignment of computing resources among the plurality of semi-autonomous or autonomous devices 1004a-b and their associated portable NMR/Multisensor devices 1002a-n and 1002b-m improves performance of the swarm and facilitates coordination of the NMR data collection (e.g., among specialized portable NMR devices). In an example, the management system 1018 can determine priority of resources based on which portable NMR/Multisensor device 1020a-n telemetry is transmitted first, a priority value (or set of values, examples of which include: detected or measured chemical levels and concentrations from one or more NMR/Multisensor devices; detected or measured sensor values relative to proximity of the semi-autonomous or autonomous devices, and/or in relation to one another; some combination of telemetry gathered by both the NMR/Multisensor and other sensor measurements from the semi-autonomous or autonomous device; predicted values based on the output of machine learning algorithms whose input data comes from the NMR/Multisensor devices) associated with a particular device 1002a-n or 1002b-m, and so forth. In this way, data gathered from a single portable NMR/Multisensor device 1020a are used to update a control or command for any other device in the system 1100.

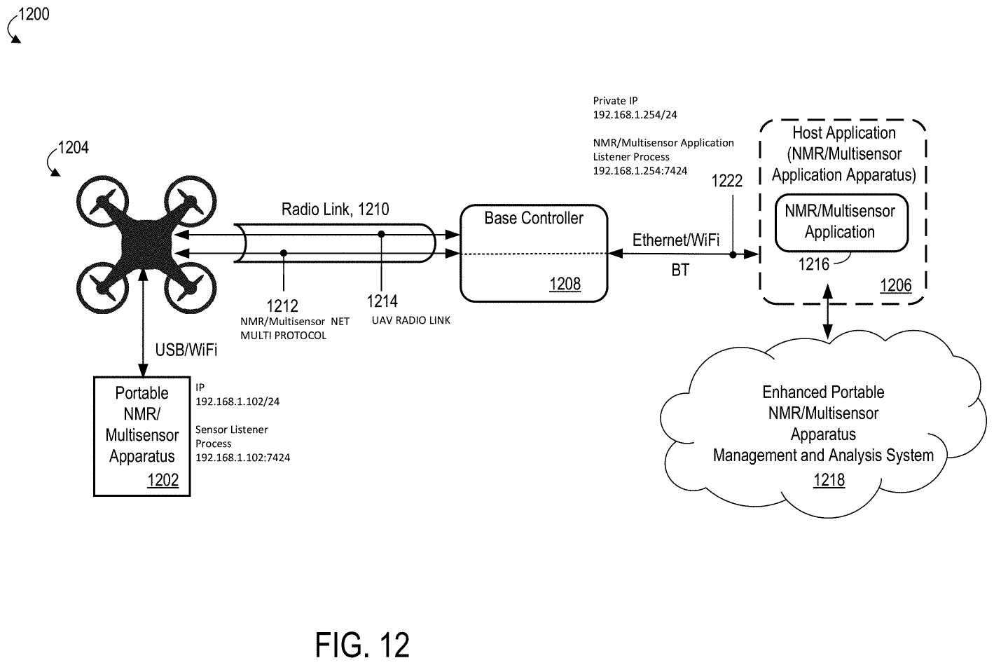

FIG. 12 is an illustration of a system 1200 that includes a representative network design. The portable NMR/Multisensor device 1202 is connected to the semi-autonomous or autonomous device 1204 (UAV as example) over an IP network with an assigned IP address. Connectivity between both devices is over USB or WiFi (including Bluetooth) as shown; however as an additional embodiment other connection methods including interconnections using directly connected hardware data and control signals are supported. The portable NMR/Multisensor device 1202 can both generate/send messages and receive messages with a resident listener process that accepts incoming messages through the USB/WiFi network link. Messages directed to the base controller 1208 over the USB/WiFi link are delivered to the base controller 1208 via the UAV radio link 1210 over a dedicated IP virtual network channel labeled as NMR Net 1212. At the base station, messages transferred over the radio link 1210 are forwarded over a second IP network to the NMR/Multisensor application host 1206 utilizing a second network transport 1222. The second network transport 1222 is one of Ethernet, WiFi, or Bluetooth, with representative IP addresses and example protocol definitions labeled as shown. System 1200 includes a complete multi-protocol/transport IP network between the portable NMR/Multisensor device 1202, the semi-autonomous or autonomous device 1204, and the application host 1206 associated with the NMR/Multisensor application and software processes, inclusive of access to the NMR/Multisensor remote computing software platform 1218.

FIG. 13A shows an example system 1300 in which there is an integration of a network of semi-autonomous or autonomous devices illustrated (in this example) as a fleet of UAV devices. Each semi-autonomous or autonomous device is associated with at least one corresponding portable NMR/Multisensor device (e.g., the NMR/Multisensor apparatus), a base controller, and an NMR/Multisensor application host system. These components together form each of sub-systems 1302a-1302n. Each of the sub-systems 1302a-n are configured to communicate on the network 1324 to an instance of the enhanced portable NMR/Multisensor device management and analysis system 1306 (also called the management and analysis system 1306 and similar to the management and analysis system 108 of FIG. 1A). The sub-systems 1302a-n each correspond to systems described in FIGS. 1A-12, such as systems 100a, 100b, 200, 300 . . . 1200, etc. in that they include each of the devices configured to communicate over the network to the management and analysis systems 1306, which represents the management systems (e.g., management and analysis system 108, 424, 618, 718, 1018, and 1218) previously described. The subsystems need not each have a single instance of a portable NMR/Multisensor device, a semi-autonomous or autonomous device, a base controller, and so forth. Rather, configurations as earlier described are each possible.

The management and analysis system 1306 is configured to provide processing and computational capability beyond that which is achieved by the other apparatus hardware/software modules of the subsystems 1302a-n. To do this, the management and analysis system 1306 is configured to enable coordination, orchestration, processing, and computation of telemetry across multiple networks of portable NMR/Multisensor devices within semi-autonomous or autonomous systems and devices (e.g., among sub-systems 1302a-n). In some implementations, the management and analysis system 1306 is configured to facilitate integration of a large network of semi-autonomous or autonomous systems and devices with additional third-party hardware/software platforms comprising private or public computing infrastructures that further extend the functionality or processing capabilities of the management and analysis system 1306. In one embodiment, the third-party systems integrate through a database interface or interactive/streaming module 1314. The third-party system includes an external database or computing host offering additional processing and/or functionality specific to the third-party system. The management and analysis system 1306 can provide global data that is enriched, processed, or otherwise operated on to the third party system. For example, one embodiment includes the utilization of global intelligence computed in 1306 from all datasets received by the one or more NMR/Multisensor devices to provide interactive and streaming data to an external swarm-intelligence system for the purposes of managing the operation and orchestration of a network of autonomous devices or systems to achieve their task or objective including path, task, and decision-making functions.

In another example system 1301, shown in FIG. 13B, the management and analysis system 1306 is utilized to compute pre-trained machine learning algorithms 1332a-d that are distributed (e.g., shown by line 1336) to the portable NMR/Multisensor devices enabling them to preprocess data detected, sampled, or measured from the portable NMR/Multisensor systems 1302a-n. The resulting embodiment increases the execution performance of the ML global algorithm 1330 as the training process is based on portable NMR/Multisensors as well as third-party datasets received and processed in parallel. This system 1301 also decreases communications required relative to system 1300, as the datasets are processed within (local to) each portable NMR/Multisensor device in comparison to transferring raw, unprocessed data between devices and system components. In a similar manner and additional embodiment, command-and-control operations local to the semi-autonomous or autonomous devices and system can be further improved in terms of their respective execution performance by leveraging resulting distributed and collective machine learning computation occurring across the portable NMR/Multisensor devices and management and analysis system 1306.

The management and analysis system 1306 of each of FIGS. 13A-13B is comprised of multiple sub-components each performing a specific function or task. These components and their associated tasks are now described. In order for semi-autonomous or autonomous systems and devices to utilize enhanced features of the software platform (e.g., application 116 described in relation to FIG. 1A), the various semi-autonomous or autonomous systems and devices (e.g., semi-autonomous or autonomous device 104) are registered through an administrative application 1308. The administrative application 1308 is configured to communicate and interface to a platform administrative module 1310 that exposes APIs for registration and administration by a registration module 1312. A registration process includes pairing one or more 3^{rd} party devices to a portable NMR/Multisensor device 102 through a NMR/Multisensor apparatus provisioning process 1318 that creates and configures entries within a subscriber device database 1320. The database 1320 includes records for each portable NMR/Multisensor device 102 and/or NMR/Multisensor application apparatus devices and/or NMR/Multisensor application software, and further invokes a provisioning process to execute the set of operations to dynamically download and update any firmware and software modules associated to the registered NMR/Multisensor system components 102. The dynamic software manager module 1322 receives rules for associated what software modules are included and allowable for a given subscriber and their respective registered system components (e.g., the NMR/Multisensors the NMR/Multisensor application instances, and, if applicable, the NMR/Multisensor application apparatus or host.

Generally, communication with a given portable NMR/Multisensor device 102 or NMR/Multisensor application 116 is routed through a NMR/Multisensor application network interface module 1316. The system 1306 coordinates message flows and sequencing of operations through the central workflow manager/message router 1326. Once registration and provisioning, as well as firmware and software updates, are complete, the system 1306 is configured to handle messages from a portable NMR/Multisensor device 102 or application 116 module by an assigned NMR/Multisensor controller 1324a-1324n in conjunction with the dynamic NMR/Multisensor software control interface 1322. The control interface 1322 is configured to dynamically assign a NMR/Multisensor controller 1324a-n to one or more portable NMR devices 102 and applications 116 during initial configuration. The function of the NMR/Multisensor controller 1324a-nis to handle enhanced function requests including the execution of one or more NMR/Multisensor analysis and machine learning (ML) algorithms, including pre-training of ML algorithms that can execute on the NMR/Multisensor devices, NMR/Multisensor application apparatus, or NMR/Multisensor applications respectively; as well as their respective execution including any run-time support. The NMR/Multisensor controller 1324a-n may execute one or more programs, scripts or software codes as part a runtime program processing module capability to enable complex processing and operations within a network of NMR/Multisensor devices, apparatus and application environments.

The management and analysis system 1306 is configured to process NMR/Multisensor telemetry for multiple semi-autonomous or autonomous systems and devices (e.g., of sub-systems 1302a-n) in a collective manner. In an example, the management and analysis system 1306 includes a NMR/Multisensor collective ML module 1328. The collective ML module 1328 provides for the execution of algorithms and software processes that operate on group or collective telemetry received from multiple portable NMR/Multisensor device 102 and application 116 instances. A representative example includes generating a heat map by geo-spatial coordinates of portable NMR/Multisensor devices 102 that determine the presence of a particular chemical structure. A second example includes a generation of a specified configuration that collections and sub-collections of portable NMR/Multisensor devices 102 or applications 116 must execute in order to realize a coordinated experiment across multiple semi-autonomous or autonomous devices 104 , each including one or more portable NMR/Multisensor device 102. While two examples are listed, many other possible processes are performed in this manner to coordinate the portable NMR/Multisensor devices 102, applications 116, and/or semi-autonomous or autonomous devices 104 using the ML module 1328. As one embodiment, the generated predictive intelligence computed by the management and analysis system 1306 can be utilized to control the decision making, path, and task execution of the semi-autonomous or autonomous devices or systems in a manner that is independent of the operation of the portable NMR/Multisensor devices. The collective ML module 1328 is supported by additional modules, such as a NMR/Multisensor signature and measurement analysis and ML module 1330 and NMR/Multisensor analysis and ML libraries and runtime support module 1332. Module 1330 is configured for specialized processing of NMR/Multisensor signatures or measurements in accordance with the NMR/Multisensor operations being performed by the portable NMR/Multisensor devices. For example, particular ML engines (e.g., neural networks with developed weighted regimes) are pre-loaded for use by the module 1330. The module 1332 can store libraries of trained ML configurations that is identified and used during processing by the modules 1328, 1330.

The datasets generated by the subsystems 1302a-n or the management and analysis system 1306 may be further encrypted and stored within a subscriber and NMR/Multisensor database 1320 in order to manage large amounts and provide a mechanism for historical analysis and said processing. In order to facilitate integration with external systems, a database interface module 1314 is designed to enable external systems access to said datasets of the database 1320.

As previously described, the management and analysis system 1306 is configured to be implemented on various devices and systems. For example, the management and analysis system 1306 is implemented such that the platform may be hosted on a server, or cluster of servers, including virtual machines, any of which may reside within a private or public cloud network.

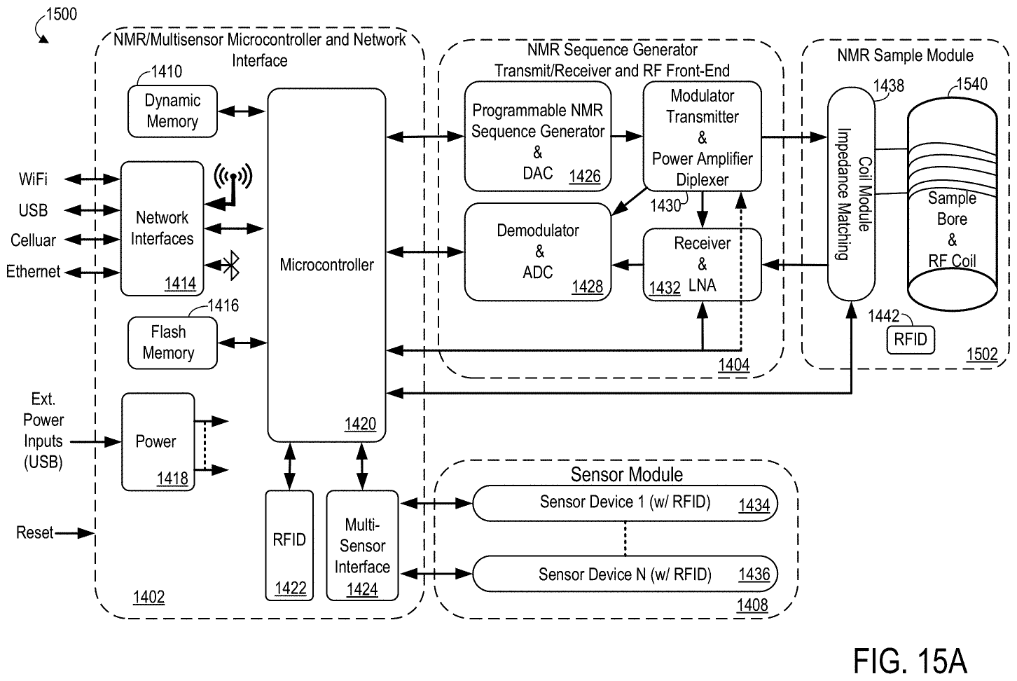

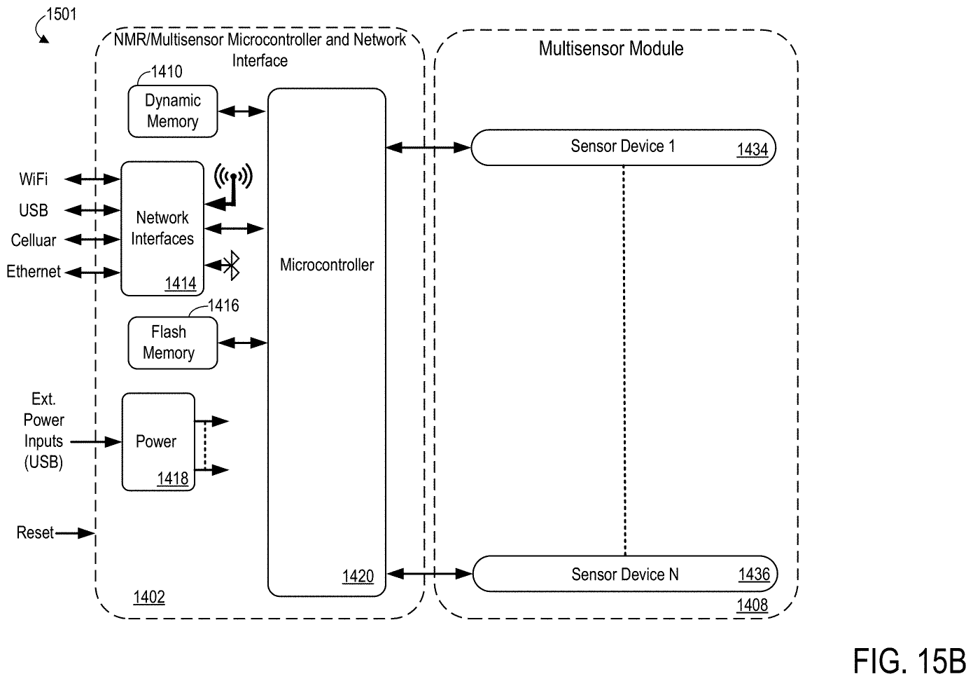

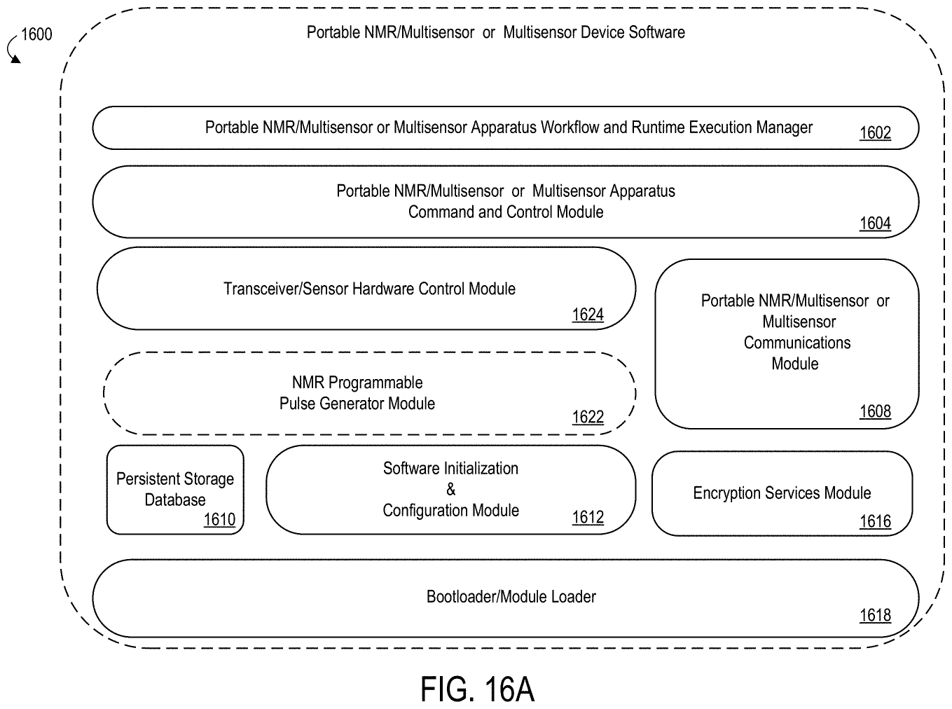

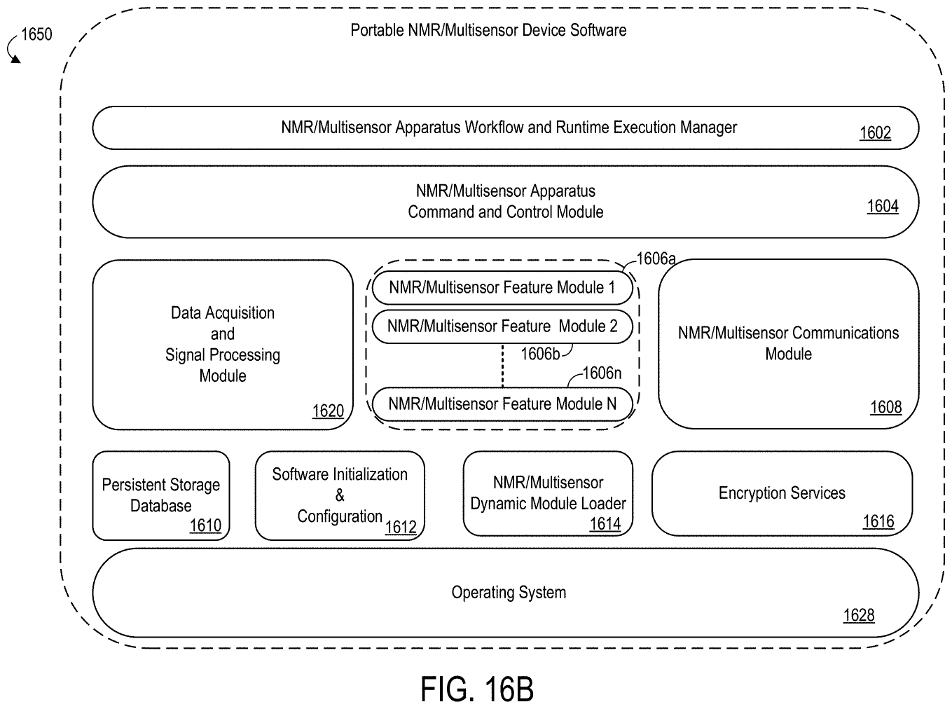

FIGS. 14-15 illustrate example systems 1400, 1500 each include exemplary hardware design embodiments for the portable NMR/Multisensor device (e.g., portable NMR/Multisensor device 102 of FIG. 1A-1B). In FIG. 14, four functional modules 1402, 1404, 1406, and 1408 are shown. The NMR/Multisensor microcontroller and network interface module 1402 includes a microcontroller 1420 configured to execute NMR/Multisensor software that is subsequently described illustrated in relation to FIGS. 16A-16B. The microcontroller 1420 supports multiple network and communications interfaces 1414, as previously described. The module 1402 includes memory 1410 including one or more of dynamic and persistent memory, an optional RFID identifier 1422, interfaces 1424 for sensor devices (such as sensors previously described in relation to FIGS. 1A-1B), and an external power supply interface 1418. The power supply may be based on USB-C, external DC-supply, or battery such as a rechargeable power cell inclusive of charging coil technologies to minimize cabling.

An NMR sequence generator transmit/receiver and RF front-end module 1404 includes a microcontroller with integral programmable sequence generator 1426, for generation of NMR transmit excitation pulses. As a consequence, the module 1404 implements a programmable RF transceiver with support for multiple TX/RX RF channels, where each channel includes all necessary modulation, demodulation, filtering, and amplification functions. For example, a transmitter and power amplifier diplexer module 1430 is configured for preparing transmissions, the demodulator and analog digital converter (ADC) 1428 is configured for receiving NMR signals and converting them to data for analysis by the microcontroller 1420, a receiver and low noise amplifier (LNA) module 1432 is configured for receiving signals from the sample module 1406 and preparing them for demodulation or other signal processing by modules 1430, 1428. In some implementations, processing of the analog signals from the sample module 1406 is controlled by the microcontroller 1420.

An NMR sample module 1406 includes at least one RF coil a 1440 and impedance matching network 1438 for receiving NMR sample signals and preparing the signal for processing by analog hardware in module 1404. The sample module 1406 can also include an RFID tag 1442 as previously described in relation to FIGS. 1A-1B. System 1400 includes two independent coil sensor modules 1405a-b, and thus has the ability to perform two independent experiments such as the case of two different chemical structures associated with different excitation frequencies. There is a dedicated RF transceiver channel 1403a-b for each respective coil module 1405a-b. Additional RF transceiver channels and coil modules may be added or included with additional programmable RF transceivers and coil assemblies in a modular implementation, as previously described.

An expandable and configurable sensor module, implementing 1 . . . N reconfigurable (modules can be added or removed) sensor modules 1 . . . N 1408 is configured to receive one or more sensor inputs and is directly integrated with module 1402. In an example, RFID is used for modules 1434, 1436 to enable the auto-recognition of the sensors of the sensor module 1408 and the NMR sample device 1440 of the sample module 1406 by the microcontroller 1420 and NMR application 116 software. Alternatively, in the absence of RFID component, each sensor module can support equivalent functionality utilizing an EEPROM or similar persistent storage, identifying the sensor module type, version and serial-number for identification and capabilities based on a software based method of discovery, sensor registration, configuration and initialization.

FIG. 15A shows a system 1500 that is similar to system 1400 of FIG. 14 and shows an embodiment of the portable NMR/Multisensor device (e.g., portable NMR/Multisensor device 102 of FIGS. 1A-1B). System 1500 includes a module 1502 with a single RF channel with direct integration to a single external RF coil 1540, however the module 1502 has an integral programmable sequence generator and RF electronics enabling an integrated system. FIG. 15B shows an alternative system 1501 to system 1500. System 1500 shows the microcontroller and network interface 1402 configured to interface with a Multisensor module only, without NMR coils. The Multisensor module 1408 includes a plurality of sensor devices 1-N.

FIGS. 16A-16B show examples of internal software architectures 1600, 1650 for the NMR/Multisensor apparatus as two exemplary embodiments. FIG. 16A illustrates a simplified software system implementation executing within the microcontroller(s) of FIGS. 14-15. FIG. 16B illustrates a more complex and sophisticated software system with enhanced features.

The software design and implementation of system 1600 is an example a baseline suite of modules for operating the NMR/Multisensor apparatus to generate NMR resonance and receive telemetry, as well as sensor configuration and receipt of sensor telemetry. Upon power reset, a bootloader/module loader 1618 starts execution of the operation system 1618 and initializes the other modules by loading and executing a software initialization and configuration module 1612, whose primary function is to start NMR command and control module 1604 and communications module 1608. Additionally, the NMR programmable pulse generator module 1622, database 1610, and encryption services 1616 are initialized and begin execution.

A typical operating sequence starts when a listener process begins execution within the communications module 1608, whereby incoming messages are delivered to the command and control module 1604 for processing. The command and control module 1604 executes a command interpreter and workflow 1602 as part of managing the runtime environment of the NMR/Multisensor device 102, in order to orchestrate the tasks and operations to execute a given command function. A command function may request a given pulse sequence generation which in turn results in a particular pulse sequence RF generation from the transceiver/sensor interface control module 1624. Similarly, a received RF signal (e.g., a frequency identification (HD), T1/T2, echo, etc.) is processed through the receive circuitry of the transceiver and processed. Processing the RF signal includes conversion from analog to digital format and packaging the digital NMR data within a suitable transport format for delivery to the communications module 1608 for external transmission to the NMR/Multisensor application 116 for further processing. In some implementations, the digital NMR data are encrypted prior to transmission. In this scenario all data is encrypted by the encryption services 1616 module, prior to forwarding all messaging to the communications module 1608.

In the event there is poor or no communications channel availability, the local persistent storage database 1610 is included and based on utilization of flash based memory for storing key configuration and telemetry datasets. In this manner the operating behavior of the portable NMR/Multisensor device 102 can tolerate temporary network interruptions, poor signal due to black out zones, or even power losses. Similar operations occur for treatment of sensor devices in terms of configuration, command execution, and telemetry receipt and delivery to the NMR/Multisensor Application for further processing.

FIG. 16B illustrates the exemplary design for expanded software functionality within the portable NMR/Multisensor device 102 in software system 1650. System 1650 includes additional loader 1614 for dynamic module loading, one or more NMR/Sensor feature modules 1606a-n, and local signal processing and data acquisition module 1620, each providing enhanced or functionality specific to a given NMR or sensor module. For example, each NMR/Sensor module contains program code to orchestrate and operate the functionality associated to a given NMR or sensor module hardware configuration. NMR modules comprise varying configurations based on the type and format of NMR pulse sequences required, the frequency of operation, number of samples acquisition-analysis cycles, coil parameters and impedance settings, and other calibration operations all in accordance with the intended samples for analysis. The NMR/Multisensor implements a module expansion capability in support of at least one sensor device. Correspondingly, a sensor feature module contains the software instructions to configure, initialize and operate the given sensor. In some configurations, one embodiment of the NMR/Sensor feature modules is the inclusion of NMR and/or sensor specific machine learning models and parameters required to implement machine learning operations on the given NMR or sensor device. For example, an NMR device can utilize one or more machine learning algorithms (as previously described) to classify the output data from the NMR device into a set of classes indicating the chemical, biological, bacterial or viral properties of an acquired sample. In another embodiment, one or more sensor feature modules implement a machine learning algorithm to classify detected or measured properties output from the given sensor. In one further embodiment, NMR/Sensor feature modules can implement machine language algorithms derived from combinations of one or more NMR/Sensor feature modules. The one or more dynamically loadable NMR/Sensor feature modules 1606a-n are configurable downloaded, begin execution, and persisted to flash under the control of the dynamic module loader 1614. In this manner the NMR/Multisensor apparatus command and control module 1604 can execute multiple algorithms (corresponding to a given NMR/Sensor feature module 1606a-n functionality) enabling the NMR/Multisensor apparatus to process all captured or measured telemetry in accordance to the NMR/sensor feature module 1606a-n locally, prior to external transmission/delivery. This improves the performance of the overall system as preprocessed acquired data minimizes computation performed within the NMR/Multisensor application 116. The portable NMR/Multisensor device 102 is thus configured to provide processed results and computation by NMR/Multisensor feature modules 1606a-n execution for use directly within the semi-autonomous or autonomous system or device.

In embodiments, the NMR/Multisensor device 1500 is configured to preprocess data collected by the NMR sensor module 1502 or system sensors of the sensor module 1408 prior to transmitting the preprocessed data to a remote computing device (e.g., enhanced portable NMR/Multisensor apparatus management and analysis system 224). The microcontroller 1420 (or another processing device of the NMR/Multisensor device 1500) can be configured to perform data transforms (e.g., Fourier transform), image processing, data filtering, signal modulation, data formatting (e.g., packetizing), or and such similar data processing. The result is that the remote computing device can receive data from many instances of the NMR/Multisensor device 1502 that are preprocessed, reducing a processing burden and reducing bandwidth usage in some examples. For example, the preprocessed data can be used to optimize a data processing workflow by the remote computing device. The remote computing system (e.g., host 224) can specify what preprocessing steps are performed by the NMR/Multisensor device 1502 in a control signal or other configuration signal. This functionality can be applicable to any of the examples of the NMR/Multisensor described previously or subsequently.

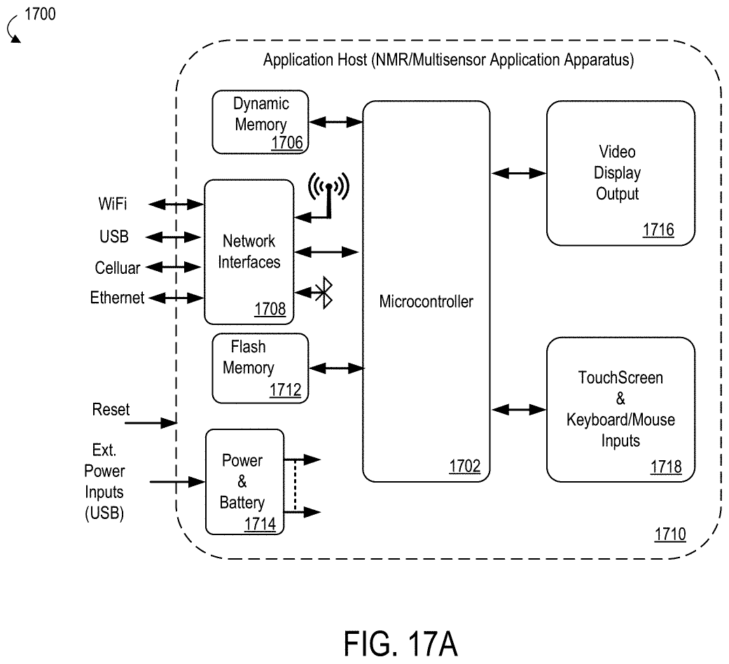

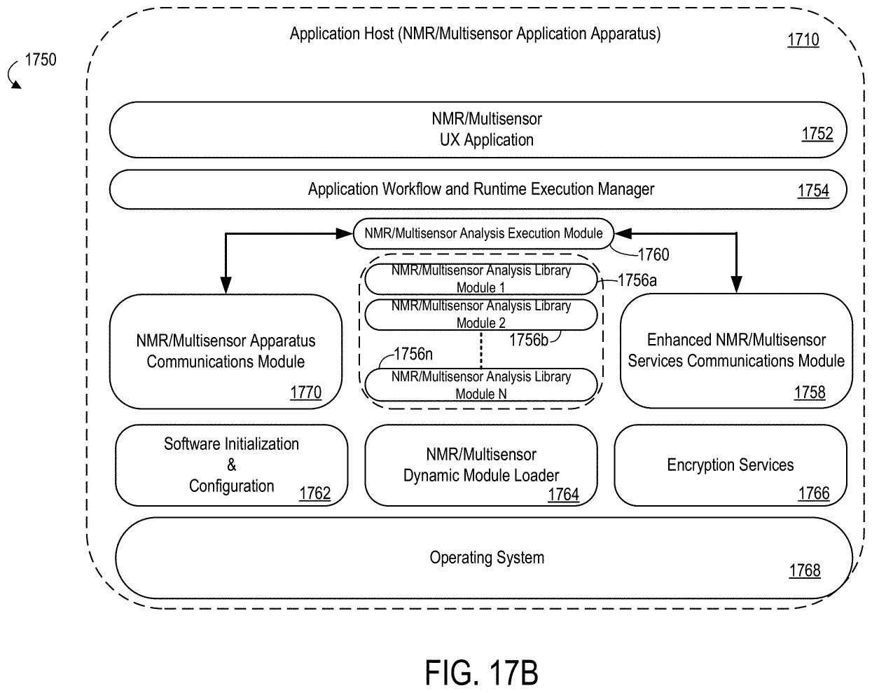

FIGS. 17A-17B illustrate hardware and software included in the application host (e.g., application host 106 of FIGS. 1A-1B) described herein. FIG. 17A illustrates an example system 1700 including a hardware design of the application host 1710 (e.g., a NMR/Multisensor application apparatus). The application host 1710 includes a microcontroller or microprocessor system on a chip (SoC) based solution with both dynamic memory 1706 and persistent memory 1712, multiple network interfaces 1708 including wired and wireless as indicated, a display 1716 for user-experience output, and touchscreen/keyboard/mouse 1718 for input. Modern laptop, tablet and semi-customized variations resulting in an optimized hardware apparatus provides a suitable operating system and programming environment to implement the software architecture and design shown in in FIG. 17B.

The software design 1750 of the application host 1710 (e.g. application host 106 of FIGS. 1A-1B) is illustrated in FIG. 17B. In one embodiment, the operating system 1768 is provided by the Linux/Unix operating system (or any of its variants), and works with a software configuration module 1762 to initiate the application at startup. Other operating system environments are equally suitable such as Android, IOS, as well as real-time operating systems. A user-experience 1752 (touchscreen, mouse, or keyboard based interactive UX) is provided at the top-level of the software stack for presenting the user with a method for managing and controlling one or more portable NMR/Multisensor devices (e.g., portable NMR/Multisensor device 102 of FIGS. 1A-1B). The UX application 1752 also enables a user to execute one or more NMR/Multisensor analysis studies utilizing telemetry from the portable NMR/Multisensor devices. In this disclosure, an analysis study is an experiment in which the NMR/Multisensor device is configured to carry out a specified task on a given sample collection and provide telemetry on the measurements, results or readings for further analysis and visualization.

Similar to the enhanced functionality previously described related to FIG. 16B, the NMR/Multisensor analysis execution module 1760 supports one or more NMR/Sensor analysis library modules 1756a-n that facilitate one or more NMR and/or sensor studies. NMR/Sensor analysis library modules 1756a-n may be dynamically loaded and configured into the NMR/Multisensor application by the module loader 1764. An embodiment of the NMR/Multisensor application (e.g., application 116 of FIGS. 1A-1B) is the integration of services for enhanced computation and processing of all NMR/Multisensor apparatus telemetry, by individual, group, or collective networks of NMR/Multisensor apparatus systems within a large network of autonomous systems and devices. The enhanced NMR/Multisensor services communication module 1758 supports this functionality. The module 1758 is configured to integrate the NMR/Multisensor application these processing functions. The module 1758 enables the NMR/Multisensor application to interact and invoke functions on a remote computing host as previously described in relation to FIG. 13.

Similar to the software of the portable NMR/Multisensor device as described in relation to FIGS. 16A-16B, the application host 1710 software 1750 includes a communications module 1770 for sending and receiving data to other devices. The runtime execution manager 1754 configures the runtime environment for the dynamically loaded modules 1756a-n. Encryption services 1766 is used as previously described.

FIGS. 18-31 illustrate various mechanical design embodiments of the portable NMR/Multisensor devices previously described in this disclosure. The mechanical designs provide examples and are not limiting in terms of other variations that are possible and may utilize the hardware and software embodiments previously described. As previously described, there are various methods for producing the mechanical design embodiments, including an additive manufacturing approach. Additive manufacturing enables a single, integrated portable NMR/Multisensor device to be produced that has a single mechanical envelope. Alternatively, the mechanical design can enable the sensor modules to be completely modular such that any combination of one or more sensors is configured to fill standard slots available in the portable NMR/Multisensor device. The portable NMR/Multisensor device is manufactured to be coupled, decoupled, and recoupled to a corresponding semi-autonomous or autonomous device. In some implementations, the portable NMR device and autonomous device are manufactured as a unified mechanical system. In some implementations, the portable NMR/Multisensor device is itself the semi-autonomous or autonomous device utilizing only those embodiments described within the disclosure and requiring no additional hardware or software integration.

FIG. 18 illustrates a three-dimensional perspective of a representative NMR/Multisensor apparatus 1800 (e.g., portable NMR/Multisensor device 102 of FIGS. 1A-1B) in an NMR-only apparatus configuration. An attachment interface module 1802 enables the NMR-only apparatus to integrate with a semi-autonomous or autonomous system or device. The semi-autonomous or autonomous device for the apparatus 1800 includes a UAV device. The front view of the perspective figure illustrates the reconfigurable NMR sample module as well as the overall structure of the NMR/Multisensor apparatus in NMR-only configuration.

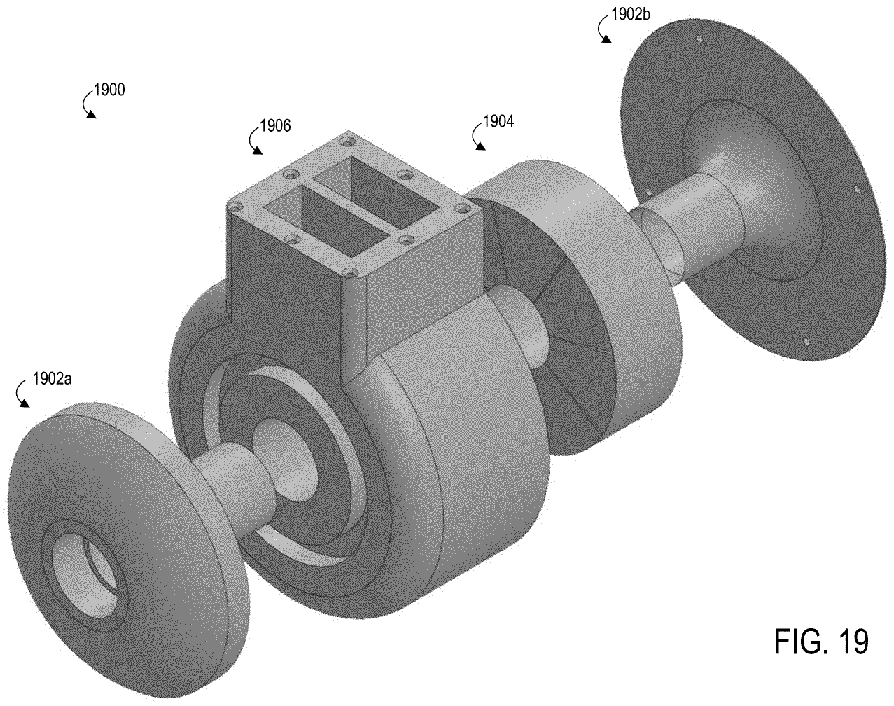

FIG. 19 shows an exploded view of an example NMR/Multisensor apparatus 1900 (e.g., portable NMR/Multisensor device 102 of FIGS. 1A-1B). Mating relationships are detailed for one of an insertable magnetic component 1904 (Halbach magnet) and NMR Electronics/Coil module 1902a-b. The upper attachment interface module 1906 to the semi-autonomous or autonomous system or device are reconfigured to suit the mechanical requirements of the mating attachment interfaces.

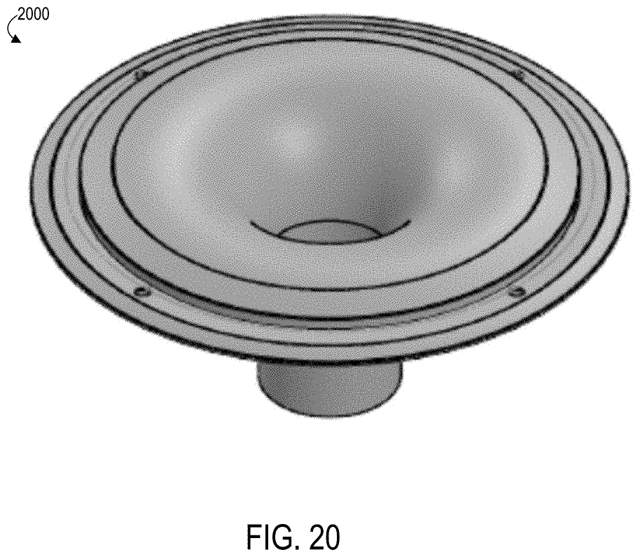

FIGS. 20-23 illustrate individual components 2000, 2100, 2200, 2300 of a representative NMR-only apparatus configuration (e.g., portable NMR/Multisensor device 102 of FIGS. 1A-1B). FIG. 20 provides a top view of the NMR Electronics/Coil module 2000. A curved geometry is optimized for minimizing fluid friction and improving aerodynamics. This curved design enables additive manufacturing of embedded electronics and coil geometries in realizing a fully integrated NMR electronics and RF/coil sub-system, as previously described.

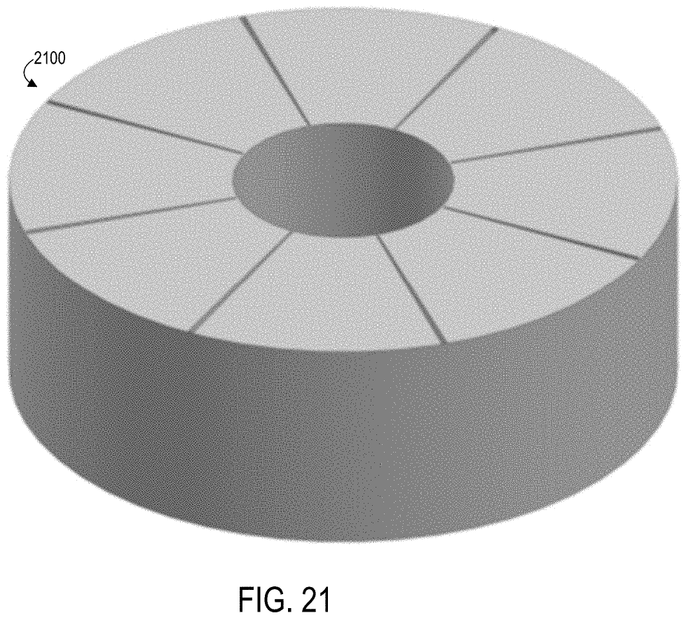

FIG. 21 illustrates an exemplary magnetic component insert 2100. A Halbach magnet is provided to realize an orthogonal magnetic field orientation relative to the solenoid coil geometry and resulting magnetic field orientation.

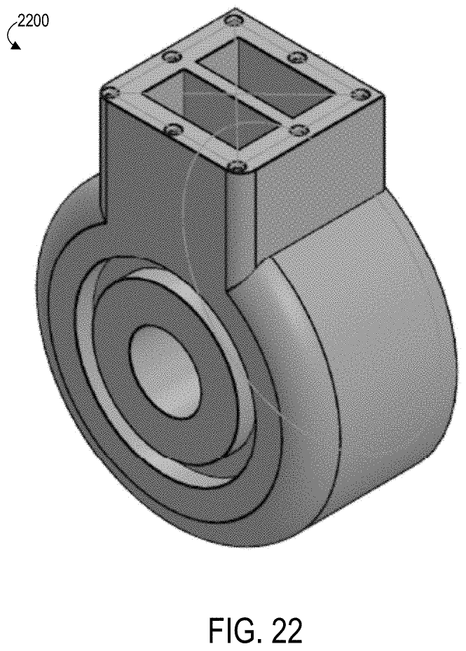

FIG. 22 illustrates a perspective view of the NMR base module 2200. The module 2200 provides a structural integrity for the assembly of component modules. An attachment interface module 2202 is provided for coupling to the autonomous device (e.g., autonomous device 104 of FIGS. 1A-1C).

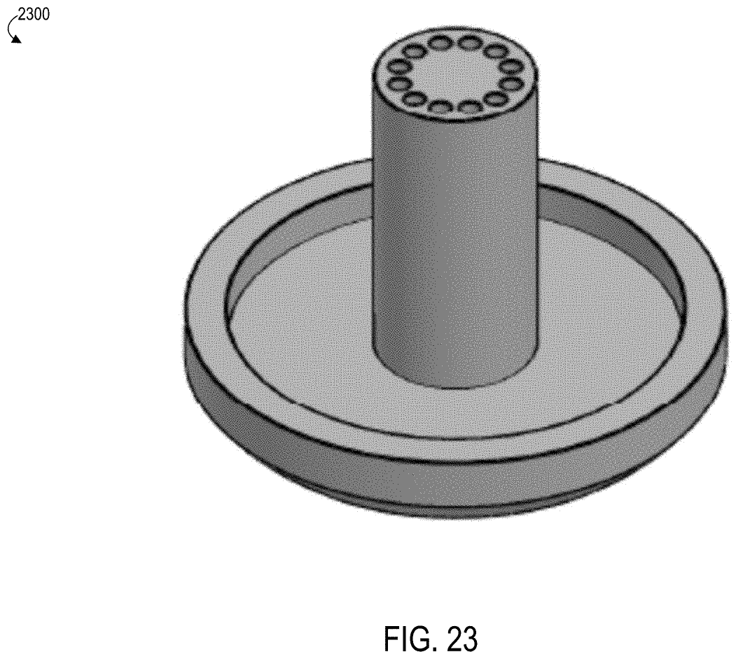

FIG. 23 shows a representative NMR sample module 2300. Different sample modules are each optimized for different environment scenarios, including fluids or solids, and may be inserted or removed with no tools as each sample module is locked into place utilizing a magnetic locking mechanism.

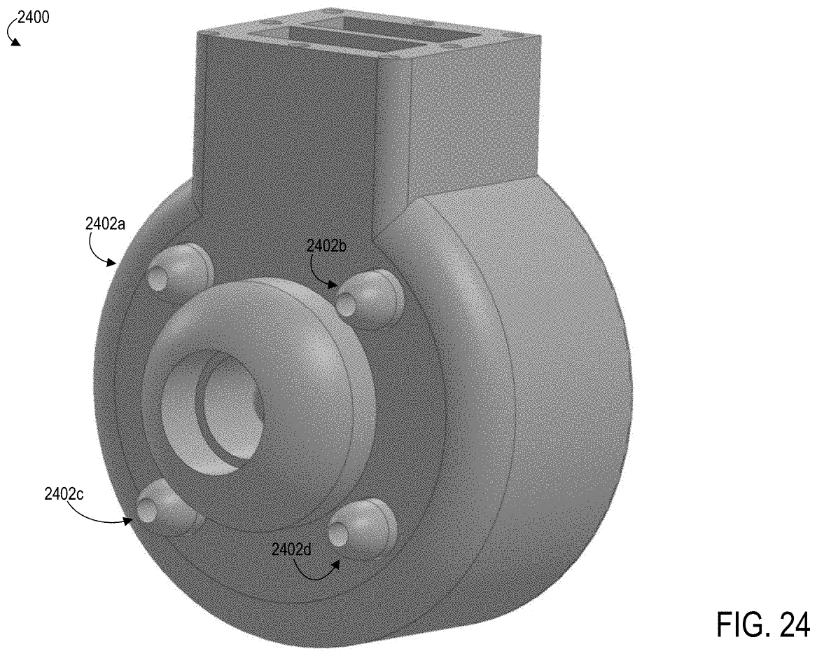

FIG. 24 shows a perspective view of an NMR/Multisensor apparatus 2400 configured with four sensors 2402a-d inserted into the modular interface. The sensors 2402a-d can be inserted and coupled based on the mechanisms previously described in relation to FIG. 35-36.

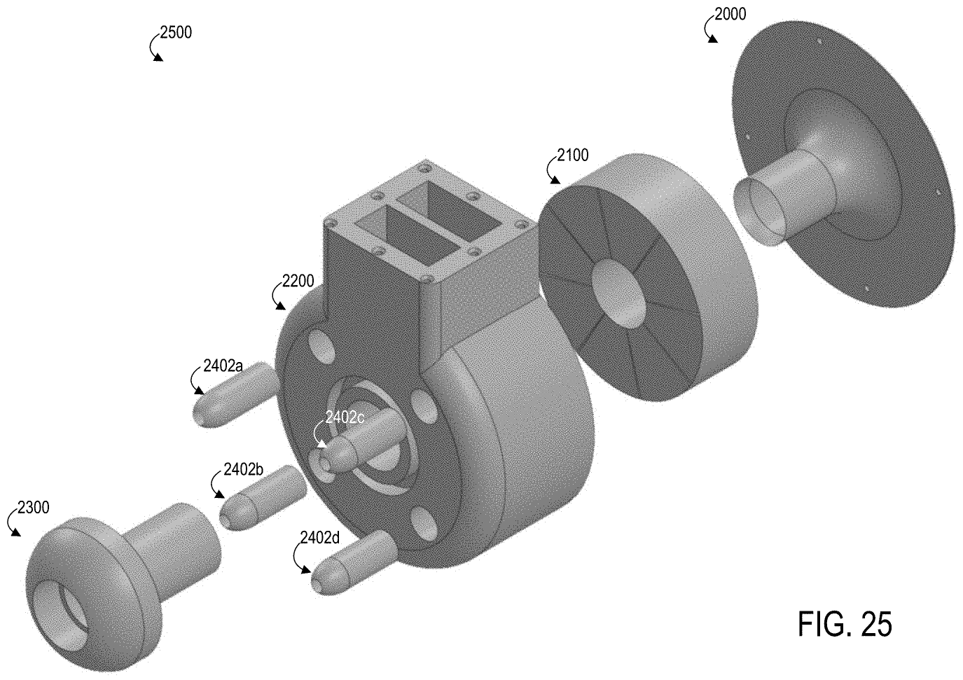

FIG. 25 provides an exploded assembly view of the NMR/Multisensor apparatus 2500 illustrating the mating relationships of each of the individual component modules. The NMR/Multisensor apparatus is one example showing a mechanical design of the portable NMR/Multisensor device 102 of FIGS. 1A-1B. For example, the apparatus includes the NMR Electronics/Coil module 2000, the magnetic component insert 2100, the NMR base module 2200, the NMR sample module 2300, and sensors 2402a-d inserted into the base modular interface 2200.

In other configuration embodiments, the NMR/Multisensor may have one or more sensors integrated within the body of the portable NMR/Multisensor when the sensor implementation benefits from the integration implementation.

In another mechanical configuration, the portable NMR/Multisensor may form other geometric shapes in accordance to the required shape, size and geometry of the integrated assembly of portable NMR/Multisensor device and semi-autonomous or autonomous device or system.

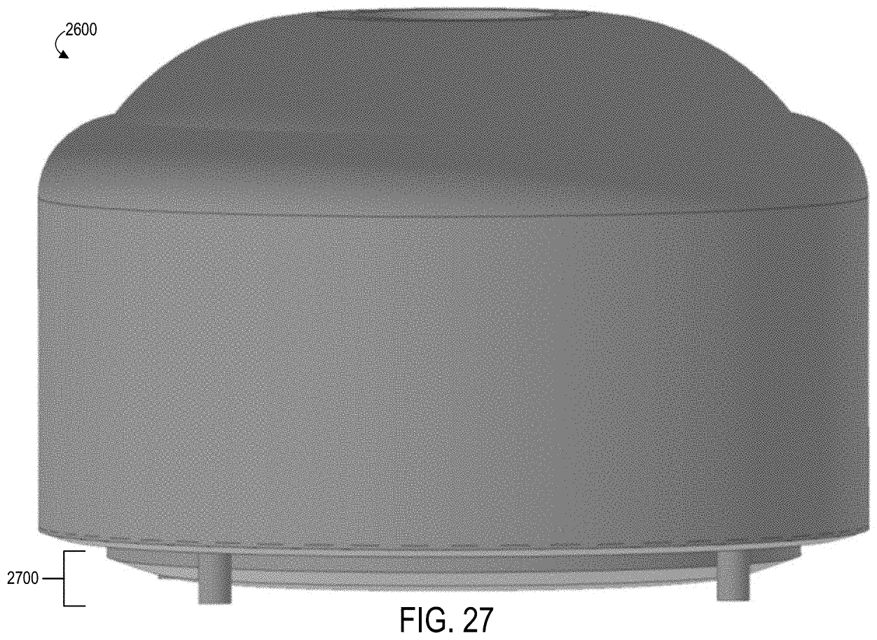

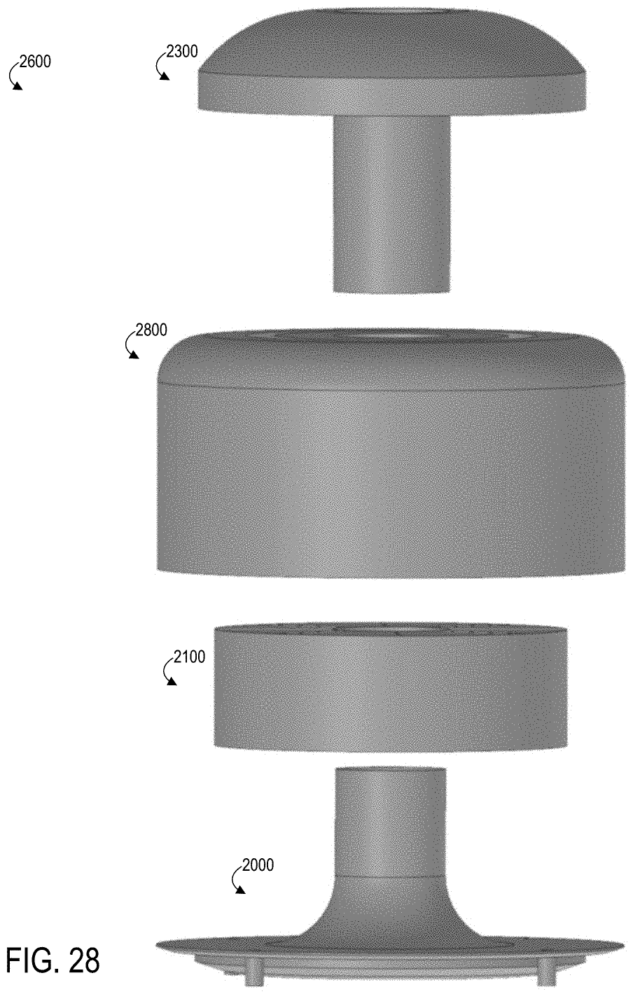

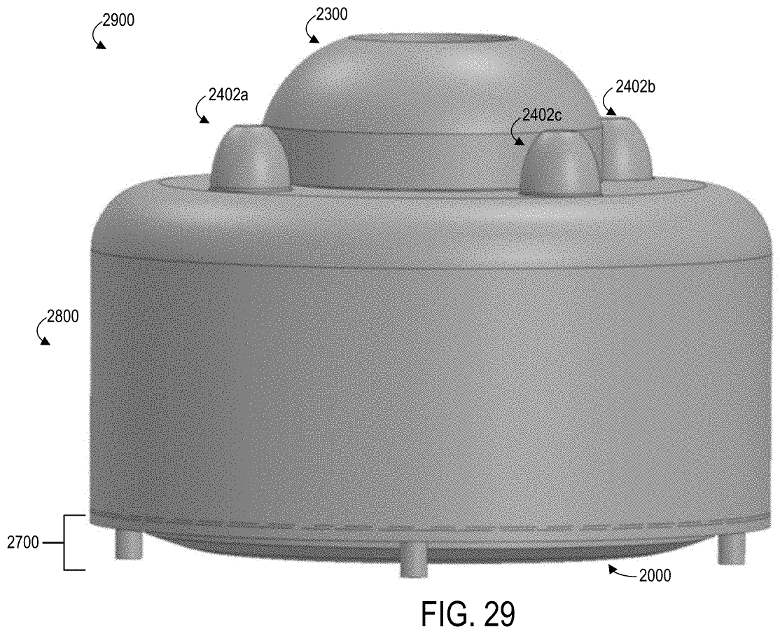

FIG. 26 illustrates a perspective view of a NMR/Multisensor apparatus 2600 (similar portable NMR/Multisensor device 102 of FIGS. 1A-1B) and is shown in a configuration for table top use and no sensors or with sensors that are integrated within the unit. The apparatus 2600 has a single mechanical envelope 2800 that is generated using additive manufacturing. FIG. 27 provides a side-view of the NMR/Multisensor apparatus 2600 noting the use of rubber or similar feet 2700 to provide stand-off distance of the device (for air-flow) and non-slippage. FIG. 28 shows an assembly view of the NMR/Multisensor apparatus 2600 and shows each of the mating relationships among component modules 2300, 2800, 2100, 2000. FIGS. 29, 30, and 31 each illustrate a side-view, a perspective view, and an exploded assembly view, respectively, of the NMR/Multisensor apparatus, with sensors 2402a-d incorporated.

The NMR/Multisensor apparatus embodiments 2600 and 2900 previously described are examples of a portable NMR/Multisensor. In some embodiments, the NMR/Multisensor apparatus embodiments 2600 and 2900 are each configured for stationary use. For example, the NMR/Multisensor apparatus embodiments 2600 and 2900 can be placed on a table and used to gather material (e.g., gas, liquid, etc.) samples in the NMR sample modules. In some embodiments, the NMR/Multisensor apparatus embodiments 2600 and 2900 can be put into any environment for autonomous or semiautonomous operation. For example, the NMR/Multisensor apparatus embodiments 2600 and 2900 can be configured to be placed in a factory, production line, or inspection system for quality assurance, monitoring, validation and/or verification. As samples of product pass on a conveyor or distribution system, the NMR/Multisensor apparatus embodiments 2600 and 2900 can be configured to take samples and transmit NMR data or sensor data to a remote computing device for further processing, as previously described. In this example, the data from the NMR/Multisensor can be used (e.g., by the remote processing system or other processing system) to control a mechanical system processing the product. For example, if a threshold number of samples fail a quality control test, the remote processing device can cause the product line temporarily shut down, generate an alert, control some other system, sort the products, or take some other action.

The NMR/Multisensor apparatus embodiments 2600 and 2900 can represent a system configured to operate entirely autonomously without receiving any feedback from the remote computing system, as previously described. For example, the NMR/Multisensor apparatus embodiments 2600 and 2900 can represent a device that collects data in an environment and emits data in a beacon (a broadcast or multicast communications) to transmit the results to one or more listening remote computing systems. For example, the NMR/Multisensor apparatus embodiments 2600 and 2900 can be a buoy placed at sea or placed on or inside a structure, or within a cavity that repeatedly collects environmental samples and performs NMR analysis or other analysis with one or more other sensors. As additional data are collected, the NMR/Multisensor apparatus embodiments 2600 and 2900 emits a dataset transmitting the data without requiring confirmation that the data are received by a particular remote computing system. An array of multiple instances of the NMR/Multisensor apparatuses 2600 and 2900 can be disbursed to operate to map a region of the environment, each emitting a dataset specifying the data and the identity of the particular transmitting NMR/Multisensor apparatus 2600 and 2900. In yet another example, NMR/Multisensor apparatus embodiments 2600 and 2900 (or other embodiments described herein) can be configured to interface with (or be) a medical device comprising medical sensors. The NMR/Multisensor apparatus embodiments 2600 and 2900 can be placed in an ambulance for transport to a scene of an accident, be placed in hospital rooms, clinics, remote areas, and so forth to collect biometric or medical data from patients, such as pharmacological analysis, blood type, blood pressure, temperature, SpO₂, heart rate, etc.

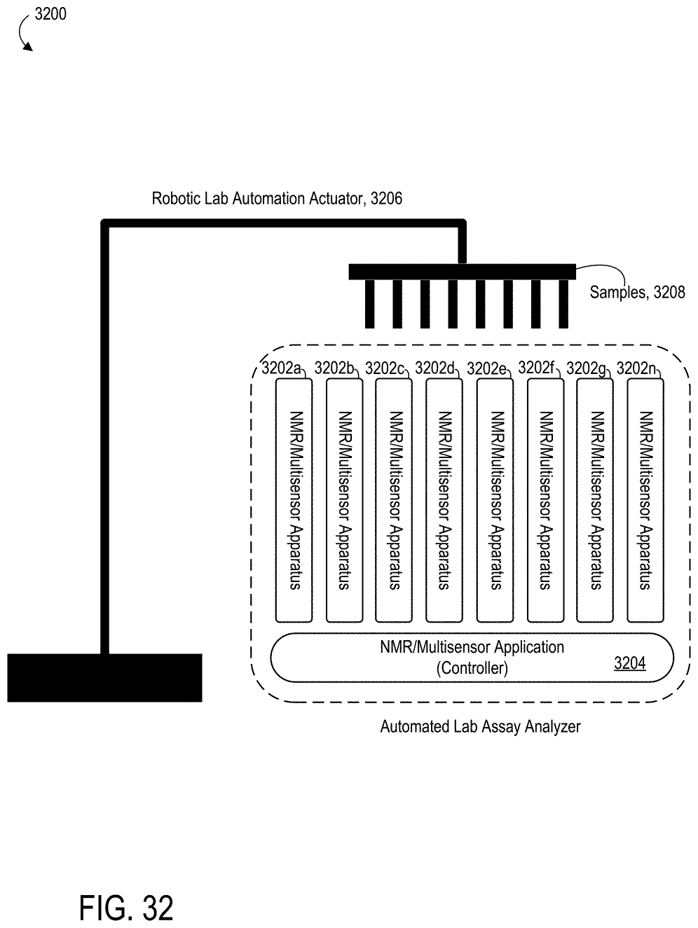

FIG. 32 illustrates the implementation of an automated lab assay and/or inspection system analyzer 3200 including the portable NMR/Multisensor devices described in this disclosure. The analyzer 3200 is based on an N-way multi-array of NMR/Multisensor apparatuses 3202a-n, with integral NMR/Multisensor application 3204 (similar to application 116 previously described). The application 3204 manages each NMR/Multisensor apparatus 3202a-n individually and collectively, performing command and controller functions. Additionally an autonomous robotic actuator 3206 coordinates the placement and removal of lab sample assays or materials for inspection 3208 synchronously with the NMR/Multisensor Application under a common command and control orchestration. Under the control of the NMR/Multisensor application controller 3204, the NMR/Multisensor apparatuses 3202a-n is configured and reconfigured for different sample analysis methods, test, inspection, measurement, and validation scenarios. Generally, the analyzer 3200 is fully autonomous and can handle a multitude of sample-analysis cycles without human intervention. Sample automation may include any type of samples in accordance to the flexible NMR sample module and sensor embodiments. Sample automation may include any scenario in which NMR technology methods are applicable, including but not limited to biologics, chemical, organic and inorganic materials, solid, etc. Sample analysis may include any scenario in which NMR and sensors can be utilized in combination to perform detection, measurement and analysis. The mechanical structure of the system represents a non-limiting embodiment of the subject matter of the present disclosure, noting that the methods and design of the hardware and software system, and overall design and methods of the overall system follow the same implementation as previously described and presented.

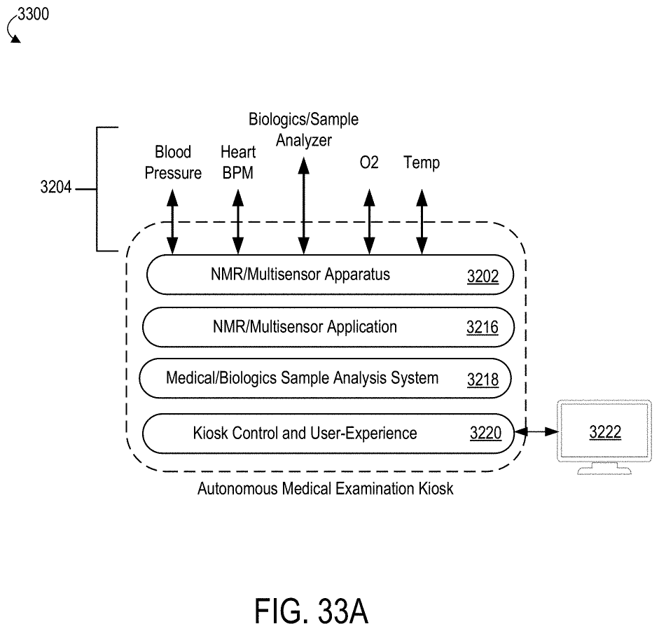

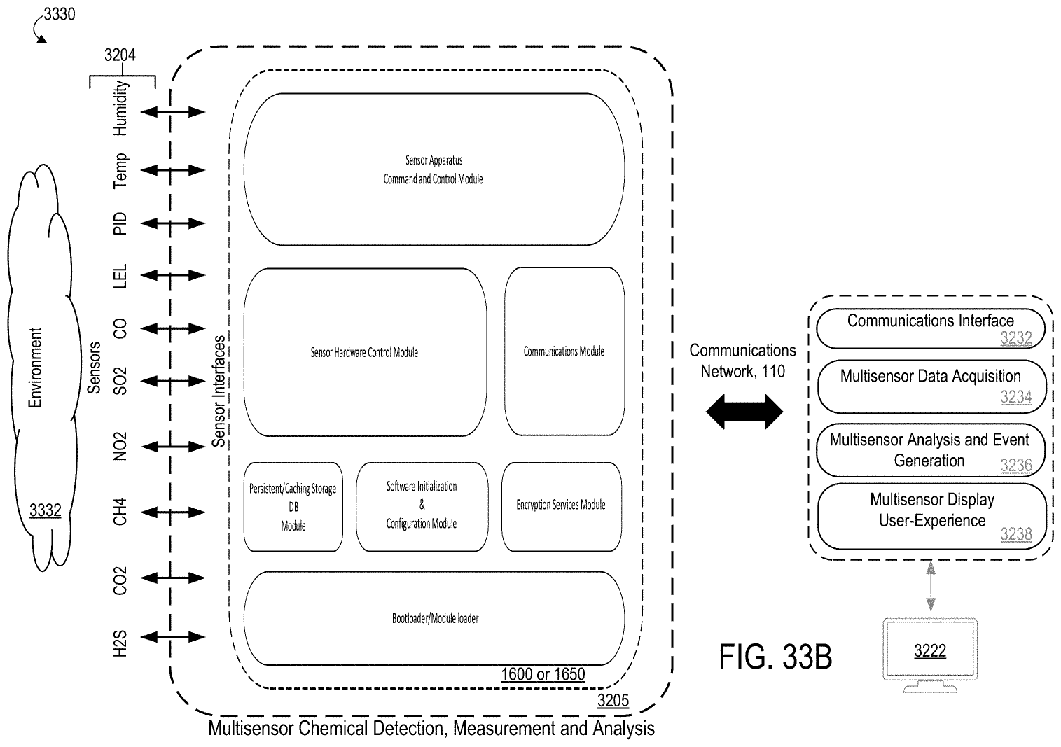

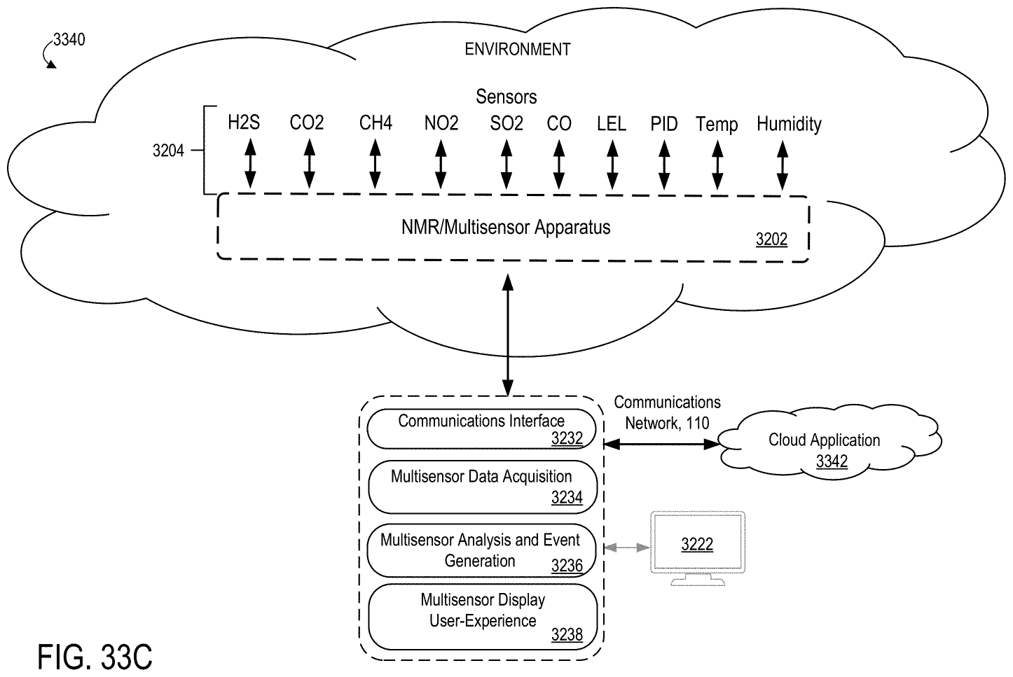

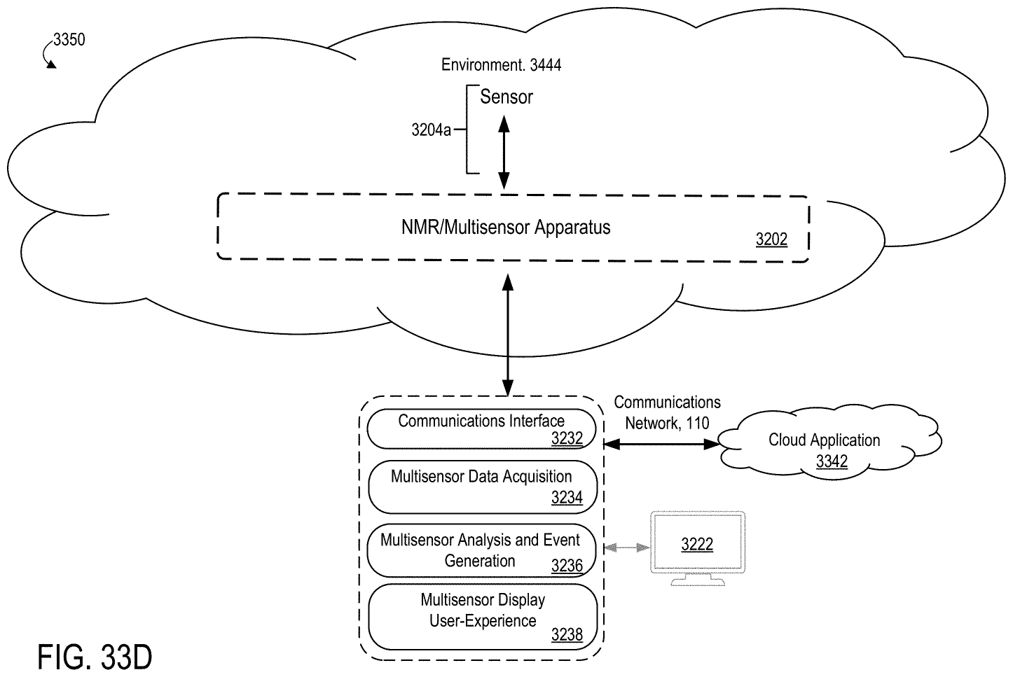

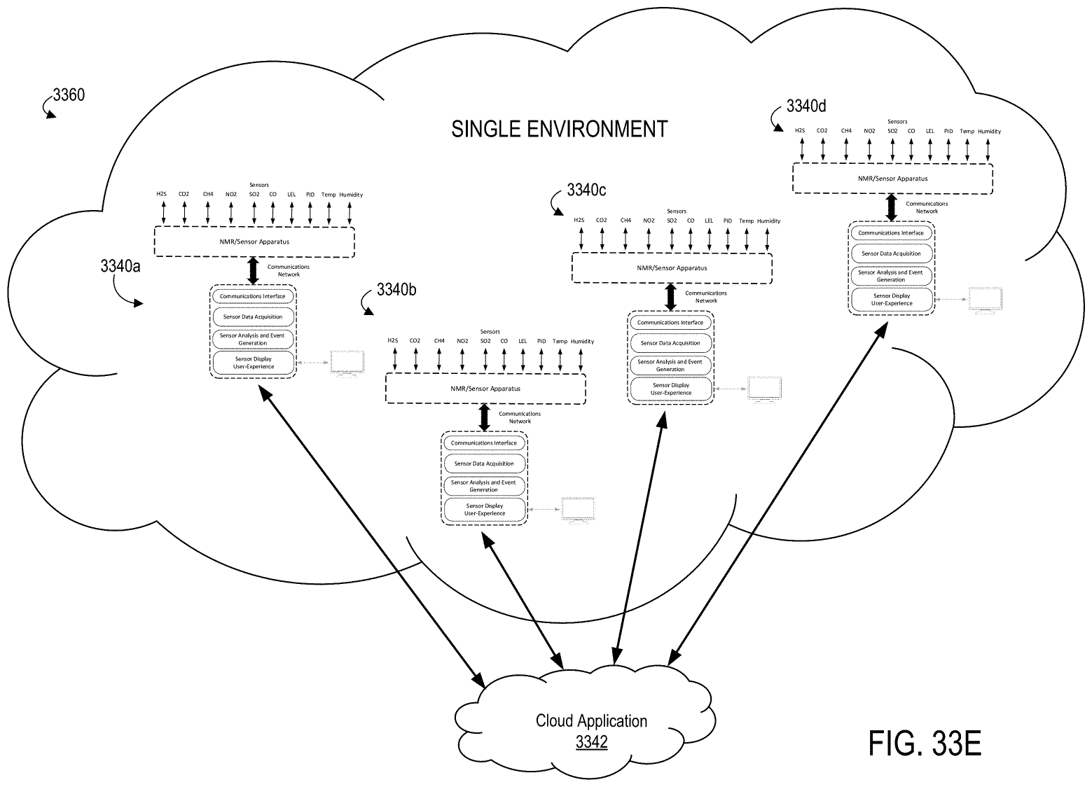

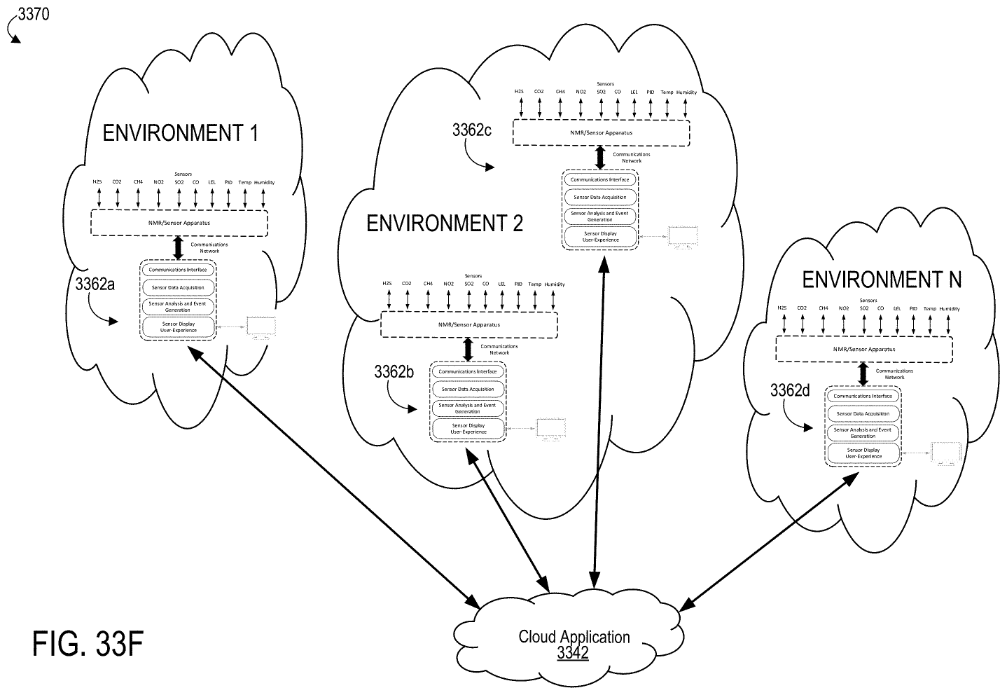

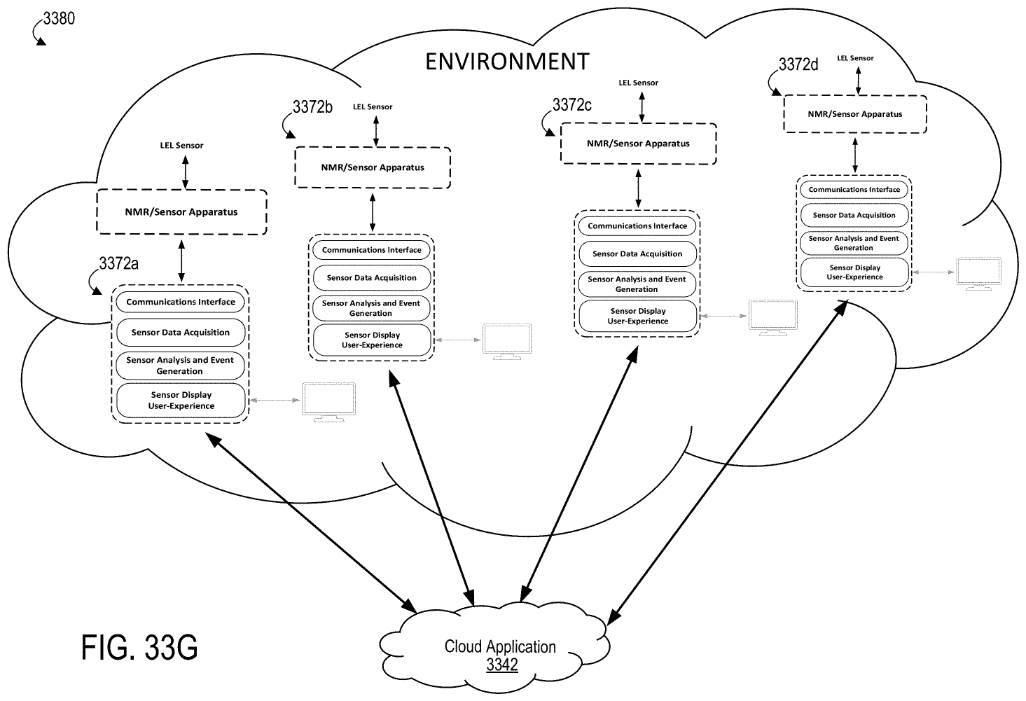

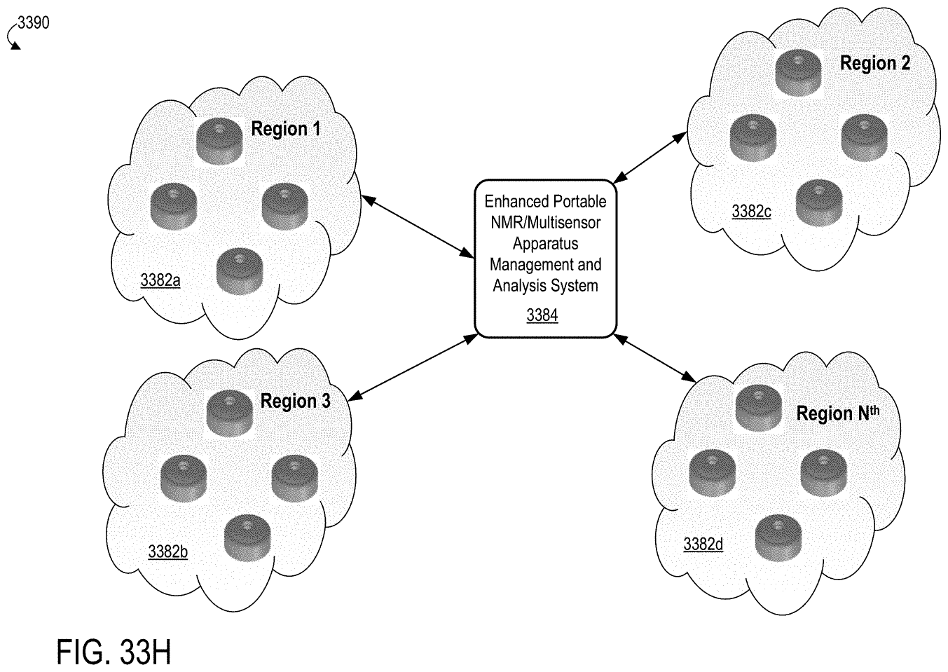

FIG. 33A illustrates a high-level design and implementation of an autonomous medical examination Kiosk or table-top automated medical examination device 3300 based on the design and methods of the subject matter of the present disclosure that have been previously described. The NMR/Multisensor apparatus 3302 (similar to portable NMR/Multisensor device 102 of FIGS. 1A-1B) is configured with multiple biometrics/medical sensors 3204 including blood-pressure, heart-rate, O₂, and temperature, etc. An instance of NMR sample module 3218 can provide analysis, test, or validation functions on a plurality of biologic substances. In other embodiments samples are analyzed for the presence of virus, bacterium or other biological significant properties. The software and system architecture of system 3300 follows the same method and design components as previously described with the addition of a Kiosk/tabletop device control and user-experience module 3220 for providing semi-autonomous or autonomous interactivity (e.g., though a client device 3222 user interface). In this scenario the Kiosk or table-top device 3300 is both a portable and fully semi-autonomous or autonomous system. A further embodiment (not shown) consistent with the subject matter of the present disclosure is enabling the NMR/Multisensor Application to integrate to a remote computing system hosting an instance of enhanced portable NMR/Multisensor device management and analysis system (e.g., management and analysis system 108 of FIGS. 1A-1B). In this embodiment, a network of semi-autonomous or autonomous medical examination Kiosks 3300 or table-top devices can supply telemetry in order to process or generate analysis of group based or collective telemetry. For example in a pandemic scenario the subject matter of the present disclosure, the embodiment of FIG. 33A could be utilized in the implementation of automated, semi-autonomous or autonomous medical testing sites to screen humans for particular health risks, virus and infections.

FIG. 33B provides an example system 3330 showing a Multisensor 3205 use scenario. The Multisensor device 3205 (e.g., using software architectures 1600/1650) is configured to interface with sensors 3204 in an environment 3332. The stand-alone Multisensor device (e.g., standalone or table top devices 2600, 2700, 2800, 2900, etc.) can interface with a client system 3222. The client system 3222 includes a communication interface 3232 for communicating over multiprotocol communication network 110. The client device 3222 receives data (e.g., in a data stream or other configuration) acquired by the sensors 3204 of the Multisensor device 3205 at a data acquisition module 3234. The client device can perform back-end computing (e.g., as previously described in relation to FIG. 10) using Multisensor analysis and event generation module 3236. Results can be displayed on a user interface or graphical presentation layer 3228.

FIG. 33C shows an example system 3340 similar to system 3330 of FIG. 33B. In this scenario, an additional cloud application 3342 is provided in addition to the client device 3222 for performing the cloud computations described previously in relation to FIGS. 10-11. Here, multiple sensors 3204 provide data via the apparatus 3202, and the data are processed by the cloud application 3342 via the client device 3222 (or independent of the client device 3222 for later presentation by the client device).

FIG. 33D shows an example system 3350 similar to system 3340 of FIG. 33C. In system 3350, a single sensor 3204a is connected or providing data to the NMR/Multisensor apparatus 3202.

FIG. 33E shows an example system 3360 that can incorporate one or more instances of the systems 3300, 3330, 3340, 3350 of FIGS. 33A-33D previously described. These are shown as instances 3340a-3340d in FIG. 33E. Each of these systems can send data to a common cloud application 3342 for global computing. In this example, each of the instances 3340a-d are operating in a single environment. A single environment means that each of the instances 3340a-d is in a common location such that they can interact with the same portions of the environment as one another. This can be useful for instances 3340a-d each optimized for different data acquisition (e.g., with specialized NMR coils or sensors of the Multisensor).

FIG. 33F shows an example system 3370 similar to system 3370, except that the instances 3362a-d are distributed among multiple environments 1-N. Different environments include locations in which instances of the NMR/Multisensors cannot interact directly with one another across environments. Here, instance 3362a, which represents an NMR/Multisensor system of any of the configurations previously described, is in a first environment 1. Two additional instances 3362b-c are in environment 2 and are isolated from direct communication with instances 3362a and 3362d, but not from one another. Instance 3362d is isolated in environment 3362d. The cloud application 3342 can receive data from each of the instances 3362a-d. A swarm controller (e.g., described in relation to FIG. 11) can coordinate all instances 3362a-d, though practical swarm operations are most useful in a common environment of the instances.

FIG. 33G shows an example system 3380 similar to system 3360 or 3370. Here, each of the NMR/Multisensor instances 3372a-d is specifically equipped with an LEL sensor for coordination for mapping combustible gas levels in a particular environment.

FIG. 33H shows an example system 3390 similar to systems 3360, 3370, or 3380. An enhanced portable NMR/Multisensor apparatus management and analysis system 3384 (similar to system 424 previously described) is configured to process data for instances of the NMR/Multisensor in each of regions 3382a-d. NMR/Multisensors in each region 3382a-d can operate as a swarm, as previously described. The management and analysis system 3384 is configured for global processing.

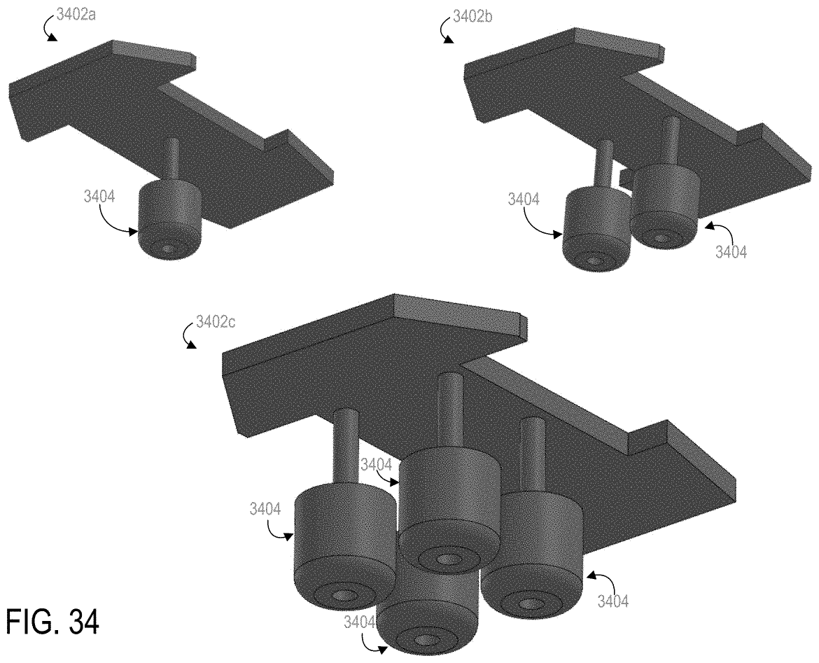

FIG. 34 shows example UAV systems 3402a-c each hosting at least one NMR/Multisensor 3404 instance. For example, UAV 3402a has one NMR/Multisensor 3404, UAV 3402b has two NMR/Multisensors 3404, and UAV 3402c has four NMR/Multisensors. While the examples show one, two, and four instances of the NMR/Multisensor on UAVS 3402a-c, any number of instances can be included. In this example, the NMR/Multisensors 3404 are integrated with the UAV, as previously described. The UAVs 3402a-c are configured to navigate through environments. In some implementations, the UAVs 3402a-c can dip the NMR/Multisensors into liquids or gases for gathering samples.

Some implementations of subject matter and operations described in this specification are implemented in digital electronic circuitry, or in computer software, firmware, or hardware, including the structures disclosed in this specification and their structural equivalents, or in combinations of one or more of them. For example, in some implementations, devices and system described herein are implemented using digital electronic circuitry, or in computer software, firmware, or hardware, or in combinations of one or more of them. Some implementations described in this specification are implemented as one or more groups or modules of digital electronic circuitry, computer software, firmware, or hardware, or in combinations of one or more of them. Although different modules are used, each module need not be distinct, and multiple modules are implemented on the same digital electronic circuitry, computer software, firmware, or hardware, or combination thereof

Some implementations described in this specification are implemented as one or more computer programs, i.e., one or more modules of computer program instructions, encoded on computer storage medium for execution by, or to control the operation of, data processing apparatus. A computer storage medium is, or can be included in, a computer-readable storage device, a computer-readable storage substrate, a random or serial access memory array or device, or a combination of one or more of them. Moreover, while a computer storage medium is not a propagated signal, a computer storage medium may be a source or destination of computer program instructions encoded in an artificially generated propagated signal. The computer storage medium can also be, or be included in, one or more separate physical components or media (e.g., multiple CDs, disks, or other storage devices).

The term “data processing apparatus” encompasses all kinds of apparatus, devices, and machines for processing data, including by way of example a programmable processor, a computer, a system on a chip, or multiple ones, or combinations, of the foregoing. In some implementations, the portable NMR device 102, the application host 106, the autonomous device 104, or the management device 108 each comprises a data processing apparatus as described herein. The apparatus includes special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) may be written in any form of programming language, including compiled or interpreted languages, declarative or procedural languages. A computer program may, but need not, correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed for execution on one computer or on multiple computers that are located at one site or distributed across multiple sites and interconnected by a communication network.

Some of the processes and logic flows described in this specification are performed by one or more programmable processors executing one or more computer programs to perform actions by operating on input data and generating output. The processes and logic flows may also be performed by, and apparatus are implemented as special purpose logic circuitry, e.g., an FPGA (field programmable gate array) or an ASIC (application specific integrated circuit).

Processors suitable for the execution of a computer program include, by way of example, both general and special purpose microprocessors, and processors of any kind of digital computer. Generally, a processor will receive instructions and data from a read only memory or a random access memory or both. A computer includes a processor for performing actions in accordance with instructions and one or more memory devices for storing instructions and data. A computer may also include, or be operatively coupled to receive data from or transfer data to, or both, one or more mass storage devices for storing data, e.g., magnetic, magneto optical disks, or optical disks. However, a computer need not have such devices. Devices suitable for storing computer program instructions and data include all forms of non-volatile memory, media and memory devices, including by way of example semiconductor memory devices (e.g., EPROM, EEPROM, flash memory devices, and others), magnetic disks (e.g., internal hard disks, removable disks, and others), magneto optical disks, and CD-ROM and DVD-ROM disks. The processor and the memory may be supplemented by, or incorporated in, special purpose logic circuitry.

To provide for interaction with a user, operations are implemented on a computer having a display device (e.g., a monitor, or another type of display device) for displaying information to the user and a keyboard and a pointing device (e.g., a mouse, a trackball, a tablet, a touch sensitive screen, or another type of pointing device) by which the user can provide input to the computer. Other kinds of devices are used to provide for interaction with a user as well; for example, feedback provided to the user include any form of sensory feedback, e.g., visual feedback, auditory feedback, or tactile feedback; and input from the user are received in any form, including acoustic, speech, or tactile input. In addition, a computer can interact with a user by sending documents to and receiving documents from a device that is used by the user; for example, by sending web pages to a web browser on a user's client device in response to requests received from the web browser.

A computer system may include a single computing device, or multiple computers that operate in proximity or generally remote from each other and typically interact through a communication network. Examples of communication networks include a local area network (“LAN”) and a wide area network (“WAN”), an inter-network (e.g., the Internet), a network comprising a satellite link, and peer-to-peer networks (e.g., ad hoc peer-to-peer networks). A relationship of client and server may arise by virtue of computer programs running on the respective computers and having a client-server relationship to each other.

While this specification includes many details, these should not be construed as limitations on the scope of what may be claimed, but rather as descriptions of features specific to particular examples. Certain features that are described in this specification in the context of separate implementations can also be combined. Conversely, various features that are described in the context of a single implementation can also be implemented in multiple embodiments separately or in any suitable sub-combination.

A number of embodiments have been described. Nevertheless, it will be understood that various modifications may be made without departing from the spirit and scope of the data processing system described herein. Accordingly, other embodiments are within the scope of the following claims.

What is claimed is:

1. A portable nuclear magnetic resonance (NMR) system configured for semi-autonomous or autonomous operation, the NMR system comprising:
a portable NMR device configured to obtain NMR data from an environment;
a wireless communications device configured to communicate with a remote computing device; and
at least one local computing device in communication with the wireless communications device and the NMR device, the at least one local computing device configured to perform operations comprising:
receiving the NMR data that is obtained from the environment by the NMR device;
processing, by the local device, the NMR data, or sending, by the wireless communications device, the NMR data to the remote computing device;
generating, at the local processing device, or causing the remote computing device to generate, at least one control signal for operating the NMR device or at least one other device in the environment or another environment, the control signal being based on processing the NMR data by the local processing device, the remote computing device, or both; and
causing, based on the at least one control signal, the NMR device, the at least one other device, or both to perform an action in the environment or another environment.

2. The NMR system of claim 1, further comprising:
a navigation assembly that is coupled to the NMR device, the navigation assembly configured to autonomously or semi-autonomously navigate the NMR device in the environment,
wherein the navigation assembly comprises at least one propulsion mechanism configured to move the navigation assembly in the environment based on the environment data and based on the at least one control signal;
wherein the at least one control signal comprises a navigation command for moving the navigational assembly in the environment to obtain additional NMR data.

3. The NMR system of claim 2, wherein the navigation assembly further comprises:
one or more sensors configured to obtain environment data for autonomous navigation in the environment by the navigation assembly.

4. The NMR system of claim 2, wherein the navigation assembly comprises an unmanned vehicle (UV).

5. The NMR system of claim 4, wherein the unmanned vehicle comprises one of an unmanned aerial vehicle (UAV), an unmanned ground vehicle (UGV), an unmanned underwater vehicle, or an unmanned spacecraft.

6. The NMR system of claim 1, wherein the remote computing device is configured to analyze the NMR data in real-time or near real-time for generating the at least one control signal, and wherein the at least one control signal is part of a stream of data that continuously or nearly continuously controls the at least one other device.

7. The NMR system of claim 1, wherein the at least one other device in the environment comprises one of a medical device, a user interface, a mechanical actuator, a data logging system, a detection system, a monitoring system, a measurement system, a chemical analysis system, or an inspection system configured for quality control, verification and validation.

8. The NMR system of claim 1, wherein the NMR device is configured to operate using at least one radio frequency (RF), and wherein the NMR device comprises one or more sensors that are configured to obtain data for a plurality of different types of data acquisition and/or analysis.

9. The NMR system of claim 1, wherein the NMR device comprises:
a sample system including a sample reservoir, the sample system configured to autonomously or semi-autonomously obtain a material sample from the environment; and
a sensor configured to obtain the NMR data from the material sample in the sample reservoir.

10. The NMR system of claim 9, wherein the sample system and the sensor are configured for obtaining one or more of a liquid sample through an inlet, a solid sample by a retaining mechanism, or a gaseous sample through an inlet.

11. The NMR system of claim 9, wherein the NMR device comprises a plurality of sample modules, wherein each sample module is configured to be removable and replaceable with one or more other sample modules.

12. The NMR system of claim 1, wherein the remote computing device comprises a first remote computing device, and wherein the operations further comprise:
sending, by the at least one local computing device through the wireless communications device, the NMR data to a second remote computing device, wherein the first remote computing device and the second remote computing device are configured to analyze the NMR data together to generate the control signal.

13. The NMR system of claim 1, the operations further comprising:
causing the remote computing device to coordinate, using the control signal, operation of the NMR device and operation of one or more other NMR devices of one or more other respective NMR systems in response to sending NMR data to the remote computing device.

14. The NMR system of claim 1, wherein the control signal comprises a data vector including results of a data analysis, and wherein the action comprises performance of additional processing of the data vector.

15. The NMR system of claim 1, the operations further comprising:
registering, by the at least one local computing device, the NMR device with the remote computing device, wherein registering comprises associating the NMR data with the NMR device; and
receiving, from the remote computing device, remote computing device configuration data responsive to registering the NMR device and representing a configuration of the remote computing device for processing the NMR data of the NMR device.

16. The NMR system of claim 15, wherein the remote computing device configuration data specify a machine learning configuration of the remote computing device, and wherein the operations further comprise:
transforming the NMR data or sensor data into feature data representing one or more features of the NMR data or sensor data, wherein transforming the NMR data or sensor data is based on the machine learning configuration of the remote computing device.

17. The NMR system of claim 15, wherein registering the NMR device with the remote computing device comprises:
sending NMR configuration data representing a hardware configuration of the NMR device to the remote computing device,
wherein the control signal is configured to control the NMR device based on the hardware configuration of the NMR device.

18. The NMR system of claim 17, wherein the hardware configuration specifies a plurality of types of material that the NMR device is configured to analyze.

19. The NMR system of claim 17, wherein the hardware configuration specifies a plurality of radio frequencies, RF configuration, and pulse sequence characteristics that the NMR device is configured to use, and wherein the control signal specifies a particular frequency, RF configuration, and pule sequence of the plurality of frequencies, RF configurations and pulse sequences for use in obtaining the NMR data.

20. The NMR system of claim 1, wherein the control signal is configured to control the NMR device based on different NMR data received by the remote computing device from a different NMR device.

21. The NMR system of claim 1, wherein the NMR device comprises a fluid reservoir, and wherein the control signal is configured to reposition the fluid reservoir to improve NMR processing by the NMR device, wherein repositioning is based on a feedback from telemetry of a semi-autonomous or autonomous device or system.

22. The NMR system of claim 1, wherein the NMR device comprises a rotating reservoir configured for receiving solid matter, and wherein the control signal is configured to position an axis of the rotating reservoir to a particular angle relative to a magnetic field of the environment.

23. The NMR system of claim 1, further comprising one or more biometric or biological sensors comprising a temperature sensor, a pressure sensor, an electrocardiogram (EKG) sensor, or an SPO₂ sensor.

24. The NMR system of claim 1, wherein the NMR device is a stand-alone device or coupled to a stationary autonomous or semi-autonomous device or system.

25. The NMR system of claim 1, wherein the local computing device is configured to cause transmission of a data delivery comprising the NMR data or sensor data, wherein the NMR device is configured to repeatedly obtain updated instances of NMR data or sensor data from the environment for transmitting in the data delivery.

26. The NMR system of claim 1, wherein the control signal is configured to cause the NMR device or the other device to adjust a data collection parameter for obtaining additional NMR data or other sensor data, respectively.

27. The NMR system of claim 1, wherein the local computing device is configured to perform a preprocessing workflow on the NMR data or sensor data to transform the NMR data or sensor data for processing by the remote computing system.

28. The NMR system of claim 27, wherein preprocessing workflow is based on a trained machine learning model, data-pattern model, or calibration data that is received from the remote computing system.

29. The NMR system of claim 1, the operations further comprising:
based on the NMR data or sensor data from a sensor device, sending one or more control signals to one or more other NMR devices or other sensor devices of one or more other respective NMR systems in the environment to control operation of the one or more other respective NMR systems, other autonomous or semiautonomous devices, or both, in the environment.

30. A system, comprising:
at least one sensor device configured to acquire sensor data in an environment, the at least one sensor device including a nuclear magnetic resonance (NMR) device, a multisensor device configured to support one or more modular sensors, or a combination of the NMR device and the multisensor device;
at least one local computing device configured to perform operations including:
processing the sensor data to update a local model representing a processing workflow for generating a control instruction for a device or to perform data analytics on the sensor data;
sending, over a communication network, the sensor data from the at least one sensor device in the environment to a remote computing device;
causing, based on the sensor data, the remote computing device to update a global model representing a processing workflow to control at least one additional device or perform data analytics for the at least one additional device, the global model being based on additional sensor data received from the least one additional device; and
causing, based on the processing workflow of the updated global model, an autonomous or semi-autonomous platform coupled to the at least one additional device to perform an action in the environment.
